(19) United States
(12) Patent Application Publication
(10) Pub. No.: US 2015/0206830 A1
(43) Pub. Date: Jul. 23, 2015

(54) Method Of Manufacturing Semiconductor Device And The Semiconductor Device

(71) Applicant: Renesas Electronics Corporation, Kawasaki-shi, KANAGAWA (JP)

(72) Inventors: Keita Takada, Kawasaki-shi (JP); Tadatoshi Danno, Kawasaki-shi (JP); Toshiyuki Hata, Kawasaki-shi (JP)

(21) Appl. No.: 14/422,351

(22) PCT Filed: Sep. 24, 2012
(86) PCT No.: PCT/JP2012/074369

§ 371 Date: Feb. 18, 2015

(51) Int. Cl. H01L 23/495; H01L 23/31; H01L 21/56

(52) U.S. Cl. CPC H01L 23/49524; H01L 21/561; H01L 23/49513; H01L 23/3114

(57) ABSTRACT

A lead frame having a first chip-mounting part on which a first semiconductor chip is mounted and having a second chip-mounting part on which a second semiconductor chip is mounted is prepared. Moreover, a process is provided, the process connecting a first electrode pad, which is formed on a top surface of the first semiconductor chip, with a first end of a first metal ribbon and connecting a ribbon-connecting surface on the second chip-mounting part with a second end of the first metal ribbon on the opposite side of the first end. Moreover, in a plan view, the ribbon-connecting surface of the second chip-mounting part is positioned between the first semiconductor chip and the second semiconductor chip. Moreover, the height of the ribbon-connecting surface is positioned at a position higher than the height of a mounting surface of the second semiconductor chip of the second chip-mounting part.

### TECHNICAL FIELD

The present invention relates to semiconductor devices and manufacturing techniques of the same and, for example, relates to the techniques which are effective when applied to a semiconductor device in which a semiconductor chip and a metal plate are electrically connected to each other via a metal ribbon.

### BACKGROUND

In Japanese Patent Application Laid-Open No. 2008-224394 (Patent Document 1) and Japanese Patent Application Laid-Open Publication No. 2007-184366 (Patent Document 2), a semiconductor device which has two semiconductor chips and have main electrodes thereof and external terminals connected via metal ribbons is described.

### PRIOR ART DOCUMENTS

### Patent Documents

Patent Document 1: Japanese Patent Application Laid-Open Publication No. 2008-224394
Patent Document 2: Japanese Patent Application Laid-Open Publication No. 2007-184366

### SUMMARY

### Problems to be Solved by the Invention

The inventor of the present application has studied about performance improvement of a semiconductor device in which a first and second semiconductor chips are mounted in a single package, wherein electrodes of a second chip-mounting part on which the second semiconductor chip is mounted and the first semiconductor chip are electrically connected via a strip-shaped metal plate. As a result, the inventor of the present application has found out that, for example, there is a problem in terms of downsizing of the semiconductor device since the distance between the region of joining the metal plate of the second chip-mounting part and the second semiconductor chip has to be increased.

The above and other preferred aims and novel characteristics of the present invention will be apparent from the description of the present specification and the accompanying drawings.

### Means for Solving the Problems

A method of manufacturing a semiconductor device according to an embodiment is to cause the height of a connecting surface, which connects a ribbon of a chip-mounting part, to be higher than the height of a mounting surface of a chip-mounting part on which a semiconductor chip is mounted.

### Effects of the Invention

According to the above-described embodiment, the semiconductor device can be downsized.

### BRIEF DESCRIPTIONS OF THE DRAWINGS

FIG. 1 is an explanatory diagram showing a configuration example of a power source circuit in which a semiconductor device is incorporated;

FIG. 2 is a main-part cross-sectional view showing an element structure example of a field-effect transistor shown in FIG. 1;

FIG. 3 is a top view of the semiconductor device shown in FIG. 1;

FIG. 4 is a bottom view of the semiconductor device shown in FIG. 3;

FIG. 5 is a plan view showing an internal structure of the semiconductor device in a state in which a seal shown in FIG. 3 is removed;

FIG. 6 is a cross-sectional view taken along a line A-A of FIG. 5;

FIG. 7 is an enlarged cross-sectional view showing a connection state of a gate electrode of a high-side semiconductor chip and a lead shown in FIG. 5;

FIG. 8 is an enlarged cross-sectional view showing a connection state of a gate electrode of a low-side semiconductor chip and a lead shown in FIG. 5;

FIG. 9 is a main-part plan view of a semiconductor device formed so that the height of a ribbon-connecting surface is higher than a chip-mounting surface as well as a low-side tab shown in FIG. 5;

FIG. 10 is a main-part plan view of a semiconductor device, which is a study example with respect to FIG. 9;

FIG. 11 shows explanatory diagrams schematically showing the stress generated along with reduction of the temperature of the semiconductor device in the cross section along the line A-A of FIG. 9;

FIG. 12 shows explanatory diagrams schematically showing the stress generated along reduction of the temperature of the semiconductor device in the cross section along the line A-A of FIG. 10;

FIG. 13 is an explanatory diagram schematically showing outlines of a method of forming a metal ribbon shown in FIG. 5 and FIG. 6;

FIG. 14 is an explanatory diagram schematically showing, subsequent to FIG. 13, outlines of the method of forming the metal ribbon shown in FIG. 5 and FIG. 6;

FIG. 15 is a main-part cross-sectional view showing a dimension example of the tab in a case in which the height of the ribbon-connecting surface of the low-side tab shown in FIG. 6 is higher than the chip-mounting surface;

FIG. 16 is a main-part cross-sectional view showing a dimension example of a case in which a semiconductor chip having a large planar size is mounted on the low-side tab as a modification example with respect to FIG. 15;

FIG. 17 is an explanatory diagram showing outlines of manufacturing processes of the semiconductor device explained by using FIG. 1 to FIG. 14;

FIG. 18 is a plan view showing an overall structure of a lead frame prepared in a lead-frame preparing process shown in FIG. 17;

FIG. 19 is an enlarged plan view corresponding to a single device region shown in FIG. 18;

FIG. 20 is an enlarged cross-sectional view taken along a line A-A of FIG. 19;

FIG. 21 is an enlarged plan view showing a state in which semiconductor chips are respectively mounted on a plurality of chip-mounting parts shown in FIG. 19;

FIG. 22 is an enlarged cross-sectional view taken along a line A-A of FIG. 21;

FIG. 23 is an enlarged plan view showing a state in which the plurality of semiconductor chips and a plurality of leads shown in FIG. 21 are electrically connected via metal ribbons;

FIG. 24 is an enlarged cross-sectional view taken along a line A-A of FIG. 23;

FIG. 25 is an enlarged cross-sectional view showing a state in which a high-side source electrode pad is joined with a metal ribbon;

FIG. 26 is an enlarged cross-sectional view showing a state in which a ribbon-connecting surface of a low-side tab is joined with a metal ribbon;

FIG. 27 is an enlarged cross-sectional view showing a state in which a metal strip is cut on the ribbon-connecting surface of the low-side tab;

FIG. 28 is an enlarged cross-sectional view showing a state in which a low-side source electrode pad is joined with a metal ribbon;

FIG. 29 is an enlarged cross-sectional view showing a state in which the metal strip is cut after the metal ribbon is joined with a ribbon-connecting surface of a low-side source lead;

FIG. 30 is an enlarged plan view showing a state in which the plurality of semiconductor chips and the plurality of leads shown in FIG. 23 are electrically connected via wires;

FIG. 31 is an enlarged cross-sectional view taken along a line A-A of FIG. 30;

FIG. 32 is an enlarged cross-sectional view taken along a line B-B of FIG. 30;

FIG. 33 is an enlarged plan view showing a state of a packaging surface side when a seal which seals the plurality of semiconductor chips and the plurality of metal ribbons shown in FIG. 30 is formed;

FIG. 34 is an enlarged cross-sectional view showing a state in which the lead frame is disposed in a forming mold in the enlarged cross section taken along the line A-A of FIG. 33;

FIG. 35 is an enlarged cross-sectional view showing a state in which a metal film is formed on the surfaces of the tabs and the lead shown in FIG. 34 which are exposed from the seal;

FIG. 36 is an enlarged plan view showing a state in which the lead frame shown in FIG. 33 has undergone singulation;

FIG. 37 is a cross-sectional view of a semiconductor device, which is a modification example with respect to FIG. 6;

FIG. 38 is a cross-sectional view of a semiconductor device, which is another modification example with respect to FIG. 6;

FIG. 39 is a plan view showing an internal structure of a semiconductor device, which is a modification example with respect to FIG. 5;

FIG. 40 is an explanatory diagram showing a modification example with respect to FIG. 1, which is a configuration example of a power source circuit in which the semiconductor device shown in FIG. 39 is incorporated;

FIG. 41 is an enlarged cross-sectional view taken along a line A-A of FIG. 39;

FIG. 42 is an enlarged cross-sectional view taken along a line B-B of FIG. 39;

FIG. 43 is a cross-sectional view of a semiconductor device, which is another modification example with respect to FIG. 6;

FIG. 44 is an explanatory diagram showing a study example with respect to FIG. 14; and

FIG. 45 is a main-part cross-sectional view showing a study example with respect to FIG. 15.

### DESCRIPTIONS OF THE PREFERRED EMBODIMENTS

### Explanations of Description Format, Basic Terms, Usage in the Present Application

In the embodiments described below, the invention will be described in a plurality of sections or embodiments etc. when needed. However, these sections or embodiments are not mutually independent to each other unless otherwise stated, and the one relates to the entire or a part of the other as a modification example or details, thereof regardless of the order of descriptions. Repetitive description of the same part is basically omitted. Further, in the embodiments described below, it goes without saying that the components of the modes are not always indispensable unless otherwise stated or except the case where the components are theoretically limited to the number and are apparently indispensable from the context.

Also, in the descriptions of the modes, as to materials and compositions, mentioning “X comprising (including, formed of) A” does not eliminate the other elements than A unless otherwise stated or except the case where the element is apparently not included from the context. For example, as to components, it means “X contains A as a main component”. For example, it goes without saying that mentioning a “silicon member” does not limit the meaning only to pure silicon but means members containing a SiGe (silicon-germanium) alloy, other multi-component alloys containing silicon as its main component, and other additives. In addition, mentioning a gold plating, Cu layer, Nickel plating does not mean pure ones unless otherwise stated but includes members containing gold, Cu, nickel etc. as main components.

Further, when referring to a specific number or amount, the number or amount may be larger or smaller than the specified number or amount unless otherwise stated or except the case where the number is theoretically limited to the specific number and they are apparently limited from the context.

Further, in each drawing of the embodiments, the same or similar parts are denoted by the same or analogous reference numeral and descriptions thereof will basically not be repeated.

Moreover, when the accompanied drawings are complex or the distinction of spaces is clear, hatching may be omitted even in a cross section. Accordingly, when it is apparent from the descriptions etc., even an outline of a hole closed in plane on the background may be omitted. Finally, even when it is not a cross section, to clearly illustrate that it is not a space or to clearly illustrate a boundary of areas, hatching or dot pattern may be added.

<Circuit Configuration Example>

In a present embodiment, as an example of a semiconductor device in which a plurality of semiconductor chips are built in a single package, a semiconductor device incorporated as a switching circuit in a power source circuit of an electronic device such as a desktop-type personal computer, a notebook-type personal computer, a server, or a game machine will be explained as an example. An embodiment of application to a QFN (Quad Flat Non-Leaded package) type semiconductor device in which part of a chip-mounted part and a plurality of leads is exposed from a lower surface of a seal, which forms a tetragonal planar shape, will be taken as a mode of a semiconductor package and explained.

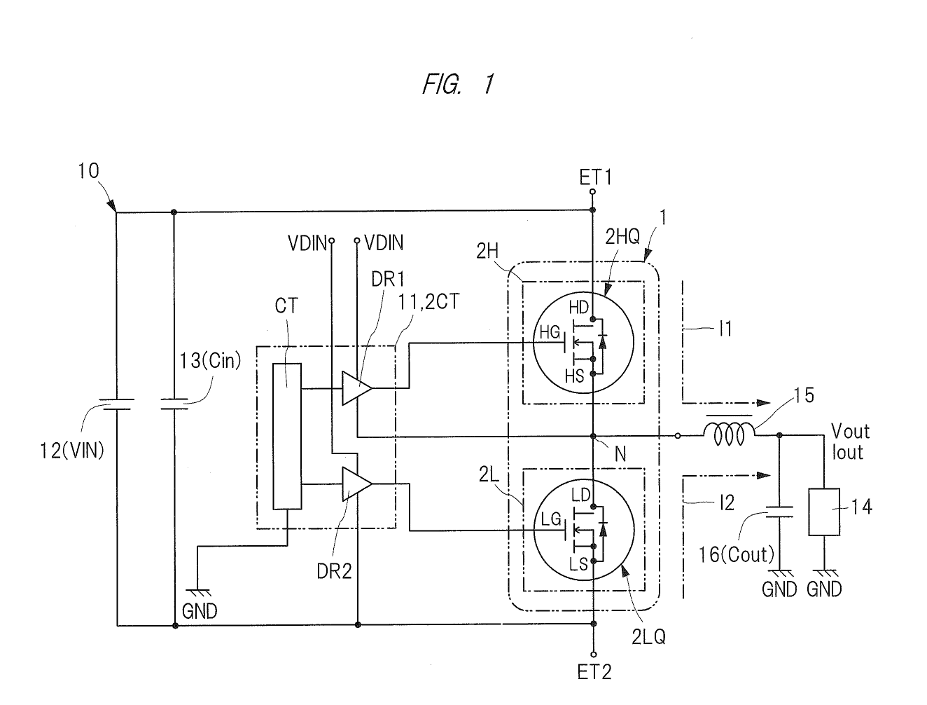

FIG. 1 is an explanatory diagram showing a configuration example of a power source circuit in which a semiconductor device explained in the present embodiment is incorporated. As an example of the power source circuit in which the semiconductor device of the present embodiment is incorporated, FIG. 1 shows a configuration example of a switching power-source circuit (for example, DC-DC converter).

A power source circuit 10 shown in FIG. 1 is a power source device which converts or adjusts electric power by utilizing the on/off time ratio (duty ratio) of semiconductor switching elements. In the example shown in FIG. 1, the power source circuit 10 is a DC-DC converter, which converts direct current to direct current of a different value. The power source circuit 10 like this is used as a power source circuit of an electronic device such as a desktop-type personal computer, a notebook-type personal computer, a server, or a game machine.

The power source circuit 10 has a semiconductor device 1, in which semiconductor switching elements are built, and a semiconductor device 11, which is provided with a control circuit CT which controls drive of the semiconductor device 1. The power source circuit 10 has an input power source 12 and an input capacitor 13, which is a power source which temporarily stores the energy (electric charge) supplied from the input power source 12 and supplies the stored energy to a main circuit of the power source circuit 10. The input capacitor 13 and the input power source 12 are parallely connected.

The power source circuit 10 has a coil 15, which is an element that supplies electric power to the output of the power source circuit 10 (input of a load 14), and an output capacitor 16, which is electrically connected between output wiring connecting the coil 15 and the load 14 and a terminal for supplying a reference potential (for example, ground potential GND). The coil 15 is electrically connected to the load 14 via the output wiring. Examples of the load 14 include a hard disk drive HDD, ASIC (Application Specific Integrated Circuit), and FPGA (Field Programmable Gate Array). Examples of the load 14 also include expansion cards (PCI CARD), memories (DDR memories, DRAM (Dynamic RAM), flash memories, etc.), and CPU (Central Processing Unit).

VIN shown in FIG. 1 represents an input power source, GND represents a reference potential (for example, ground potential which is 0 V), Iout represents output current, and Vout represents output voltage. Cin shown in FIG. 1 represents the input capacitor 13, and Cout 16 represents an output capacitor.

The semiconductor device 11 has two driver circuits DR1 and DR2 and the control circuit CT, which transmits controls signals to the driver circuits DR1 and DR2, respectively. The semiconductor device 1 has field-effect transistors for a high-side and a low-side as switching elements. Specifically, the semiconductor device 1 has a MOSFET (Metal Oxide Semiconductor Field Effect Transistor) 2HQ for the high side and a MOSFET 2LQ for the low side.

The above-described MOSFET is described as a term that widely represents a field-effect transistor having a structure in which a gate electrode consisting of an electrically-conductive material is disposed on a gate insulating film. Therefore, even when MOSFET is described, it does not exclude a gate insulating film other than an oxide film. Also, even if MOSFET is described, a gate electrode material other than metal such as polysilicon is not excluded.

The control circuit CT is a circuit which controls working of the MOSFETs 2HQ and 2LQ and consists of, for example, a PWM (Pulse Width Modulation) circuit. The PWM circuit compares a command signal and the amplitude of a triangular wave and outputs a PWM signal (control signal). The output voltages of the MOSFETs 2HQ and 2LQ (specifically, the power source circuit 10) (specifically, the ranges of voltage switch-on (on-time) of the MOSFETs 2HQ and 2LQ) are configured to be controlled by the PWM signal.

The output of the control circuit CT is electrically connected to the inputs of the driver circuits DR1 and DR2 via wiring formed on a semiconductor chip 2S of the semiconductor device 11. The outputs of the driver circuits DR1 and DR2 are electrically connected to a gate electrode 2HG of the MOSFET 2HQ and a gate electrode 2LG of the MOSFET 2LQ, respectively.

The driver circuits DR1 and DR2 are the circuits which control the potentials of the gate electrodes HG and LG of the MOSFETs 2HQ and 2LQ and control working of the MOSFETs 2HQ and 2LQ, respectively, in accordance with pulse-width modulation (Pulse Width Modulation: PWM) signals supplied from the control circuit CT. The output of the driver circuit DR1 of one side is electrically connected to the gate electrode HG of the MOSFET 2HQ. The output of the driver circuit DR2 of the other side is electrically connected to the gate electrode LG of the MOSFET 2LQ. The control circuit CT and the two driver circuits DR1 and DR2 are formed on, for example, the single semiconductor chip 2S. VDIN represents input power sources for the driver circuits DR1 and DR2.

The MOSFETs 2HQ and 2LQ, which are power transistors, are serially connected between a terminal (first power source terminal) ET1 for supplying a high potential (first power source potential) of the input power source 12 and a terminal (second power source terminal) ET2 for supplying a reference potential (second power source potential). The wiring which connects a source HS of the MOSFET 2HQ of the power source circuit 10 and a drain LD of the MOSFET 2LQ is provided with an output node N, which supplies an outputting power source potential to outside. The output node N is electrically connected to the coil 15 via the output wiring and is further electrically connected to the load 14 via the output wiring.

More specifically, the path of the source HS and the drain HD of the MOSFET 2HQ is serially connected between the high-potential-supplying terminal ET1 and the output node (output terminal) N of the input power source 12. The path of the source LS and the drain LD of the MOSFET 2LQ is serially connected between the output node N and the reference-potential-supplying terminal ET2. FIG. 1 shows parasitic diodes (internal diodes) at the MOSFETs 2HQ and 2LQ, respectively.

In the power source circuit 10, a power-source voltage is converted by alternately turning on/off the MOSFETs 2HQ and 2LQ while synchronizing them. More specifically, when the high-side MOSFET 2HQ is on, a current (first current) I1 flows from the terminal ET1 to the output node N through the MOSFET 2HQ. On the other hand, when the high-side MOSFET 2HQ is off, a current I2 flows because of the inverse voltage of the coil 15. A voltage drop can be reduced by turning on the low-side MOSFET 2LQ when the current I2 is flowing.

The MOSFET (first field-effect transistor, power transistor) 2HQ is a field-effect transistor for a high-side switch (high-potential side: first operating voltage; hereinafter, simply referred to as high side) and has a switching function for storing energy in the above-described coil 15. The high-side MOSFET 2HQ is formed on a semiconductor chip 2H different from the semiconductor chip 2S.

On the other hand, the MOSFET (second field-effect transistor, power transistor) 2LQ is a field-effect transistor for a low-side switch (low-potential side: second operating voltage; hereinafter, simply referred to as low side) and has a function to carry out rectification by reducing the resistance of the transistor in synchronization with the frequency from the control circuit CT. In other words, the MOSFET 2LQ is a transistor for rectification of the power source circuit 10.

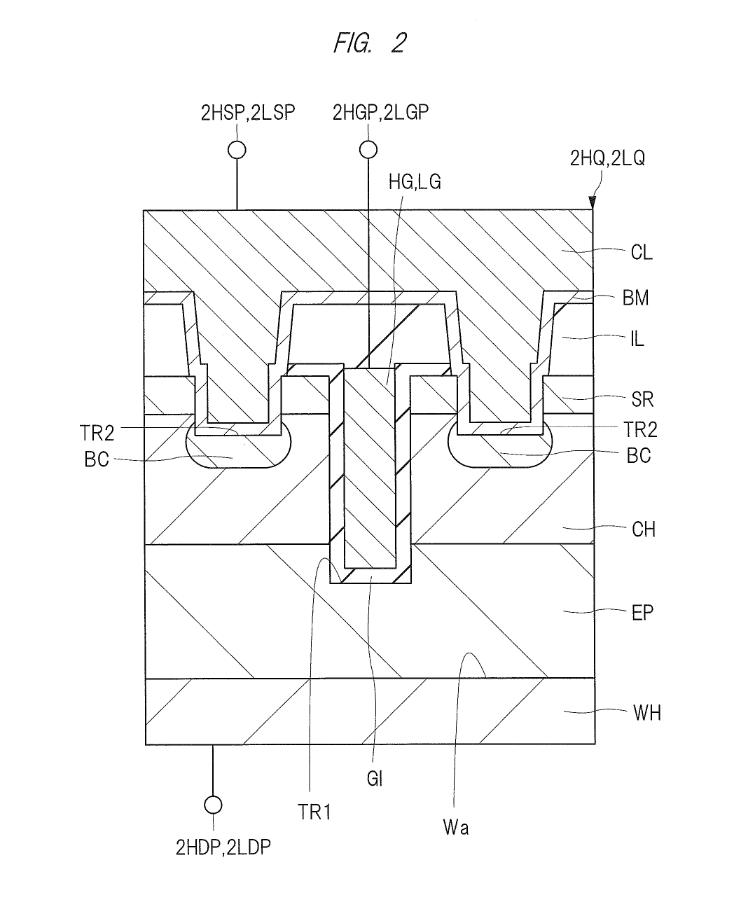

As shown in FIG. 2, the high-side MOSFET 2HQ and the low-side MOSFET 2LQ are formed, for example, by n-channel-type field-effect transistors. FIG. 2 is a main-part cross-sectional view showing an element structure example of the field-effect transistors shown in FIG. 1.

In the example shown in FIG. 2, for example, on a principal surface Wa of a semiconductor substrate WH consisting of n-type single-crystal silicon, an n⁻-type epitaxial layer EP is formed. The semiconductor substrate WH and the epitaxial layer EP constitute a drain region (drain 2HD or 2LD shown in FIG. 1) of the MOSFET 2HQ or 2LQ. The drain region is electrically connected to a drain electrode 2HDP or 2LDP formed in the back surface side of the semiconductor chip 2H or 2L shown in FIG. 1.

A channel formation region CH, which is a p⁻-type semiconductor region, is formed on the epitaxial layer EP, and source regions SR, which are n⁺-type semiconductor regions, are formed on the channel formation region CH. A trench (opening, groove) TR1, which penetrates through the channel formation region CH from the upper surface of the source region SR and reaches the inside of the epitaxial layer EP, is formed.

Moreover, a gate insulating film GI is formed on the inner wall of the trench TR1. Moreover, on the gate insulating film GI, the gate electrode HG or LG, which is stacked so as to bury the trench TR1, is formed. The gate electrode HG or LG is electrically connected to a gate electrode pad 2HGP or 2LGP of the semiconductor chip 2H or 2L shown in FIG. 1 via unshown outgoing wiring.

Moreover, adjacent to the trench TR1, in which the gate electrode HG or LG is buried, with the source regions SR therebetween, body-contact trenches (openings, grooves) TR2 are formed. In the example shown in FIG. 2, the trenches TR2 are formed in both sides adjacent to the trench TR1. Moreover, at the bottom of each of the trenches TR2, a body-contact region BC, which is a p⁺-type semiconductor region, is formed. By providing the body-contact region BC, the base resistance of a parasitic bipolar transistor having the source region SR as an emitter region, the channel formation region CH as a base region, and the epitaxial layer EP as a collector region can be reduced.

In the example shown in FIG. 2, the position of the upper surface of the body-contact region BC is configured to be positioned below (the lower-surface side of the channel formation region CH) the lower surface of the source region SR by forming the body-contact trench TR2. However, although illustration is omitted, as a modification example, the body-contact region BC may be formed at a height approximately the same as the source region SR without forming the body-contact trench TR2.

Moreover, an insulating film IL is formed on the source regions SR and the gate electrode HG or LG. Moreover, a barrier conductor film BM is formed on the insulating film IL and in the region including the inner walls of the body-contact trench TR2. Moreover, wiring CL is formed on the barrier conductor film BM. The wiring CL is electrically connected to a source electrode pad 2HSP or 2LSP formed on the surface of the semiconductor chip 2H or 2L shown in FIG. 1.

Moreover, the wiring CL is electrically connected to both of the source regions SR and the body-contact regions BC via the barrier conductor film BM. Thus, the source regions SR and the body-contact regions BC are at the same potential. By virtue of this, turning-on of the above-described parasitic bipolar transistor due to the potential difference between the source region SR and the body-contact region BC can be suppressed.

Moreover, in each of the MOSFETs 2HQ and 2LQ, the drain region and the source region SR are disposed with the channel formation region CH therebetween in the thickness direction; therefore, a channel is formed in the thickness direction (hereinafter, referred to as a vertical channel structure). In this case, the element occupied area in a plan view can be reduced compared with a field-effect transistor in which a channel is formed along a principal surface Wa. Therefore, the planar size of the semiconductor chip 2H (see FIG. 1) can be reduced by applying the above-described vertical channel structure to the high-side MOSFET 2HQ.

Moreover, in the case of the above-described vertical channel structure, since the channel width per unit area can be increased in the plan view, on-resistance can be reduced. Particularly, the on-time in operation (the time taken while voltage is applied) of the low-side MOSFET 2LQ is longer than the on-time of the high-side MOSFET 2HQ, and loss due to on-resistance seems to be larger than switching loss. Therefore, the on-resistance of the low-side field-effect transistor can be reduced by applying the above-described vertical channel structure to the low-side MOSFET 2LQ. It is preferred in a point that voltage conversion efficiency can be improved as a result even when the current that flows to the power source circuit 10 shown in FIG. 1 is increased.

FIG. 2 is a drawing showing the element structure of the field-effect transistor. On the semiconductor chips 2H and 2L shown in FIG. 1, a plurality of field-effect transistors having, for example, the element structures like that shown in FIG. 2 are parallely connected. Thus, a power MOSFET through which large current that exceeds, for example, 1 ampere flows can be formed.

<Semiconductor Device>

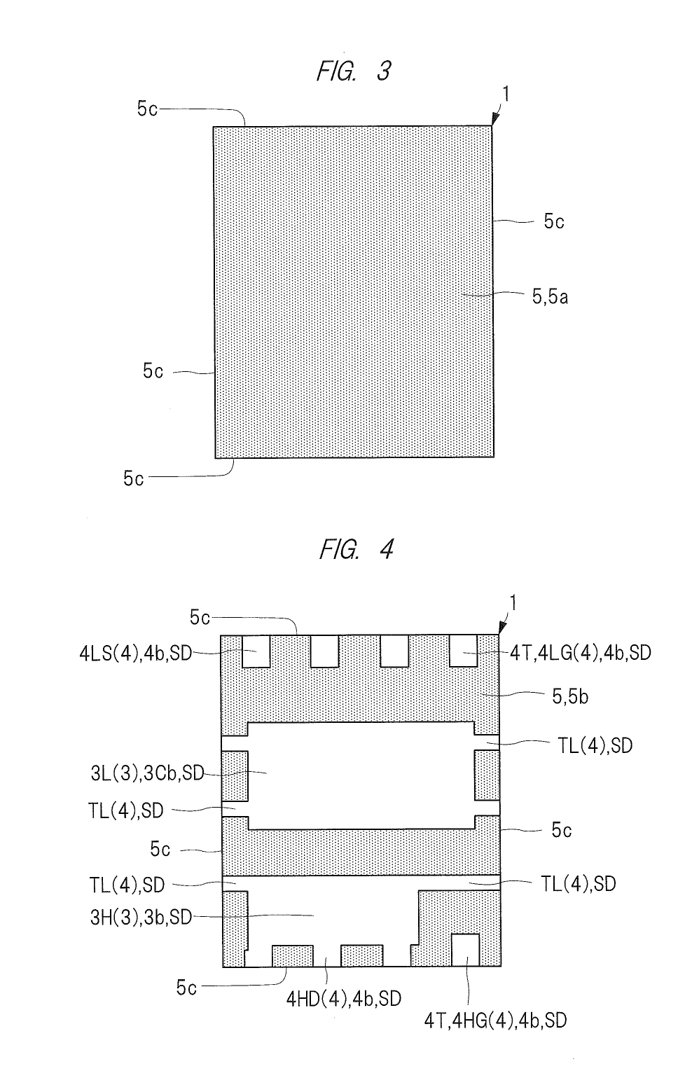

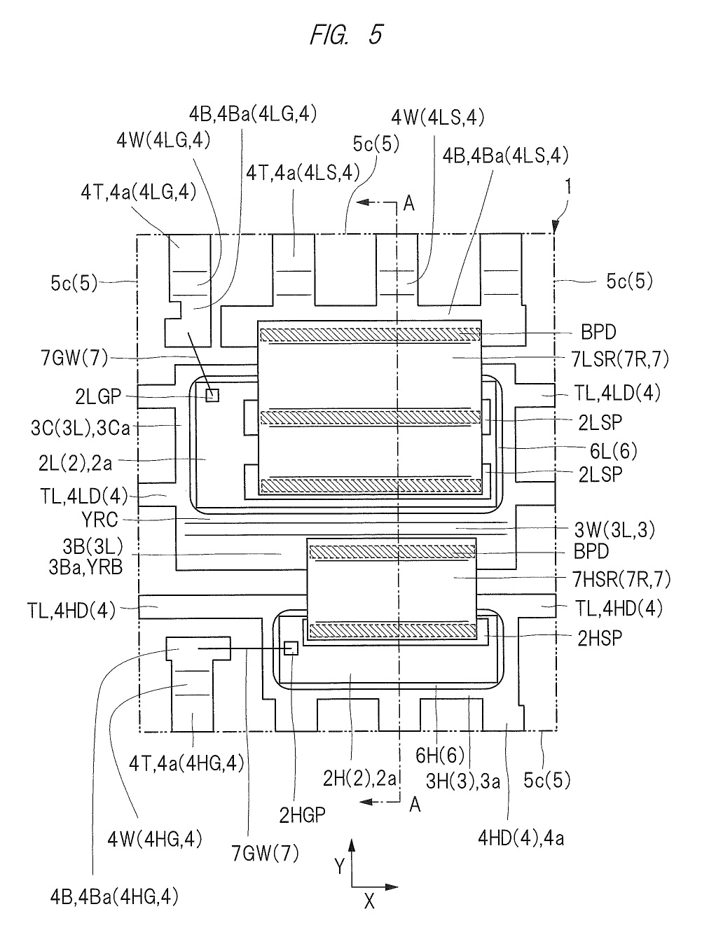

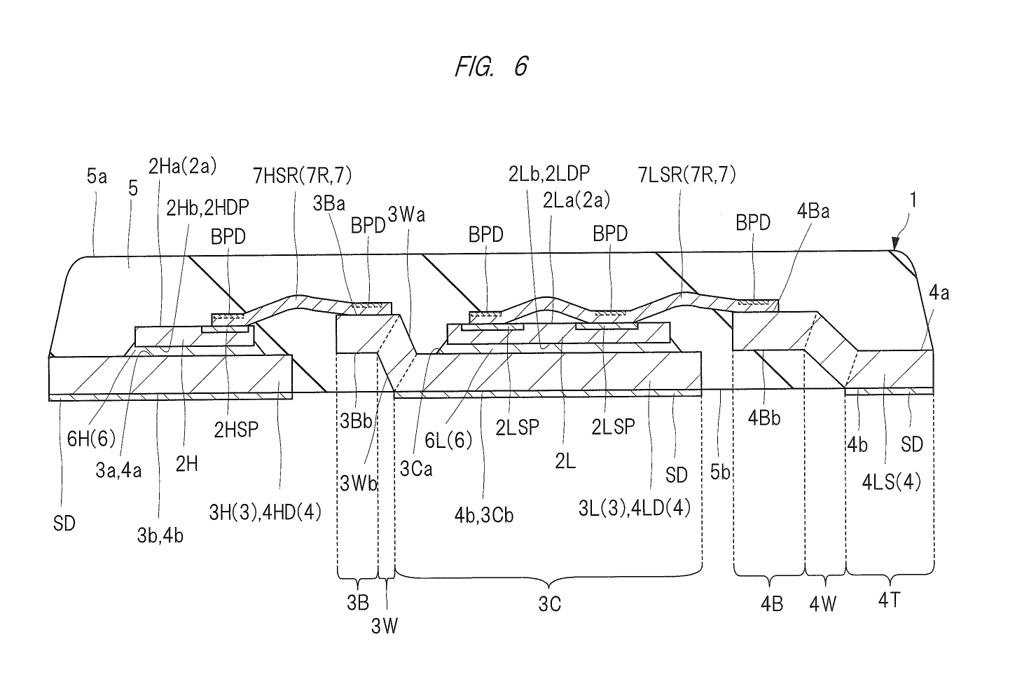

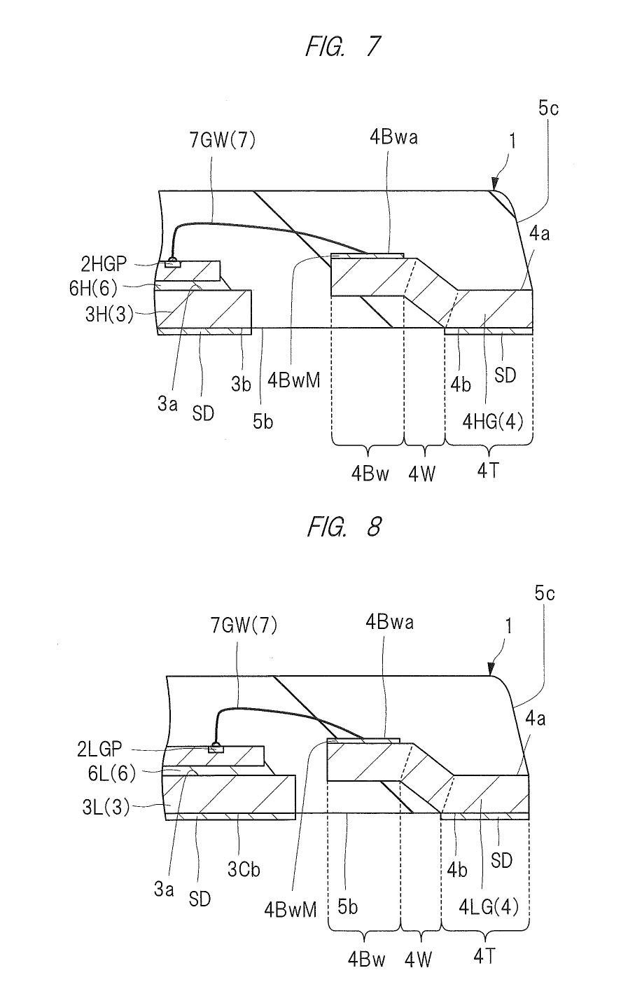

Next, a package structure of the semiconductor device 1 shown in FIG. 1 will be explained. FIG. 3 is a top view of the semiconductor device shown in FIG. 1. FIG. 4 is a bottom view of the semiconductor device shown in FIG. 3. FIG. 5 is a plan view showing an internal structure of the semiconductor device in a state in which a seal shown in FIG. 3 is removed. FIG. 6 is a cross-sectional view taken along a line A-A of FIG. 5. FIG. 7 is an enlarged cross-sectional view showing a connection state of a gate electrode of a high-side semiconductor chip and a lead shown in FIG. 5. FIG. 8 is an enlarged cross-sectional view showing a connection state of a gate electrode of a low-side semiconductor chip and a lead shown in FIG. 5. In FIG. 5 and FIG. 6, in order to facilitate understanding of the positions of pressure-bonding marks PBD formed when metal ribbons 7R are joined by a later-described bonding tool, they are schematically shown with hatching surrounded by dotted lines.

As shown in FIG. 3 to FIG. 8, the semiconductor device 1 has a plurality of semiconductor chips 2 (see FIG. 5 and FIG. 6), a plurality of tabs (chip-mounting parts, die pads) 3 on which the plurality of semiconductor chips 2 are mounted, respectively (see FIG. 4 to FIG. 6), and a plurality of leads 4 serving as external terminals (see FIG. 4 to FIG. 6). Moreover, the plurality of semiconductor chips 2 are sealed at a time by a single seal (resin body) 5. The separated distance between the mutually adjacent semiconductor chips 2 can be reduced by mounting the plurality of semiconductor chips 2 in the single seal 5 in this manner; therefore, a packaging area can be reduced than a case in which the plurality of semiconductor chips 2 are separately sealed.

Moreover, the plurality of semiconductor chips 2 include the semiconductor chip 2H, on which the MOSFET 2HQ which is the high-side switching element of the power source circuit 10 explained by using FIG. 1 is formed. As shown in FIG. 6, the semiconductor chip 2H has a top surface 2Ha and a back surface 2Hb positioned on the opposite side of the top surface 2Ha. Also, as shown in FIG. 5, on the top surface 2Ha of the semiconductor chip 2H, the source electrode pad (first electrode pad) 2HSP corresponding to the source HS shown in FIG. 1 and the gate electrode pad (third electrode pad) 2HGP corresponding to the gate electrode HG shown in FIG. 1 are formed. On the other hand, as shown in FIG. 6, on the back surface 2Hb of the semiconductor chip 2H, the drain electrode 2HDP corresponding to the source HS shown in FIG. 1 is formed. In the example shown in FIG. 6, the entire back surface 2Hb of the semiconductor chip 2H serves as the drain electrode 2HDP.

The plurality of semiconductor chips 2 also include the semiconductor chip 2L on which the MOSFET 2LQ, which is the low-side switching element of the power source circuit 10 explained by using FIG. 1, is formed. As shown in FIG. 6, the semiconductor chip 2L has a top surface 2La and a back surface 2Lb positioned on the opposite side of the top surface 2La. Moreover, as shown in FIG. 5, on the top surface 2La of the semiconductor chip 2L, the source electrode pad 2LSP (second electrode pad) corresponding to the source LS shown in FIG. 1 and the gate electrode pad 2LGP (fourth electrode pad) corresponding to the gate electrode LG shown in FIG. 1 are formed. On the other hand, as shown in FIG. 6, on the back surface 2Lb of the semiconductor chip 2L, the drain electrode 2LDP corresponding to the source LS shown in FIG. 1 is formed. In the example shown in FIG. 6, the entire back surface 2Lb of the semiconductor chip 2L is the drain electrode 2LDP.

Moreover, in the example shown in FIG. 5, the planar size of the semiconductor chip 2L (the area of the top surface 2La) is larger than the planar size of the semiconductor chip 2H (the area of the top surface 2Ha). As explained by using FIG. 1 and FIG. 2, the on-resistance of the low-side field-effect transistor can be reduced by increasing the planar size of the semiconductor chip 2L on which the low-side MOSFET 2LQ is formed. This is preferred in a point that the voltage conversion efficiency can be improved as a result even if the current that flows to the power source circuit 10 shown in FIG. 1 is increased.

Moreover, as shown in FIG. 5 and FIG. 6, the semiconductor device 1 has a tab (chip-mounting part) 3H on which the semiconductor chip 2H is mounted. The tab 3H has a chip-mounting surface (upper surface) 3a, on which the semiconductor chip 2H is mounted via an electrically-conductive adhesive material (electrically-conductive member) 6H, and a lower surface (packaging surface) 3b on the opposite side of the chip-mounting surface 3a.

As shown in FIG. 5, the tab 3H is integrally formed with leads 4HD corresponding to the terminals electrically connected to the terminal ET1 shown in FIG. 1. Moreover, as shown in FIG. 6, the drain electrode 2HDP formed on the back surface 2Hb of the semiconductor chip 2H is electrically connected to the tab 3H via the electrically-conductive adhesive material 6H. Thus, the tab 3H has both of the function as a chip-mounting part on which the semiconductor chip 2H is mounted and the function as the leads 4HD which are the terminals of the drain HD of the high-side MOSFET 2HQ shown in FIG. 1.

Moreover, as shown in FIG. 4 and FIG. 6, the lower surface 3b of the tab 3H (lower surfaces 4b of the leads 4HD) are exposed from the seal 5 from a lower surface 5b of the seal 5. A metal film (exterior plating film) SD for improving the wettability of a solder material serving as a joining material is formed on the exposed surface of the tab 3H when the semiconductor device 1 is packaged on an unshown packaging board. The heat dissipation efficiency of the heat generated at the semiconductor chip 2H can be improved by exposing the lower surface 3b of the tab 3H, which is serving as the chip-mounting part on which the semiconductor chip 2H is mounted, from the seal 5. Moreover, the cross-sectional area of the conduction path through which current flows can be increased by exposing the lower surface 3b of the tab 3H serving as the leads 4HD, which are external terminals, from the seal 5. Therefore, the impedance component in the conduction path can be reduced.

Moreover, as shown in FIG. 5 and FIG. 6, the semiconductor device 1 has a tab (chip-mounting part) 3L, on which the semiconductor chip 2L is mounted. The tab 3L consists of below three parts. First, the tab 3L is provided with a chip-connecting part 3C to which the semiconductor chip 2L is fixed and serving as a part electrically connected to the semiconductor chip 2L. As shown in FIG. 6, the chip-connecting part 3C of the tab 3L has a chip-mounting surface (upper surface) 3Ca, on which the semiconductor chip 2L is mounted via an electrically-conductive adhesive material (electrically-conductive member) 6L, and a lower surface (packaging surface) 3Cb on the opposite side of the chip-mounting surface 3Ca.

Moreover, the tab 3L is provided with a ribbon-connecting part 3B which is a part joined with and electrically connected to one end of a metal ribbon (electrically-conductive member, strip-shaped metal member) 7HSR. As shown in FIG. 6, the ribbon-connecting part 3B has a ribbon-connecting surface (connecting surface, upper surface) 3Ba, to which the metal ribbon 7HSR is connected, and a lower surface 3Bb on the opposite side of the ribbon-connecting surface 3Ba.

Moreover, the tab 3L is provided with a bent part (tilted part) 3W, which is a part at which the height of the ribbon-connecting surface 3Ba of the ribbon-connecting part 3B becomes higher than the height of the chip-mounting surface 3Ca of the chip-connecting part 3C. The bent part 3W is disposed between the chip-connecting part 3C and the ribbon-connecting part 3B. Moreover, as shown in FIG. 6, the bent part 3W has an upper surface 3Wa continued to the ribbon-connecting surface 3Ba of the ribbon-connecting part 3B and the chip-mounting surface 3Ca of the chip-connecting part 3C. Moreover, the bent part 3W has a lower surface 3Wb continued to the lower surface 3Bb of the ribbon-connecting part 3B and the lower surface 3Ca of the chip-connecting part 3C.

The bent part 3W is formed by subjecting a metal plate to bending, and the upper surface 3Wa and the lower surface 3Wb of the bent part 3W are tilted surfaces, respectively. Moreover, the bent part 3W is tilted so that the height of the ribbon-connecting surface 3Ba of the ribbon-connecting part 3B becomes higher than the height of the chip-mounting surface 3Ca of the chip-connecting part 3C. Therefore, in a plan view, the area of the lower surface 3Cb of the chip-connecting part 3C is larger than the area of the chip-mounting surface 3Ca. On the other hand, the area of the ribbon-connecting surface 3Ba of the ribbon-connecting part 3B is larger than the area of the lower surface 3Bb of the ribbon-connecting part 3B.

As shown in FIG. 6, the drain electrode 2LDP formed on the back surface 2Lb of the semiconductor chip 2L is electrically connected to the tab 3L via the electrically-conductive adhesive material 6L. Thus, the tab 3L has both of the function as a chip-mounting part on which the semiconductor chip 2L is mounted and the function as leads 4LD which are external terminals corresponding to the output node N between the drain LD of the low-side MOSFET 2LQ and the source HS of the high-side MOSFET 2HQ shown in FIG. 1.

Moreover, as shown in FIG. 4 and FIG. 6, the lower surface 3Cb of the tab 3L (the part corresponding to the lower surfaces 4b of the leads 4LD) is exposed from the seal 5 at the lower surface 5b of the seal 5. Moreover, a metal film (exterior plating film) SD for improving the wettability of the solder material serving as a joining material is formed on the exposed surface of the tab 3L when the semiconductor device 1 is packaged on an unshown packaging board. The heat dissipation efficiency of the heat generated at the semiconductor chip 2L can be improved by exposing the lower surface 3Cb of the tab 3L, which is serving as the chip-mounting part on which the semiconductor chip 2L is mounted, from the seal 5. Particularly, as described above, the operating-time on-time (the time during which voltage is applied) of the low-side semiconductor chip 2L is longer than the on-time of the high-side semiconductor chip 2H. Thus, the amount of heat generation of the semiconductor chip 2L is larger than that of the semiconductor chip 2H. Therefore, as shown in FIG. 4, it is preferred that the area of the exposed surface of the tab 3L be larger than the area of the exposed surface of the tab 3H.

Moreover, the cross-sectional area of the conduction path through which current flows can be increased by exposing the lower surface 3Cb of the tab 3L serving as the leads 4LD, which are external terminals, from the seal 5. Therefore, the impedance component in the conduction path can be reduced. Particularly, the leads 4LD are the external terminals corresponding to the output node N explained by using FIG. 1. Therefore, this is preferred in a point that the electric power loss of output wiring can be directly reduced by reducing the impedance component of the conduction paths connected to the leads 4LD.

The electrically-conductive adhesive materials 6H and 6L shown in FIG. 5 and FIG. 6 are electrically-conductive members (die-bond material) 6 for respectively fixing the semiconductor chips 2H and 2L onto the tabs 3H and 3L and electrically connecting the semiconductor chips 2H and 2L to the tabs 3H and 3L. As the electrically-conductive adhesive materials 6H and 6L, for example, an electrically-conductive resin material called so-called silver (Ag) paste containing electrically-conductive particles such as a plurality (a number) of silver (Ag) particles in a thermo-setting resin or a solder material can be used.

When the semiconductor device 1 is to be packaged on an unshown packaging board (mother board), for example, a solder material is used as a joining material which electrically connects the plurality of leads 4 of the semiconductor device 1 and unshown terminals in the packaging board side to each other. The metal film SD, which is an exterior plating film consisting of, for example, solder, shown in FIG. 5 and FIG. 6 is formed on each of the joining surfaces of the terminals of the semiconductor device 1 from the viewpoint of improving the wettability of the solder material serving as the joining material.

In a step of packaging the semiconductor device 1, heating treatment called reflow treatment is carried out in order to melt an unshown solder material and join the leads 4 with the unshown terminals of the packaging board side, respectively. In a case in which the electrically-conductive adhesive materials 6H and 6L, in which electrically-conductive particles are mixed in resin, are used as the electrically-conductive members 6, the electrically-conductive adhesive materials 6H and 6L are not melted even if the treatment temperature of the above-described reflow treatment is arbitrarily set. Therefore, this is preferred in a point that troubles caused when the electrically-conductive members 6 at the joining parts of the semiconductor chips 2H and 2L and the tabs 3H and 3L are remelted upon packaging of the semiconductor device 1 can be prevented.

On the other hand, in a case in which a solder material is used as the electrically-conductive members 6, which join the semiconductor chips 2H and 2L and the tabs 3H and 3L, it is preferred to use a material having a melting point higher than the melting point of the joining material which is used in packaging in order to suppress remelting upon packaging of the semiconductor device 1. The selection of material is restricted in this manner in the case in which the solder material is used as the electrically-conductive members 6, which are die-bond materials; however, this is preferred in a point that electrical connection reliability can be improved compared with the case in which the electrically-conductive adhesive material is used.

As shown in FIG. 4 and FIG. 5, the tab 3H and the tab 3L are supported by the plurality of leads 4 including suspension leads TL. The suspension leads TL are supporting members for fixing the tabs 3H and 3L to a frame part of a lead frame in a manufacturing process of the semiconductor device 1.

Moreover, as shown in FIG. 5 and FIG. 6, the source electrode pad 2HSP and the leads 4LD of the semiconductor chip 2H are electrically connected via the metal ribbon (electrically-conductive member, strip-shaped metal member) 7HSR. The metal ribbon 7HSR is an electrically-conductive member corresponding to wiring which connects the source HS of the high-side MOSFET 2HQ and the output node N shown in FIG. 1 and consists of, for example, aluminum (Al).

Specifically, as shown in FIG. 6, a first end of the metal ribbon 7HSR is joined with the source electrode pad 2HSP of the semiconductor chip 2H. On the other hand, a second end which is on the opposite side of the above-described first end of the metal ribbon 7HSR is joined with the ribbon-connecting surface (connecting surface, upper surface) 3Ba of the ribbon-connecting part 3B formed in part of the tab 3L, which also serve as the function as the lead 4LD.

At a joining part of the metal ribbon 7HSR and the source electrode pad 2HSP, a metal member (for example, aluminum) exposed at the uppermost surface of the source electrode pad 2HSP and, for example, an aluminum ribbon constituting the metal ribbon 7HSR form metal bonding and are joined with each other. On the other hand, at the joining part of the metal ribbon 7HSR and the ribbon-connecting surface 3Ba of the ribbon-connecting part 3B, for example, copper (Cu) constituting a base material is exposed, and the exposed surface of the copper (Cu) and, for example, an aluminum ribbon constituting the metal ribbon 7HSR form metal bonding and are joined with each other. Although details will be described later, the joining parts as described above can be formed by applying ultrasonic waves from a bonding tool when the metal ribbon 7HSR is joined.

As shown in FIG. 5, in the plan view, the ribbon-connecting surface 3Ba of the ribbon-connecting part 3B is positioned between the semiconductor chip 2H and the semiconductor chip 2L. Moreover, as shown in FIG. 6, the height of the ribbon-connecting surface 3Ba of the ribbon-connecting part 3B is positioned at a position higher than the chip-mounting surface 3Ca of the chip-connecting part 3C of the tab 3L. In the example shown in FIG. 5 and FIG. 6, the bent part (or the tilted part) 3W, which is provided so that the height of the ribbon-connecting surface 3Ba becomes higher than the height of the chip-mounting surface 3Ca, is provided between the ribbon-connecting surface 3Ba of the ribbon-connecting part 3B and the chip-mounting surface 3Ca of the chip-connecting part 3C. Therefore, the lower surface (the lower surface immediately below the ribbon-connecting surface 3Ba) 3Bb of the ribbon-connecting part 3B is covered with the seal 5. In other words, the ribbon-connecting part 3B of the tab 3L is sealed with the seal 5. Since part of the tab 3L is sealed with the seal 5 in this manner, the tab 3L does not easily fall from the seal 5.

Moreover, the shape for causing the lower surface (the lower surface immediately below the ribbon-connecting surface 3Ba) 3Bb of the ribbon-connecting part 3B to be covered with the seal 5 has various modification examples such as a method of subjecting the tab 3L to bending and a method of carrying out etching treatment. The example shown in FIG. 5 and FIG. 6 employs a method of subjecting part of the tab 3L to bending. Therefore, the thickness of the ribbon-connecting part 3B has the same thickness as the thickness of the chip-connecting part 3C of the tab 3L. In other words, in the thickness direction of the tab 3L, the thickness from the ribbon-connecting surface 3Ba to the lower surface immediately below the ribbon-connecting surface 3Ba is equal to the thickness from the chip-mounting surface 3Ca of the chip-connecting part 3C to the lower surface 3Cb immediately below the chip-mounting surface 3Ca. In the example shown in FIG. 6, each of the thickness of the ribbon-connecting part 3B and the thickness of the chip-connecting part 3C of the tab 3L is about 200 μm to 250 μm. The method of subjecting the tab 3L to bending in this manner is preferred in a point that it can be easily processed in the stage of manufacturing the lead frame.

Moreover, as shown in FIG. 5 and FIG. 6, the semiconductor device 1 has a lead (plate-shaped lead member) 4LS, which is an external terminal electrically connected to the semiconductor chip 2L. The lead 4LS has a ribbon-connecting part (connecting part) 4B, which connects a metal ribbon 7LSR, and a terminal part 4T serving as an external terminal when the semiconductor device 1 is packaged on the unshown packaging board. Moreover, the terminal part 4T has a lower surface 4b, which is a packaging surface, and an upper surface 4a, which is positioned on the opposite side of the lower surface 4b.

Moreover, as shown in FIG. 5 and FIG. 6, the source electrode pad 2LSP of the semiconductor chip 2L and the lead 4LS are electrically connected to each other via the metal ribbon (electrically-conductive member, strip-shaped metal member) 7LSR. The metal ribbon 7LSR is an electrically-conductive member corresponding to the wiring which connects the source LS of the low-side MOSFET 2LQ and the terminal ET2 shown in FIG. 1 and consists of, for example, aluminum (Al) as well as the above-described metal ribbon 7HSR.

Specifically, as shown in FIG. 6, a first end of the metal ribbon 7LSR is joined with the source electrode pad 2LSP of the semiconductor chip 2L. On the other hand, a second end on the opposite side of the above-described first end of the metal ribbon 7LSR is joined with a ribbon-connecting surface (connecting surface, upper surface) 4Ba of the ribbon-connecting part 4B formed in part of the lead 4LS. In the example shown in FIG. 6, the source electrode pad 2LSP of the semiconductor chip 2L is formed to be separated into a plurality of parts (for example, 2 parts). Therefore, the first end of the metal ribbon 7LSR is joined with the source electrode pad 2LSP disposed in the semiconductor chip 2H side among the plurality of source electrode pads 2LSP, and part between both ends of the metal ribbon 7LSR is joined with the other source electrode pad 2LSP.

At the joining part of the metal ribbon 7LSR and the source electrode pad 2LSP, a metal member (for example, aluminum) exposed at the uppermost surface of the source electrode pad 2HSP and, for example, an aluminum ribbon constituting the metal ribbon 7HSR form metal bonding and are joined with each other. On the other hand, at the joining part of the metal ribbon 7LSR and the ribbon-connecting surface 3Ba of the ribbon-connecting part 3B, for example, copper (Cu) constituting a base material is exposed, and the exposed surface of the copper (Cu) and, for example, an aluminum ribbon constituting the metal ribbon 7LSR form metal bonding and are joined with each other. Although details will be described later, the joining parts as described above can be formed by applying ultrasonic waves from a bonding tool when the metal ribbon 7LSR is joined.

Moreover, in the example shown in FIG. 5 and FIG. 6, the semiconductor chip 2L is disposed between the ribbon-connecting part 4B of the lead 4LS and the ribbon-connecting part 3B of the tab 3L. Moreover, as shown in FIG. 6, the height of the ribbon-connecting surface 4Ba of the ribbon-connecting part 4B is positioned at a position higher than the upper surface 4a positioned on the opposite side of the lower surface 4b, which is the packaging surface of the lead 4LS. Specifically, between the ribbon-connecting surface 4Ba of the ribbon-connecting part 4B and the upper surface 4a of the terminal part 4T, a bent part (or a tilted part) 4W provided so that the height of the ribbon-connecting surface 4Ba becomes higher than the height of the upper surface 4a of the terminal part 4T is provided. Therefore, the lower surface 4Bb of the ribbon-connecting part 4B is covered with the seal 5. In other words, the ribbon-connecting part 4B of the lead 4LS is sealed with the seal 5. Since part of the lead 4LS is sealed with the seal 5 in this manner, the lead 4LS does not easily fall from the seal 5. As a result, the electrical connection reliability of the semiconductor device 1 can be improved.

Moreover, as shown in FIG. 5 and FIG. 7, adjacent to the tab 3H, a lead 4HG, which is an external terminal electrically connected to the gate electrode pad 2HGP of the semiconductor chip 2H, is disposed. The lead 4HG is provided to be separated from the tab 3H. Moreover, as shown in FIG. 5 and FIG. 8, adjacent to the tab 3L, a lead 4LG, which is an external terminal electrically connected to the gate electrode pad 2LGP of the semiconductor chip 2L, is disposed. The lead 4LG is provided to be separated from the tab 3L.

Moreover, as shown in FIG. 7 and FIG. 8, each of the leads 4HG and 4LG has a wire connecting part 4Bw, which is a bonding region joined with a wire 7GW, and a terminal part 4T serving as an external terminal when the semiconductor device 1 is packaged on the unshown packaging board. Moreover, as shown in FIG. 7 or FIG. 8, the height of a wire connecting surface 4Bwa of the wire connecting part 4Bw is positioned at a position higher than the upper surface 4a positioned on the opposite side of the lower surface 4b, which is the packaging surface of the lead 4HG or 4LG. Specifically, between the wire connecting surface 4Bwa of the wire connecting part 4Bw and the upper surface 4a of the terminal part 4T, a bent part (or a tilted part) 4W provided so that the height of the wire connecting surface 4Bwa becomes higher than the height of the upper surface 4a of the terminal part 4T is provided. Therefore, as well as the above-described lead 4LS, the wire connecting part 4Bw of each of the leads 4HG and 4LG is sealed with the seal 5. Since part of the leads 4HG and 4LG is sealed with the seal 5 in this manner, the leads 4HG and 4LG do not easily fall from the seal 5. As a result, the electrical connection reliability of the semiconductor device 1 can be improved.

Meanwhile, the leads 4HG and 4LG and the gate electrode pads 2HGP and 2LGP are respectively electrically connected to respective output terminals of the driver circuits DR1 and DR2 shown in FIG. 1. Moreover, the signals which control the potentials of the gate electrodes HG and LG of the MOSFETs 2HQ and 2LQ shown in FIG. 2 are supplied to the leads 4HG and 4LG and the gate electrode pads 2HGP and 2LGP. Therefore, compared with the other leads 4 (the leads 4HD, 4LD, and 4LS shown in FIG. 5), the current that flows therethrough is comparatively small. Therefore, the lead 4HG or 4LG and the gate electrode pad 2HGP or 2LGP are electrically connected via the wire (electrically-conductive member) 7GW, which is a thin metal wire.

For example, in the example shown in FIG. 7 and FIG. 8, a metal film (for example, an aluminum film or a gold film) formed on the uppermost surface of the gate electrode pad 2HGP or 2LGP is joined with a first end (for example, a first bonding part) of the wire 7GW consisting of, for example, gold (Au). Moreover, on the wire connecting surface 4Bwa of the wire connecting part 4Bw of the lead 4HG or 4LG, a metal film 4BwM, which can improve the connection strength of the wire 7GW and the base material of the lead 4HG or 4LG, is formed. A second end (for example, a second bonding part) on the opposite side of the above-described first end of the wire 7GW is electrically connected to the base material of the lead 4HG or 4LG via the metal film 4BwM. The base material of the leads 4HG and 4LG consists of, for example, copper (Cu), and the metal film 4BwM consists of, for example, silver (Ag).

Moreover, as shown in FIG. 6, the semiconductor chips 2H and 2L, part (the chip-mounting-surface side of the chip-connecting part 3C and the ribbon-connecting part 3B) of the tabs 3H and 3L, the ribbon-connecting part 4B of the lead 4LS, and the metal ribbons 7HSR and 7LSR are sealed with the seal 5. Moreover, as shown in FIG. 7 and FIG. 8, part (the upper-surface-4a side and the wire connecting part 4Bw) of the leads 4HG and 4LG and the plurality of wires 7GW are sealed with the seal 5.

The seal 5 is a resin body which seals the plurality of semiconductor chips 2, the plurality of metal ribbons 7HSR and 7LSR, and the plurality of wires 7GW and has an upper surface 5a (see FIG. 3 and FIG. 6) and the lower surface (packaging surface) 5b (see FIG. 4 and FIG. 6) positioned on the opposite side of the upper surface 5a. Moreover, as shown in FIG. 3, FIG. 4, and FIG. 5, the seal 5 forms a tetragon in a plan view and has four lateral surfaces 5c.

The seal 5, for example, mainly consists of a thermosetting resin such as an epoxy-based resin. Moreover, in order to improve the characteristics (for example, expansion characteristics depending on thermal influence) of the seal 5, for example, filler particles such as silica (silicon dioxide; SiO₂) particles are mixed in a resin material in some cases.

<About Adhesiveness of Tabs and Seal>

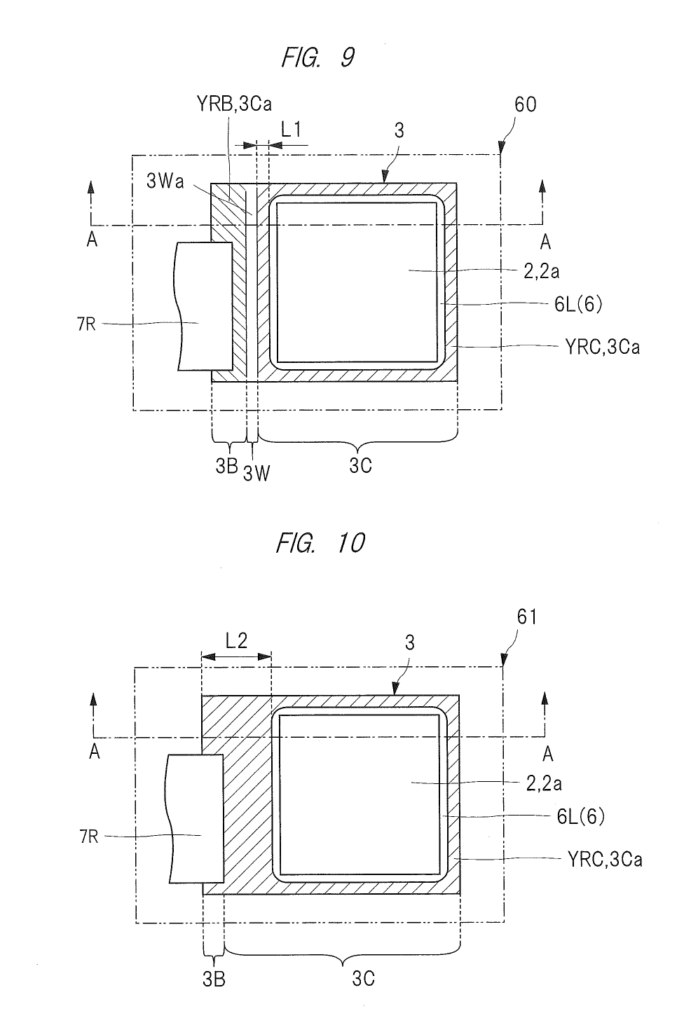

Meanwhile, in a case in which the electrodes formed on the back surface of the semiconductor chip 2 and the tabs 3 are electrically connected to each other like the present embodiment, it is preferred to improve the adhesiveness between the seal 5 and the tabs 3 to prevent or suppress occurrence of peel-off from the viewpoint of reliability improvement. Hereinafter, by using FIG. 9 to FIG. 12, the mechanism of peel-off occurrence will be explained according to the results studied by the inventor of the present application.

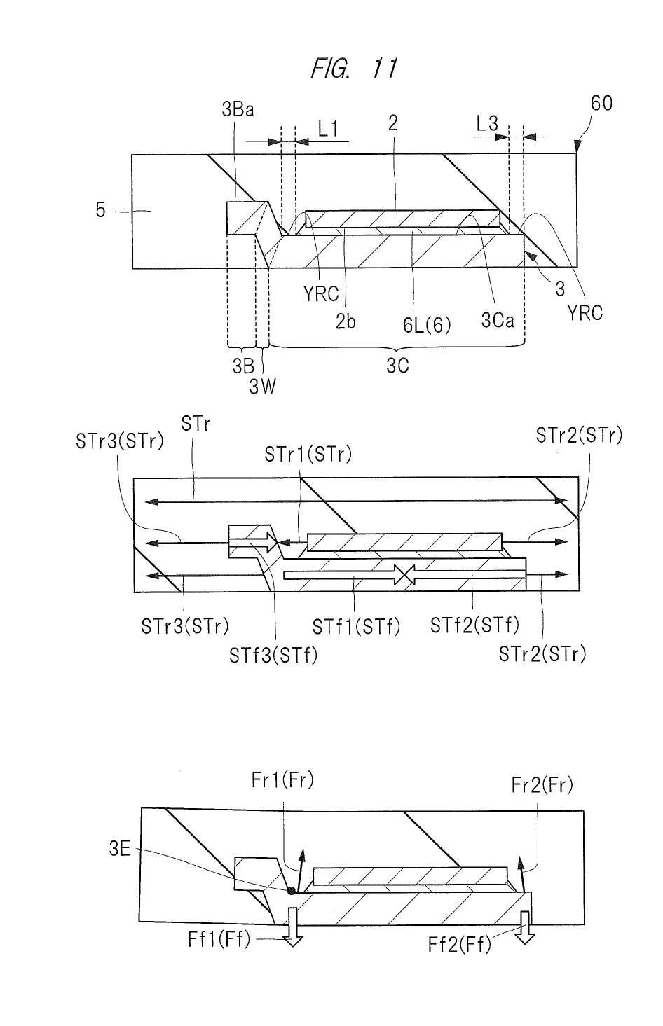

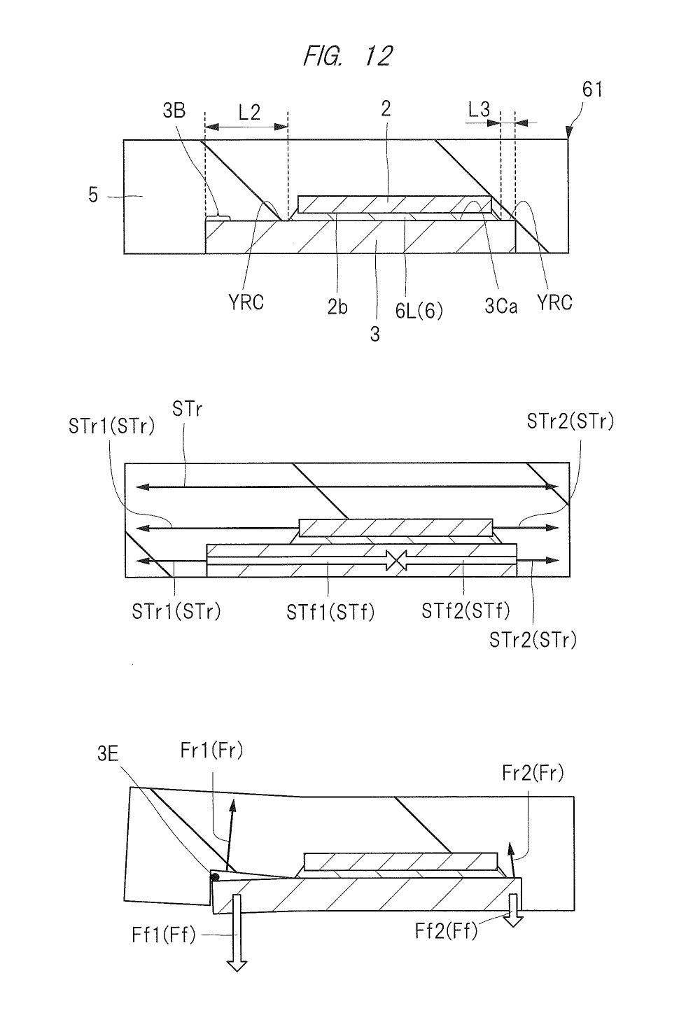

FIG. 9 is a main-part plan view of a semiconductor device formed so that the height of a ribbon-connecting surface is higher than a chip-mounting surface as well as a low-side tab shown in FIG. 5 and FIG. 10 is a main-part plan view of a semiconductor device, which is a study example with respect to FIG. 9. In addition, FIG. 11 shows explanatory diagrams schematically showing the stress generated along with reduction of the temperature of the semiconductor device in the cross section along the line A-A of FIG. 9. Further, FIG. 12 shows explanatory diagrams schematically showing the stress generated along reduction of the temperature of the semiconductor device in the cross section along the line A-A of FIG. 10. In FIG. 9 and FIG. 10, in order to facilitate viewing of the boundary between blank regions YRC and YRB, the blank regions YRC and YRB are shown with hatching.

A semiconductor device 60 shown in FIG. 9 is different from a semiconductor device 61 shown in FIG. 10 in the points that the bent part 3W is provided between the ribbon-connecting part 3B, which connects the metal ribbon 7R, and the chip-connecting part 3C and that the height of the ribbon-connecting surface 3Ba is higher than the height of the chip-mounting surface 3Ca. In other words, the semiconductor device 61 shown in FIG. 10 is different from the semiconductor device 60 shown in FIG. 9 in the point that the chip-mounting surface 3Ca of the tab 3 and the ribbon-connecting surface are disposed at the same height.

In this case, when the semiconductor chip 2 is to be mounted on the chip-connecting part 3C via the electrically-conductive member 6, in order to cause an entire back surface 2b (see FIG. 11) of the semiconductor chip 2 to reliably adhere to the electrically-conductive member 6, the planar size (planar area) of the chip-mounting surface 3Ca is preferred to be larger than the planar size (planar area) of the back surface 2b of the semiconductor chip 2. If the planar size (planar area) of the chip-mounting surface 3Ca is larger than the planar size (planar area) of the back surface 2b of the semiconductor chip 2, the entire back surface 2b of the semiconductor chip 2 can be placed on within the chip-mounting surface 3Ca even when slight positional misalignment upon mounting is taken into consideration.

If the planar size (planar area) of the chip-mounting surface 3Ca is larger than the planar size (planar area) of the back surface 2b of the semiconductor chip 2 in this manner, as shown in FIG. 9 or FIG. 10, a blank area YRC is present around the region in which the semiconductor chip 2 is actually fixed.

The blank region YRC of the tab 3 is a region which is not in contact with the electrically-conductive member 6, which fixes the semiconductor chip 2, or the metal ribbon 7R in the plane continuous at the height same as that of the chip-mounting surface 3Ca of the tab 3 on which the semiconductor chip 2 is mounted. In other words, the blank region YRC of the tab 3 is a region that is not covered by the electrically-conductive member 6, which fixes the semiconductor chip 2, or the metal ribbon 7R in the plane continuous at the same height as that of the chip-mounting surface 3Ca of the tab 3 and exposes the upper surface of the tab 3 (for example, the copper surface of the base material).

Therefore, in the case of the semiconductor device 60 shown in FIG. 9, the ribbon-connecting surface 3Ba and the upper surface 3Wa of the bent part 3W are not included in the blank region YRC. Since the blank region YRB shown in FIG. 9 of the ribbon-connecting surface 3Ba which is not in contact with the metal ribbon 7R is disposed at the height different from that of the chip-mounting surface 3Ca, the blank region YRB is distinguished from the blank region YRC.

On the other hand, in the semiconductor device 61 shown in FIG. 10, the upper surface (ribbon-connecting surface) of the ribbon-connecting part 3B and the chip-mounting surface 3Ca are continuous to each other at the same height. Therefore, on the upper surface of the tab 3, the entire region which is not covered with the electrically-conductive member 6, which fixes the semiconductor chip 2, or the metal ribbon 7R is the blank region YRC.

As is understood from comparison of FIG. 9 and FIG. 10, the area of the blank region YRC of the chip-mounting surface 3Ca provided on the semiconductor device 60 is smaller than the area of the blank region YRC of the chip-mounting surface 3Ca provided on the semiconductor device 61. Specifically, in the semiconductor device 60 shown in FIG. 9, a length L1 of the blank region YRC provided in the metal-ribbon-7R side from the electrically-conductive member 6 is shorter than a length L2 of the blank region YRC which is provided in the metal-ribbon-7R side from the electrically-conductive member 6 in the semiconductor device 61 shown in FIG. 10. Therefore, in the semiconductor device 60, the area of the blank region YRC provided in the metal-ribbon-7R side is smaller than the area of the blank region YRC provided in the metal-ribbon-7R side in the semiconductor device 61.

Herein, the stress which is generated because of a difference(s) in the linear expansion coefficients of constituent members when a temperature change occurs in the semiconductor device 60 or the semiconductor device 61 will be explained. Hereinafter, an example of a case in which the temperature (for example, 180° C.) of hardening resin is reduced to an ordinary temperature (for example, 25° C.) in a step of forming the seal 5 by a transfer mold method will be explained.

First, as shown in the upper levels of FIG. 11 and FIG. 12, in the state of the temperature (for example, 180° C.) at which the seal 5 is hardened, the stress that causes peel-off is not generated in both of the cases of the semiconductor devices 60 and 61.

Then, when the temperature is gradually reduced from the temperature at which the seal 5 is hardened, as shown in the middle levels of FIG. 11 and FIG. 12, stress caused by differences in the linear expansion coefficients (differences in contraction percentage) of the members constituting the semiconductor device 60 or 61 is generated. In both of the case of the semiconductor device 60 and the case of the semiconductor device 61, the linear expansion coefficients become large in the order of the semiconductor chip 2, the seal 5, and the tab 3. Therefore, since the contraction percentage of the tab 3 is relatively larger than the contraction percentage of the seal 5, stress STf is generated from the peripheral part side of the seal 5 toward the inner side as shown by arrows in the middle levels of FIG. 11 and FIG. 12. Since the semiconductor chip 2 and the tab 3 having small linear expansion coefficients are fixed by the electrically-conductive member 6 at this point, the tab 3 is not easily deformed in the region immediately below the semiconductor chip 2. Therefore, in the chip-mounting surface 3Ca of the tab 3, the stress STf is generated toward the center of the region opposed to the back surface 2b of the semiconductor chip 2 (the region immediately below the semiconductor chip 2).

On the other hand, since the contraction percentage of the seal 5 is relatively smaller than the contraction percentage of the tab 3, as shown with arrows in the drawings in the middle levels of FIG. 11 and FIG. 12, stress STr is generated from the peripheral part side of the tab 3 toward the outer side (the peripheral part side of the seal 5). At this point, since the semiconductor chip 2 further does not easily contract compared with the seal 5, stress (tensile stress) STr is generated in the direction toward the peripheral part of the seal 5 while the semiconductor chip 2 serves as a base point.

Herein, as shown in FIG. 12, if the chip-mounting surface 3Ca is extended to the ribbon-connecting part 3B at the same height, the length L2 of the blank region YRC provided in the ribbon-connecting-part-3B side from the electrically-conductive member 6 is longer than a length L3 of the blank region YRC provided in the side opposite to the ribbon-connecting part 3B with the semiconductor chip 2 therebetween. Therefore, stress STf1 generated in the ribbon-connecting-part-3B side from the semiconductor chip 2 is larger than stress STf2 generated in the side opposite to the ribbon-connecting part 3B with the semiconductor chip 2 therebetween. Moreover, stress STr1 generated in the ribbon-connecting-part-3B side from the semiconductor chip 2 is larger than stress STr2 generated in the side opposite to the ribbon-connecting part 3B with the semiconductor chip 2 therebetween.

On the other hand, when the bent part 3W is provided between the chip-mounting surface 3Ca and the ribbon-connecting surface 3Ba as shown in FIG. 11, stress is dispersed since the bent part 3W is elastically deformed. In other words, the bent part 3W functions as a stress relaxing part. Therefore, as shown in the drawing of the middle level of FIG. 11, the stress STf1 is generated in the chip-connecting part 3C in the region in the ribbon-connecting-part-3B side from the semiconductor chip 2, and stress ST3 is generated in the ribbon-connecting part 3B. However, the mutual influence of the stress STf1 and STf3 is reduced by providing the bent part 3W. Moreover, the stress STr1 is generated between the semiconductor chip 2 and the ribbon-connecting part 3B, and stress STr3 is generated in the region in the peripheral-part-side of the seal 5 from the ribbon-connecting part 3B. However, the mutual influence of the stress STr1 and STf3 is reduced by providing the bent part 3W.

Thus, in the case of the semiconductor device 60 shown in FIG. 11, the stress STf and STr generated around the ribbon-connecting part 3B is dispersed by providing the bent part 3W for disposing the ribbon-connecting surface 3Ba at the position higher than the chip-mounting surface 3Ca. Therefore, the stress STf1 and STr1 applied to the chip-connecting part 3C of the tab 3 can be reduced compared with the semiconductor device 61 shown in FIG. 12.

The value of the stress STf1 can be reduced by shortening the length L1 of the blank region YRC provided in the ribbon-connecting-part-3B side from the electrically-conductive member 6. For example, in the example shown in FIG. 11, the length L1 of the blank region YRC provided in the ribbon-connecting-part-3B side from the electrically-conductive member 6 has the same length as the length L3 of the blank region YRC provided in the side opposite to the ribbon-connecting part 3B with the semiconductor chip 2 therebetween. Therefore, the stress STf1 generated in the ribbon-connecting-part-3B side from the semiconductor chip 2 has an equivalent value as that of the stress STf2 generated in the side opposite to the ribbon-connecting part 3B with the semiconductor chip 2 therebetween.

Moreover, as shown in the drawings in the lower level of FIG. 11 and FIG. 12, if the temperatures of the constituent members of the semiconductor devices 60 and 61 are reduced, force Fr and Ff is generated in the directions that deform the constituent members. The directions related to the force Fr and Ff are described as below when viewed from the viewpoints of the seal 5 and the tab 3.

First, when viewed from the viewpoint of the seal 5, the linear expansion coefficient of the semiconductor chip 2 is smaller than the linear expansion coefficient of the seal 5. Therefore, around the semiconductor chip 2, disturbing force acts against the contracting direction of the seal 5. As a result, force Fr acts so that a convex shape is formed in a downward direction (packaging-surface direction) while the adhesion interface of the seal 5 and the semiconductor chip 2 serves as a base point.

On the other hand, when viewed from the viewpoint of the tab 3, the linear expansion coefficient of the semiconductor chip 2 is smaller than the linear expansion coefficient of the tab 3. Therefore, around the region immediately below the semiconductor chip 2, disturbing force acts against the contracting direction of the tab 3. As a result, force Ff acts so that a convex shape is formed in the upward direction while the region of the tab 3 immediately below the semiconductor chip 2 serves as a base point.

Herein, if the chip-mounting surface 3Ca is extended to the ribbon-connecting part 3B at the same height as shown in FIG. 12, the length L2 of the blank region YRC provided in the ribbon-connecting-part-3B side from the electrically-conductive member 6 is longer than the length L3 of the blank region YRC provided in the side opposite to the ribbon-connecting part 3B with the semiconductor chip 2 therebetween. Therefore, the force Ff1 generated in the ribbon-connecting-part-3B side from the semiconductor chip 2 is larger than the force Ff2 generated in the side opposite to the ribbon-connecting part 3B with the semiconductor chip 2 therebetween. Moreover, the force Fr1 generated in the ribbon-connecting-part-3B side from the semiconductor chip 2 is larger than the stress Fr2 generated in the side opposite to the ribbon-connecting part 3B with the semiconductor chip 2 therebetween.

As a result, largest force acts on the peripheral part of the ribbon-connecting part 3B (an edge part 3E shown in the drawing of the lower level of FIG. 12) in the direction that peels off the adhesion interface of the seal 5 and the tab 3. In other words, the peel-off of the adhesion interface of the seal 5 and the tab 3 easily occurs while a peripheral part of the ribbon-connecting part 3B (the edge part 3E shown in the drawing of the lower level of FIG. 12) serves as a starting point.

On the other hand, if the bent part 3W is provided between the chip-mounting surface 3Ca and the ribbon-connecting surface 3Ba as shown in FIG. 11, stress is dispersed since the bent part 3W is elastically deformed in the above-described manner. Therefore, the force Ff1 and Fr1 generated in the vicinity of the boundary between the chip-connecting part 3C and the bent part 3W becomes small compared with the force Ff1 and Fr2 shown in FIG. 12.

Moreover, the values of the force Ff1 and Fr1 can be reduced by reducing the length L1 of the blank region YRC provided in the ribbon-connecting-part-3B side from the electrically-conductive member 6. For example, in the example shown in FIG. 11, the length L1 of the blank region YRC provided in the ribbon-connecting-part-3B side from the electrically-conductive member 6 has the same length as the length L3 of the blank region YRC provided in the side opposite to the ribbon-connecting part 3B with the semiconductor chip 2 therebetween. Therefore, the stress Ff1 and Fr1 generated in the ribbon-connecting-part-3B side from the semiconductor chip 2 has the values equivalent to those of the stress Ff2 and Fr2 generated in the side opposite to the ribbon-connecting part 3B with the semiconductor chip 2 therebetween.

However, in a strict sense, at the boundary between the chip-connecting part 3C and the bent part 3W (the edge part 3E shown in the drawing of the lower level of FIG. 11), the influence of the force Ff and Fr generated at the ribbon-connecting part 3B and the bent part 3W is not entirely eliminated (does not become 0).

Therefore, at the boundary part of the chip-connecting part 3C and the bent part 3W (the edge part 3E shown in the drawing of the lower level of FIG. 11), largest force acts in the direction that peels off the adhesion interface of the seal 5 and the tab 3. In other words, peel-off of the adhesion interface of the seal 5 and the tab 3 easily occurs while the boundary part of the chip-connecting part 3C and the bent part 3W (the edge part 3E shown in the drawing of the lower level of FIG. 11) serves as a starting point. However, when the semiconductor device 60 shown in FIG. 11 and the semiconductor device 61 shown in FIG. 12 are compared with each other, generation of peel-off (peel-off starting point) can be suppressed more in the semiconductor device 60.

Meanwhile, a case in which the electrical characteristics of the semiconductor device are immediately reduced because of occurrence of peel-off at the adhesion interface of the seal 5 and the tab 3 is rare. A slight peel-off (peel-off starting point) generated at the adhesion interface of the seal 5 and the tab 3 is often expanded/progressed in a manufacturing process thereafter. More specifically, when a completed semiconductor device (package) is to be built in a finished product, the semiconductor device is generally soldered on a packaging board of the finished product. If the solder used in this process is lead-free solder using tin (Sn)-silver (Ag) as a base, the reflow temperature of soldering reaches about 260° C. As a matter of course, the temperature of the semiconductor device at this point is also increased to about 260° C. Then, when reflow is completed, the semiconductor device is returned to an ordinary temperature (25° C.). Thus, stress is applied to the adhesion interface of the seal 5 and the tab 3 by the temperature cycle of the normal temperature (25° C.), the high temperature (260° C.), and the normal temperature (25° C.), and the peel-off starting point generated at the adhesion interface of the seal 5 and the tab 3 is expanded/progressed by the stress. Furthermore, if the finished product is used, for example, in a low-temperature environment below 0° C. Celsius, the tab 3 is largely contracted compared with the seal 5, and the stress in the direction in which the tab 3 and the seal 5 are separated from each other is applied; therefore, peel-off easily progress also in this case. When the peel-off progresses in this manner and reaches the electrically-conductive adhesive material 6L, the electrically-conductive adhesive material 6L is peeled off in some cases. The electrically-conductive adhesive material 6L is the electrically-conductive member 6 for electrically connecting the back-surface electrodes of the semiconductor chip 2 and the tab 3; therefore, peel-off of the electrically-conductive adhesive material 6L is a cause that reduces the electrical characteristics between the semiconductor chip 2 and the tab 3. Particularly, in the example shown in FIG. 6, the electrically-conductive adhesive material 6L is the electrically-conductive member 6, which electrically connects the drain electrode 2LDP of the semiconductor chip 2L and the tab 3L; therefore, if part of the electrically-conductive adhesive material 6L is peeled off, drain resistance is increased, and reduction of the electrical characteristics is caused.

As described above, at the tab 3 electrically connected to the semiconductor chip 2, it is particularly important to prevent or suppress peel-off of the adhesion interface of the seal 5 and the tab 3 from the viewpoint of suppressing reduction of the electrical characteristics. Moreover, if peel-off of the adhesion interface of the seal 5 and the tab 3 occurs, it is important to suppress progress of the peel-off and prevents it from easily reaching the electrically-conductive adhesive material 6L.

The readiness of progress of peel-off is changed depending on the magnitude of the stress applied to the vicinity of the location at which the peel-off occurs. If the stress at the location where peel-off occurs is large, the progress speed of the peel-off along a peel-off surface is fast. On the other hand, the stress applied to the location at which the peel-off occurs is small, the progress speed of the peel-off can be slowed down.

As shown in the middle levels of FIG. 11 and FIG. 12, the stress STr1 and STF1 applied to the edge part 3E serving as the location (peel-off starting point) at which peel-off occurs is smaller in the semiconductor device 60, in which the bent part 3W is provided between the ribbon-connecting part 3B and the chip-connecting part 3C, than that of the semiconductor device 61. Thus, since the bent part 3W is provided between the ribbon-connecting part 3B and the chip-connecting part 3C, even if peel-off occurs, progress of the peel-off can be suppressed.

Next, the relation of the peel-off of the seal 5 and the tab and the relation of the peel-off of the tab 3 and the electrically-conductive adhesive material 6L explained by using FIG. 9 to FIG. 12 will be explained by application to the semiconductor device 1 shown in FIG. 5 and FIG. 6. As shown in FIG. 5, the planar size (planar area) of the chip-mounting surface 3Ca of the chip-connecting part 3C of the tab 3L is larger than the planar size (planar area) of the semiconductor chip 2L. Therefore, around the semiconductor chip 2L, the blank region YRC not covered with the electrically-conductive adhesive material 6L is present. Moreover, as shown in FIG. 5, the metal ribbon 7HSR is joined with part of the ribbon-connecting surface 3Ba of the ribbon-connecting part 3B, and, around the joined region, the blank region YRB not joined with the metal ribbon 7HSR is present.

Herein, if the semiconductor device 1 is subjected to a temperature cycle in a state in which the bent part 3W is not provided between the ribbon-connecting part 3B and the chip-connecting part 3C, peel-off occurs at the adhesion interface of the seal 5 and the tab 3L in some cases due to the difference in the linear expansion coefficients of the tab 3L and the seal 5. However, according to the present embodiment, the area of the blank region YRC is reduced by disposing the ribbon-connecting surface 3Ba and the chip-mounting surface 3Ca at different heights. Therefore, occurrence of peel-off at the boundary of the chip-connecting part 3C and the bent part 3W can be suppressed.

Moreover, in the semiconductor device 1, since the bent part 3W is provided between the ribbon-connecting part 3B and the chip-connecting part 3C, the stress applied to the boundary of the chip-connecting part 3C and the bent part 3W can be reduced. Therefore, even if peel-off occurs at the boundary of the chip-connecting part 3C and the bent part 3W, progress of the peel-off toward the electrically-conductive adhesive material 6L can be prevented.

As a result, increase in the drain resistance due to peel-off of the electrically-conductive member 6, which electrically connects the drain electrode 2LDP of the semiconductor chip 2L and the tab 3L, can be suppressed. Thus, according to the present embodiment, occurrence or progress of peel-off can be suppressed; therefore, reduction in the electrical characteristics caused by peel-off of the electrically-conductive adhesive material 6L can be suppressed. In other words, reliability of the semiconductor device 1 can be improved.

From the viewpoint of suppressing fall of the tab 3H from the seal 5, it is preferred to form a bent part 3W or a bent part 4W in part of the tab 3H or the lead 4HD. However, space is required to form the bent parts 3W and 4W. Therefore, in the example shown in FIG. 5 and FIG. 6, the bent parts 3W and 4W are not formed in the tab 3H and the lead 4HD from the viewpoint of prioritizing downsizing of the planar size thereof. Moreover, since the tab 3H is not provided with a ribbon-connecting part, which connects the metal ribbon 7R, the area of the blank region thereof around the semiconductor chip 2H and the electrically-conductive adhesive material 6H can be reduced. Therefore, even though the bent part 3W is not formed, occurrence and progress of peel-off can be easily suppressed.

However, as a modification example with respect to FIG. 5 and FIG. 6, the bent part 3W or the bent part 4W can be formed in part of the tab 3H or the lead 4HD. The effects other than those described above exerted by causing the height of the ribbon-connecting surface 3Ba, to which the metal ribbon 7HSR is connected, to be higher than the chip-mounting surface 3a, on which the semiconductor chip 2L is mounted, and a preferred height thereof will be explained later in detail.

<About Metal Ribbon>

Next, the metal ribbons shown in FIG. 5 and FIG. 6 will be explained. In the below explanation, 7R will be used as a reference sign that collectively represents the metal ribbons 7HSR and 7LSR. In the below explanation, the description of the metal ribbons 7R means the metal ribbon 7HSR and the metal ribbon 7LSR.

The metal ribbons 7R shown in FIG. 5 and FIG. 6 are metal members (metal strips) formed in strip shapes and are distinguished from the wire 7GW by the point that the cross-sectional area of the conduction path thereof is larger than that of the wire 7GW. For example, in the example shown in FIG. 6, the metal ribbon 7HSR has a thickness of about 50 μm to 100 μm and has a width of about 750 μm. Moreover, the metal ribbon 7LSR has a thickness of about 50 μm to 100 μm and has a width of about 2000 μm. On the other hand, the wire 7GW has a wire diameter of, for example, about 20 μm to 50 μm. In this manner, when the semiconductor chip 2 and the lead 4 (or the tab 3) are electrically connected to each other via the metal ribbon 7R, the cross-sectional area of the conduction path thereof becomes significantly large; therefore, this is preferred in a point that the impedance component thereof can be reduced.

Moreover, in the example shown in FIG. 5, from the viewpoint of reducing electric power loss, the planar size (area) of the semiconductor chip 2L is larger than the planar size (area) of the semiconductor chip 2H. As a result, the planar size (area) of the source electrode pad 2LSP of the semiconductor chip 2L is larger than the planar size (area) of the source electrode pad 2HSP of the semiconductor chip 2H. Therefore, the width of the metal ribbon 7LSR, which is connected to the source electrode pads 2LSP of the semiconductor chip 2L, is wider than the width of the metal ribbon 7HSR, which is connected to the source electrode pad 2HSP of the semiconductor chip 2H. The width of the metal ribbon 7LSR is defined as the distance between the lateral surfaces of the metal ribbon 7LSR opposed to each other in an X-direction, which is orthogonal to a Y-direction which is from the source electrode pads 2LSP of the semiconductor chip 2L toward the ribbon-connecting part (connecting part) 4B of the lead 4LS. Also, the width of the metal ribbon 7HSR is defined as the distance between the lateral surfaces of the metal ribbon 7HSR opposed to each other in the direction orthogonal to the direction which is from the source electrode pad 2HSP of the semiconductor chip 2H toward the ribbon-connecting part (connecting part) 3B of the tab 3L.

As a connecting method that can increase the cross-sectional area of the conduction path between the semiconductor chip 2 and the lead 4 to be larger than that of the wire 7GW, other than a ribbon bonding method by the metal ribbon 7R shown in FIG. 5 and FIG. 6, a method in which a metal plate molded in advance is joined via an electrically-conductive joining material such as solder (metal clip method) can be also applied to the present embodiment as a modification example. The metal ribbon 7R shown in FIG. 5 and FIG. 6 have some points which are different from the metal plate molded in advance (metal clip). They will be explained below.

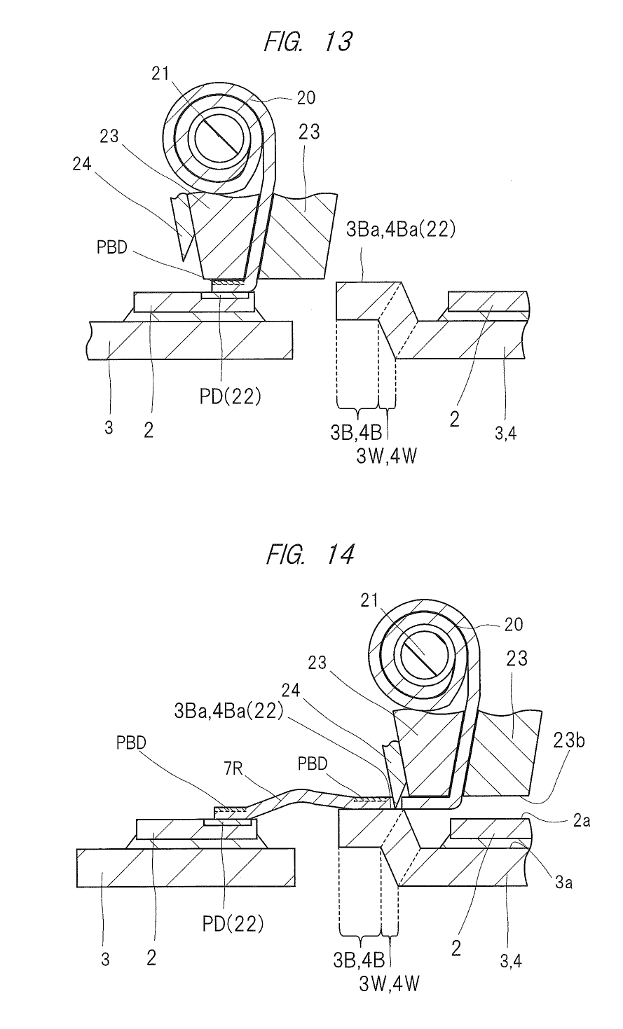

As shown in FIG. 13, in the method of forming the metal ribbon 7R (ribbon bonding method), while a metal strip 20 is sequentially fed and molded from a reel (retaining part) 21, which retains the metal strip 20, the metal strip 20 is joined with a part to be joined (the electrode pad PD of the semiconductor chip 2 or the connecting surface 3Ba of the ribbon-connecting part 3B of the tab 3) 22. Thus, this is different from the metal clip which is molded in advance in the point that it is joined with the part 22 to be joined while it is molded.

Therefore, from the viewpoint of improving the moldability upon bonding, the thickness of the metal ribbon 7R is preferred to be thin. For example, as described above, the thickness of the metal ribbon 7R is about 50 μm to 100 μm in the example shown in FIG. 5 and FIG. 6. Reversely, the metal clip, which is molded in advance and to mount the molded one onto the part to be joined, is required to have rigidity after molding. Therefore, in a case of a copper (Cu) material, the thickness thereof is about 100 to 250 μm. In other words, since the metal ribbon 7R is joined with the part 22 to be joined while molding it, the plate thickness thereof can be reduced compared with the metal clip.

As long as the width and the length are the same, conductor resistance of the metal ribbon is higher by the amount the thickness of the metal ribbon is thinner than that of the metal clip. Therefore, if importance is put on thickness reduction of the semiconductor device (package), it is preferred to employ the metal ribbon. If importance is put on the electrical characteristics of the semiconductor device, it is preferred to employ the metal clip.

When the metal ribbon 7R is to be joined with the part 22 to be joined, metal bonding is formed at the joint interface of the metal ribbon 7R and the metal member of the part to be joined by applying ultrasonic waves by a bonding tool (joining jig) 23 to join them. Therefore, as shown in FIG. 5, at the part that contacts the bonding tool of the metal ribbon 7R, the pressure-bonding marks PBD remain when the ultrasonic waves are applied. This is one of main characteristics of the case in which the metal ribbon is employed. Since the metal ribbon forms electrical connection with the part 22 to be joined when the ultrasonic waves are applied in this manner, an electrically-conductive joining material is not required between the metal ribbon and the part to be joined. Therefore, assembly cost of the semiconductor device can be reduced, for example, since the material that constitutes the semiconductor device is reduced and since the process, etc. of supplying the electrically-conductive joining material are reduced. However, the metal clip which uses the electrically-conductive joining material also has a large advantage. If, for example, a solder material is used as the electrically-conductive joining material which electrically connects the metal clip and the part to be joined, the strength of the connection part thereof is higher compared with the connection strength of the joining part of the metal ribbon formed by applying the ultrasonic waves. This is effective for improving the reliability of the semiconductor device. This can be summarized that the metal ribbon is preferred to be employed when importance is put on cost reduction and that the metal clip is preferred to be employed when importance is put to ensure reliability.

The case in which joining with the part 22 to be joined is carried out while molding like the metal ribbon 7R is suitable in a case in which separated parts 22 to be joined are to be connected so as to linearly connect them. However, molding is difficult in a case in which the planar layout of the parts 22 to be joined are complex. Therefore, in this case, it is preferred to apply the metal clip method in which the metal plate molded in a predetermined shape in advance is joined.

As described above, it can be understood that the metal ribbon and the metal clip have advantages and disadvantages. Therefore, it is important to use them depending on the purpose of each case.

Then, in the ribbon bonding method, after the metal ribbon 7R is molded and joined with the plurality of parts 22 to be joined, a step of cutting the metal strip 20 is required. In the step of cutting the metal strip 20, for example as shown in FIG. 14, the metal strip 20 can be cut by pressing a cutting blade 24 against the metal strip 20. In this process, from the viewpoint of suppressing application of the pressing force of the cutting to the semiconductor chip 2 (to prevent the surface of the semiconductor chip 2 from being damaged by the pressing force of cutting), it is preferred to join the metal ribbon with the electrode pad PD of the semiconductor chip 2 first and then connect the metal ribbon with the ribbon-connecting part 3B of the tab 3 (or the ribbon-connecting part 4B of the lead 4). In other words, the load applied to the semiconductor chip 2 upon ribbon bonding can be reduced by setting the electrode pad PD of the semiconductor chip 2 as a first bonding side and setting the ribbon-connecting part 3B of the tab 3 (or the ribbon-connecting part 4B of the lead 4) as a second bonding side.

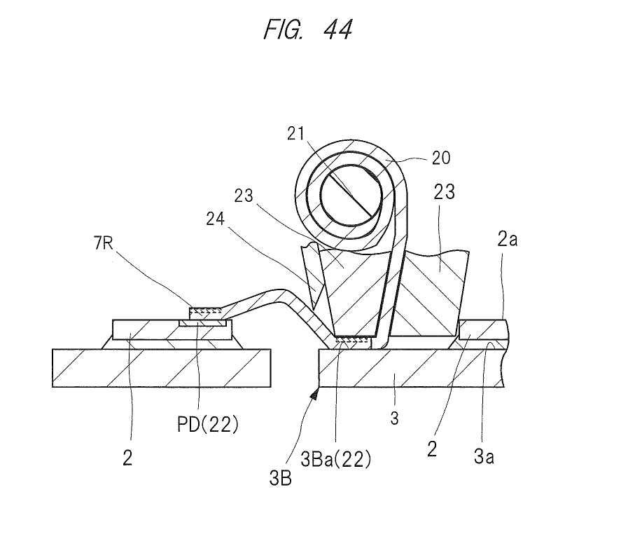

If the part 22 of the metal ribbon 7R to be joined is provided on the tab 3 on which the semiconductor chip 2 is mounted, the semiconductor chip 2 and the bonding tool 23 have to be prevented from contacting each other. For example, as shown in FIG. 44, if the ribbon-connecting surface 3Ba of the ribbon-connecting part 3B and the chip-mounting surface 3Ca of the chip-connecting part 3C on which the semiconductor chip 2 is mounted are at the same height, the bonding tool 23 and the semiconductor chip 2 easily contact with each other upon ribbon bonding.

As a method of preventing the bonding tool 23 and the semiconductor chip 2 from contacting each other, a method in which the distance between the semiconductor chip 2 and the ribbon-connecting part 3B is increased is conceivable. In this case, the space larger than an actual joining region is required; therefore, downsizing of the semiconductor device becomes difficult. Moreover, as another method, a method in which the semiconductor chip 2 is mounted on the tab 3 after the metal ribbon 7R is joined by the ribbon bonding method is conceivable. However, in this case, manufacturing processes become cumbersome since the plurality of semiconductor chips 2 cannot be mounted at one time.

On the other hand, in the example shown in FIG. 14, the height of the ribbon-connecting surface 3Ba of the ribbon-connecting part 3B of the tab 3L is positioned at a position higher than the height of the chip-mounting surface 3Ca of the chip-connecting part 3C of the tab 3L. Therefore, even if the distance between the semiconductor chip 2 and the ribbon-connecting part 3B is short in ribbon bonding, the contact between the bonding tool 23 and the semiconductor chip 2 can be easily avoided. More specifically, the distance between the semiconductor chip 2 and the ribbon-connecting part 3B can be shortened more than the comparative example shown in FIG. 44. As a result, the planar size of the semiconductor device can be downsized.

Herein, the fact that downsizing is enabled by disposing the height of the ribbon-connecting surface 3Ba of the ribbon-connecting part 3B of the tab 3L at the position higher than the height of the chip-mounting surface 3Ca of the chip-connecting part 3C will be explained by taking examples studied by the inventor of the present application.

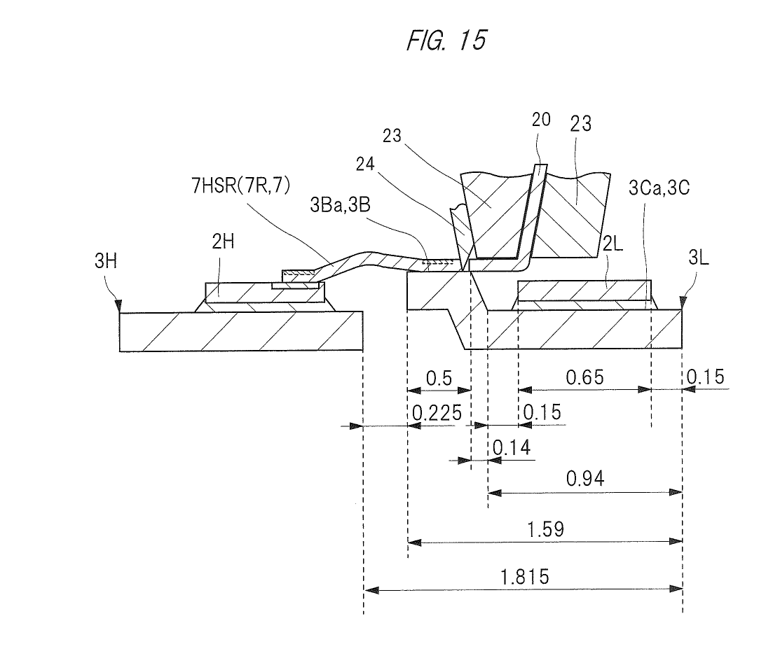

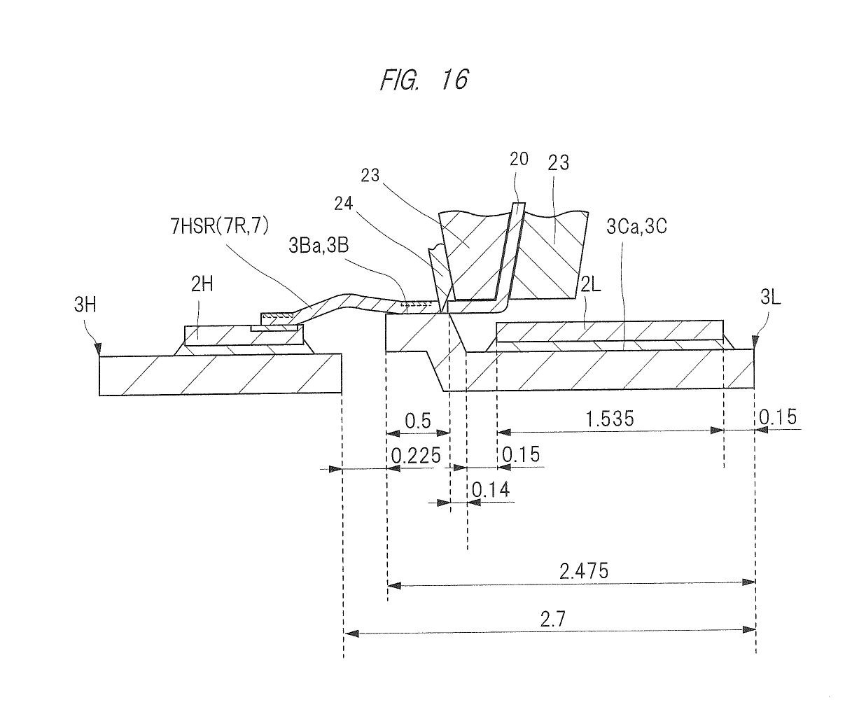

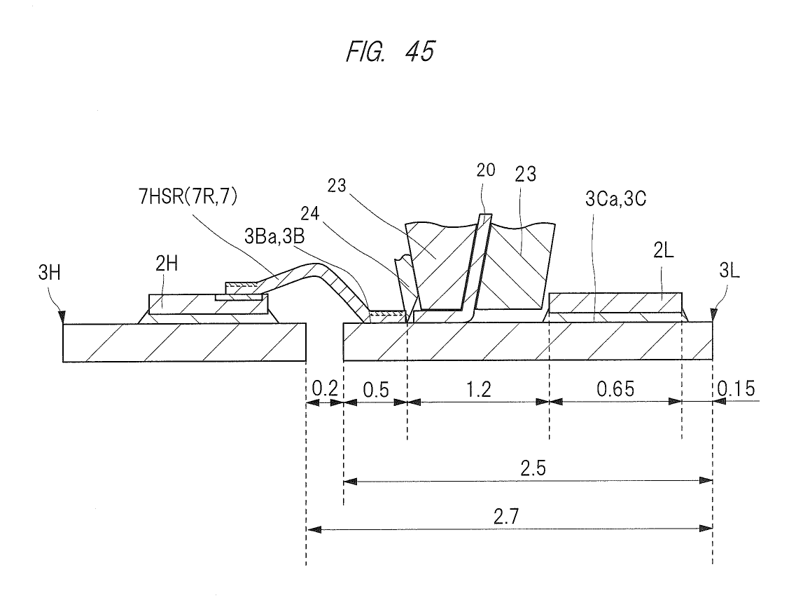

FIG. 15 is a main-part cross-sectional view showing a dimension example of the tab of the case shown in FIG. 6 in which the height of the ribbon-connecting surface of the tab in the low side is higher than the chip-mounting surface. FIG. 16 is a main-part cross-sectional view showing a dimension example of a case in which a semiconductor chip having a large planar size is mounted on the tab of the low side as a modification example with respect to FIG. 15. FIG. 45 is a main-part cross-sectional view showing a study example with respect to FIG. 15. In FIG. 15, FIG. 16, and FIG. 45, the dimensions (lengths) in the cross-sectional views of the tab 3L of the low side are shown by the millimeter (mm) unit. Specific numerical values of the dimensions in the below explanation are examples for the sake of explanation, and the numerical values are not limited thereto.

In the examples shown in FIG. 15, FIG. 16, and FIG. 45, the occupied width of the bonding tool 23 and the cutting blade 24 (the minimum required width for bonding and cutting the metal ribbon 7R) is 1.2 mm. As shown in FIG. 45, since the height of the ribbon-connecting surface 3Ba of the ribbon-connecting part 3B of the tab 3L is the same as the height of the chip-mounting surface 3Ca of the chip-connecting part 3C, the semiconductor chip 2L has to be mounted while providing the space of 1.2 mm, which is the occupied width of the bonding tool 23 and the cutting blade 24. Therefore, the space of the entire tab 3L is 2.5 mm.

On the other hand, in a case in which the height of the ribbon-connecting surface 3Ba of the ribbon-connecting part 3B of the tab 3L is positioned at a position higher than the height of the chip-mounting surface 3Ca of the chip-connecting part 3C as shown in FIG. 15, even if the bonding tool 23 is overlapped above the semiconductor chip 2L, contact of the semiconductor chip 2L with the bonding tool 23 and the metal strip 20 can be prevented or suppressed. Therefore, the dimension of the chip-mounting surface 3Ca can be set to 0.94 mm. Even if the dimensions of the ribbon-connecting part 3B and the bent part 3W (see FIG. 6) are taken into consideration, the dimension of the upper surface of the entire tab 3L in a plan view can be set to 1.59 mm. Thus, it can be understood that the planar size can be downsized by 0.91 mm compared with the case shown in FIG. 45.

The separated distance between the tab 3L and the tab 3H is slightly longer (by 0.025 mm) in the case shown in FIG. 15. This is for the reason that a processing allowance for forming the bent part 3W (see FIG. 6) is required. However, it has been found out that, in the case of the example shown in FIG. 15, the planar size can be downsized by 0.885 mm compared with the example shown in FIG. 45 even when the processing allowance is taken into consideration.

Also, as a modification example, as shown in FIG. 16, the planar size of the semiconductor chip 2L can be increased. For example, in the example shown in FIG. 16, the distance from the tab-3L-side end of the tab 3H to the end of the tab 3L in the side opposite to the tab 3H is 2.7 mm. This distance is the same as that of the example shown in FIG. 45. However, in the example shown in FIG. 16, the length of one side of the semiconductor chip 2L can be set to 1.535 mm.

As described above, the on-resistance of the low-side field-effect transistor can be reduced by increasing the planar size of the semiconductor chip 2L. Therefore, even in a case in which the on-resistance is reduced by increasing the planar size of the semiconductor chip 2L, the example shown in FIG. 16 is preferred in a point that increase in the planar size of the semiconductor device can be suppressed.

Furthermore, effects are exerted also in terms of manufacturing of the semiconductor device. That is, manufacturing processes can be simplified since the plurality of semiconductor chips 2 can be mounted at a time in the manufacturing process of the semiconductor device. As a result, manufacturing efficiency can be improved. Details thereof will be described later.

From the viewpoint of downsizing the semiconductor device and facilitating avoiding of contact between the bonding tool 23 and the semiconductor chip 2 upon ribbon bonding, it is preferred that a lower surface 23b of the bonding tool 23 be disposed to be opposed to a top surface 2a of the semiconductor chip 2 upon ribbon bonding as shown in FIG. 14. If the lower surface 23b of the bonding tool 23 is disposed at a position higher than the top surface 2a of the semiconductor chip 2 upon ribbon bonding, contact between the bonding tool 23 and the semiconductor chip 2 can be avoided. Therefore, when the thickness of the metal ribbon 7R is taken into consideration, even if the height of the ribbon-connecting surface 3Ba shown in FIG. 14 is at a height between the chip-mounting surface 3Ca and the top surface 2a of the semiconductor chip 2, the lower surface 23b and the top surface 2a can be prevented from contacting each other.

However, since the thickness of the metal ribbon 7R is about 50 μm to 100 μm as described above, from the viewpoint of avoiding the contact between the bonding tool 23 and the semiconductor chip 2, it is preferred that the height of the ribbon-connecting surface 3Ba be higher than or equal to the height of the top surface 2a of the semiconductor chip 2. Also, from the viewpoint of reliably avoiding the contact between the bonding tool 23 and the semiconductor chip 2, it is particularly preferred that the height of the ribbon-connecting surface 3Ba be positioned at a position higher than the height of the top surface 2a of the semiconductor chip 2.

Moreover, in the example shown in FIG. 6, the thickness of the tab 3H and the thickness of the tab 3L (for example, the distance from the chip-mounting surface 3Ca to the lower surface 3Cb thereof) are the same thickness, wherein each of the thicknesses is, for example, about 200 μm to 250 μm. Moreover, in the example shown in FIG. 6, the thickness of the semiconductor chip 2H and the thickness of the semiconductor chip 2L are the same thickness, wherein each of the thicknesses is about 50 μm to about 160 μm. Moreover, in the example shown in FIG. 6, the thicknesses of the electrically-conductive adhesive materials 6H and 6L are the same thickness which is about 20 μm to 50 μm. Therefore, if the height of the ribbon-connecting surface 3Ba is higher than the height of the top surface 2La of the low-side semiconductor chip 2L, the height of the ribbon-connecting surface 3Ba is in a state that it is higher than the height of the top surface 2Ha of the high-side semiconductor chip 2H.

Moreover, if the height of the ribbon-connecting surface 3Ba is higher than the height of the top surface 2Ha of the high-side semiconductor chip 2H, the height of the ribbon-connecting surface 3Ba is in a state that it is higher than the height of the high-side source electrode pad 2HSP. Thus, if the metal ribbon 7HSR is connected in the order of the source electrode pad 2HSP and the ribbon-connecting surface 3Ba, this is a so-called upward structure in which the position of the connecting point serving as the second bonding side is higher than the connecting point serving as the first bonding side.

In a case of a so-called downward structure in which the position of the connecting point of the second bonding side is lower than the position of the connecting point of the first bonding side when ribbon bonding is carried out, for example, like the example shown in FIG. 45, it is preferred that the loop shape of the metal ribbon 7R be large (loop distance be long) in order to avoid contact between the semiconductor chip 2 disposed in the first bonding side and the metal ribbon 7R. However, if the loop shape of the metal ribbon 7R becomes large, the resistance component of the metal ribbon 7R is increased.

On the other hand, in a case in which ribbon bonding is carried out by a so-called upward structure in which the position of the connecting point of the second bonding side is higher than the position of the connecting point of the first bonding side as shown in FIG. 6, even if the loop shape of the metal ribbon 7HSR is small (the loop distance is shortened), the contact between the semiconductor chip 2H and the metal ribbon 7HSR can be prevented. As a result, the resistance component can be reduced by shortening the loop distance of the metal ribbon 7HSR. Moreover, if the loop distance of the metal ribbon 7HSR is shortened, shortening of the distance between the tab 3H and the tab 3L is facilitated; therefore, the semiconductor device 1 can be further downsized.

Moreover, in the example shown in FIG. 6, the height of the ribbon-connecting surface 3Ba of the tab 3L and the height of the ribbon-connecting surface 4Ba of the lead 4LS are at the same height. Moreover, the height of the ribbon-connecting surface 3Ba of the tab 3L shown in FIG. 6 and the height of the wire connecting surfaces 4Bwa of the wire connecting parts 4Bw of the leads 4HG and 4LG shown in FIG. 7 and FIG. 8 (in a strict sense, the height of the joining surfaces of the metal film 4BwM and the base materials of the leads 4HG and 4LG) are at the same height.

By aligning the height of the ribbon-connecting surface 4Ba with the height of the ribbon-connecting surface 4Ba and the wire connecting surface 4Bwa in this manner, management of the bending angle can be easily carried out when the tab 3L and the leads 4LS, 4HG, and 4LG are subjected to bending. Therefore, the bent part 3W of the tab 3L and the bent parts 4W of the leads 4LS, 4HG, and 4LG shown in FIG. 5 can be formed at a time.

<Manufacturing Method of Semiconductor Device>

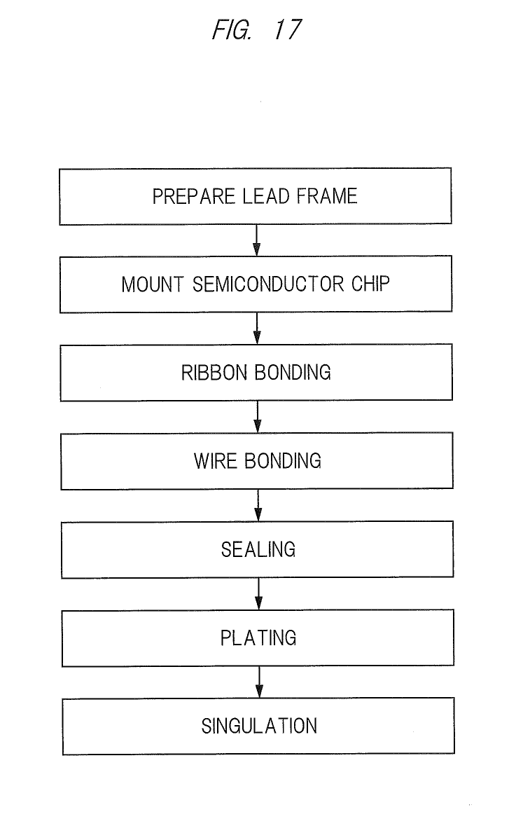

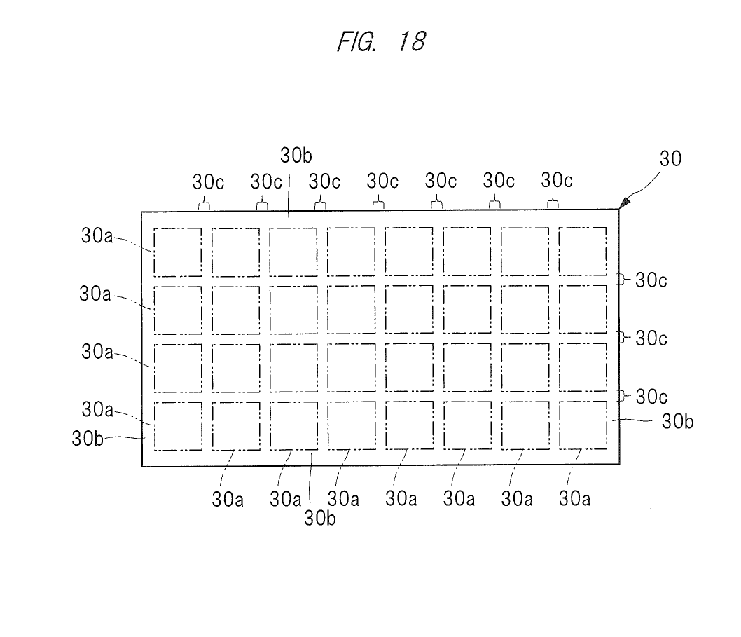

Next, manufacturing processes of the semiconductor device 1 explained by using FIG. 1 to FIG. 14 will be explained. The semiconductor device 1 is manufactured along the flow shown in FIG. 17. FIG. 17 is an explanatory diagram showing outlines of the manufacturing processes of the semiconductor device explained by using FIG. 1 to FIG. 14. Details of the processes will be explained below by using FIG. 18 to FIG. 36.

<Lead Frame Preparing Process>

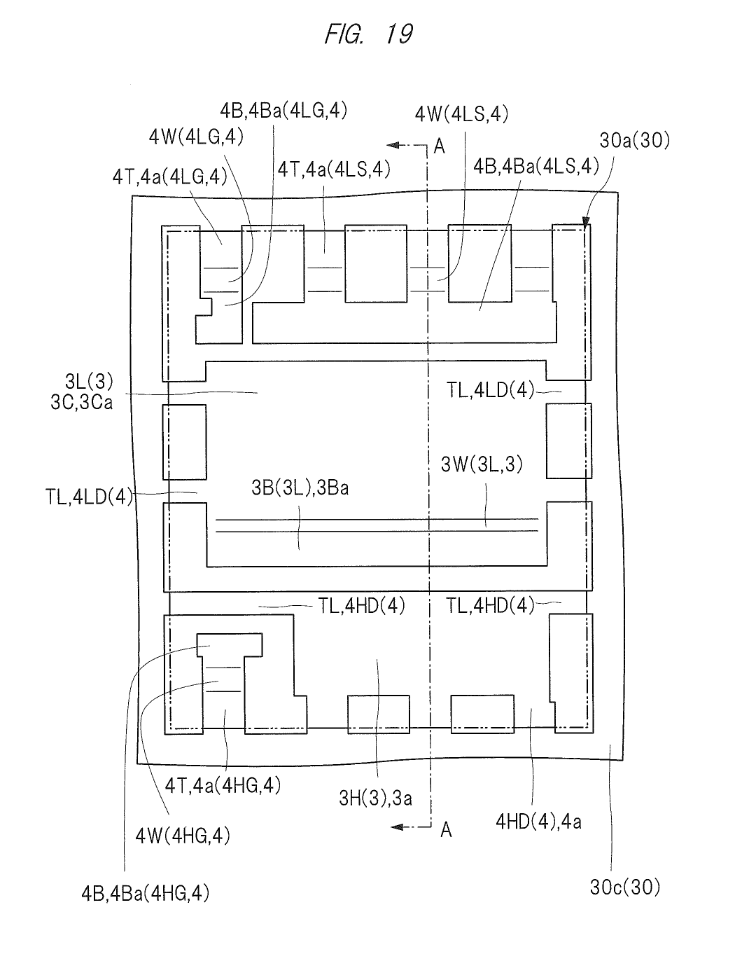

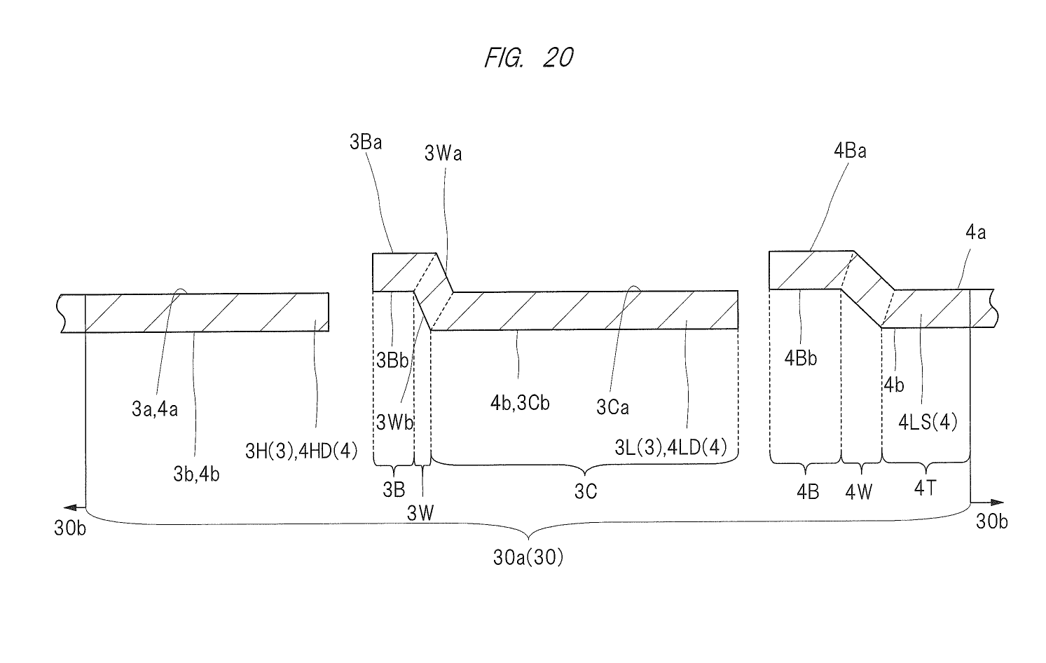

First, in a lead frame preparing process shown in FIG. 17, a lead frame 30 shown in FIG. 18 to FIG. 20 is prepared. FIG. 18 is a plan view showing an overall structure of a lead frame prepared in a lead-frame preparing process shown in FIG. 17. FIG. 19 is an enlarged plan view corresponding to a single device region shown in FIG. 18. FIG. 20 is an enlarged cross-sectional view along a line A-A of FIG. 19.

As shown in FIG. 18, the lead frame 30 prepared in the present process is provided with a plurality (32 in FIG. 18) of device regions 30a in the inner side of an outer frame 30b. Each of the plurality of device regions 30a corresponds to the single semiconductor device 1 shown in FIG. 5. The lead frame 30 is a so-called multiple-piece providing base material on which the plurality of device regions 30a are disposed in a matrix shape. Since the plurality of semiconductor devices 1 can be manufactured at a time by using the lead frame 30 provided with the plurality of device regions 30a in this manner, manufacturing efficiency can be improved.

The periphery of each of the device regions 30a is surrounded by a frame part 30c as shown in FIG. 19. The frame part 30c is a supporting part, which supports the members formed in the device region 30a until a singulation process shown in FIG. 17.

Moreover, as shown in FIG. 19 and FIG. 20, the plurality of tabs 3 (the tab 3H and the tab 3L) and the plurality of leads 4 explained by using FIG. 5 and FIG. 6 have been already formed in each of the device regions 30a. The plurality of tabs 3 are coupled to the frame part 30c, which is disposed in the periphery of the device region 30a, via the suspension leads TL and are supported by the frame part 30c. Moreover, each of the plurality of leads 4 is coupled to the frame part 30c and supported by the frame part 30c.

In the example shown in FIG. 19, the tab 3H, the tab 3L, and the lead 4LS are arranged in this order from a first side to the opposed side of the device region 30a, which forms a tetragon in a plan view. Moreover, adjacent to the lead 4HD integrally formed with the tab 3H, the lead 4HD is disposed. Moreover, adjacent to the lead 4LS, the lead 4LG is disposed.

Moreover, the tab 3L and the leads 4HG, 4LS, and 4LG have been subjected to bending in advance to form the bent parts 3W and 4W. In other words, the ribbon-connecting surface 3Ba of the ribbon-connecting part 3B of the tab 3L is disposed at a position higher than the chip-mounting surface 3Ca of the chip-connecting part 3C of the tab 3L. The bent parts 3W and 4W can be formed by, for example, pressing.

In a case in which the bent part 3W is formed by bending (pressing), the thickness of the ribbon-connecting part 3B has the same thickness as the thickness of the chip mounting region of the tab 3L as shown in FIG. 20. In other words, in the thickness direction of the tab 3L, the thickness from the ribbon-connecting surface 3Ba to the lower surface immediately below the ribbon-connecting surface 3Ba is equal to the thickness from the chip-mounting surface 3Ca, which is a chip-mounting surface, to the lower surface 3Cb immediately below the chip-mounting surface 3Ca.

Similarly, in a case in which the bent part 4W is formed by bending (pressing), as shown in FIG. 20, the thickness of the ribbon-connecting part 4B has the same thickness as the thickness of the terminal part 4T of the lead 4LS. In other words, in the thickness direction of the lead 4LS, the thickness from the ribbon-connecting surface 4Ba to the lower surface immediately below the ribbon-connecting surface 4Ba is equal to the thickness from the upper surface 4a, which is a chip-mounting surface, to the lower surface 4b, which is an exposed surface. In this manner, the method of subjecting the tab 3L or the lead 4LS to bending is preferred in a point that they can be easily processed.

The lead frame 30 consists of, for example, a metal member mainly consisting of copper (Cu). Although illustration is omitted, the metal film 4Bwm explained by using FIG. 7 or FIG. 8 is formed in advance on the lead HG shown in FIG. 19 and the wire connecting surface 4Bwa of the wire connecting part 4Bw of the lead LG. On the other hand, the metal film 4BwM (see FIG. 7, FIG. 8) is not formed on the chip-mounting surface 3Ca of the chip-connecting part 3C of the tab 3L shown in FIG. 20, and the base material (for example, copper) thereof is exposed. In a case of ribbon bonding, since metal bonding is formed by applying ultrasonic waves to the bonding tool 23 as shown in FIG. 13 and FIG. 14, joining strength can be improved when the metal material of the base material is exposed rather than a metal film 4BM is.

Moreover, if a solder material is used as a die-bond material in a later-described semiconductor-chip mounting process, from the viewpoint of improving the wettability of the solder material, it is preferred to form a metal film (illustration omitted) of nickel (Ni), silver (Ag), or the like on the chip-mounting surface 3Ca. However, in the present embodiment, as described above, the electrically-conductive adhesive material in which a plurality of electrically-conductive particles (for example, silver particles) are mixed in a resin material is used; therefore, from the viewpoint of improving the wettability and adhesiveness of the electrically-conductive adhesive material and the tab 3L, the above-described metal film is not formed, and the base material (for example, copper) is exposed.

The characteristics other than those described above about the lead frame 30 prepared in the present process are as explained by using FIG. 5 to FIG. 14. Therefore, redundant explanations will be omitted.

<Semiconductor-Chip Mounting Process>

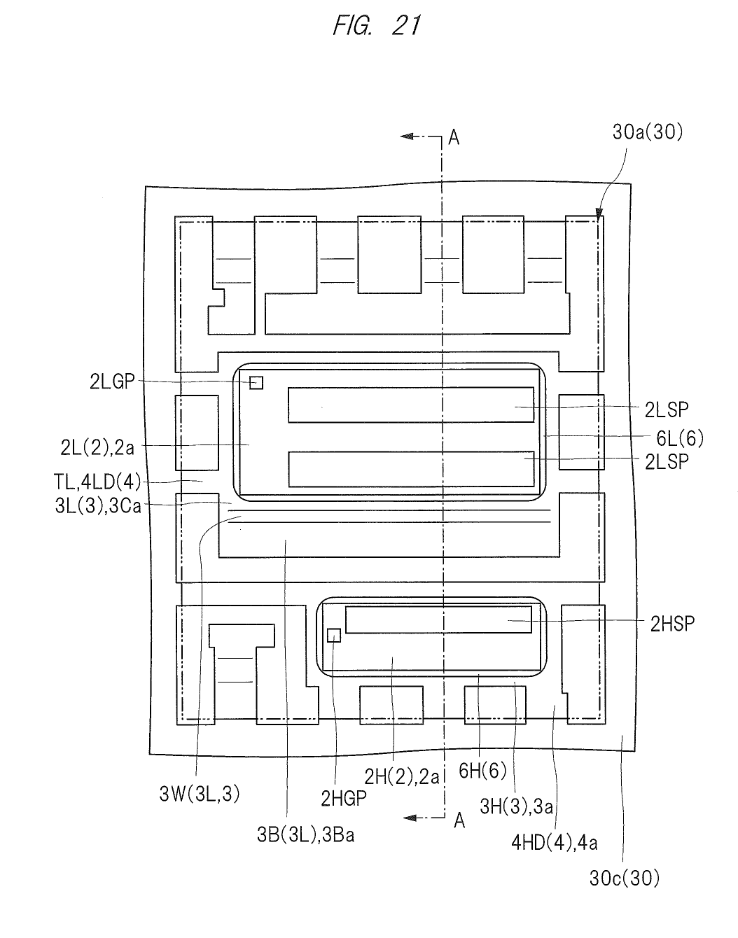

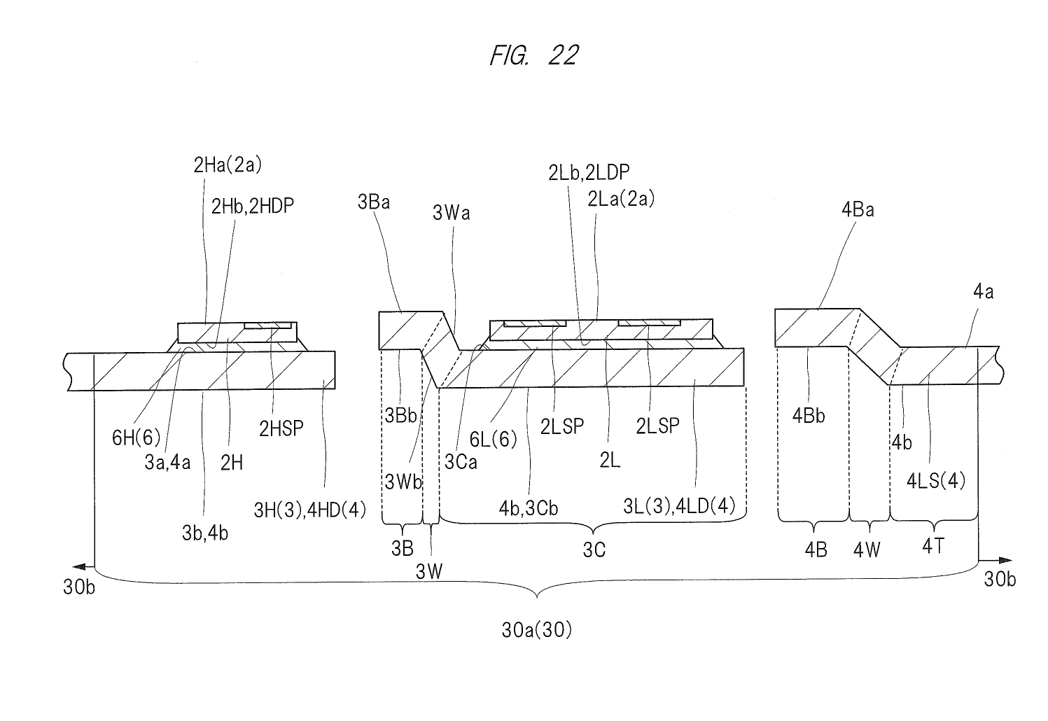

Then, in the semiconductor-chip mounting process shown in FIG. 17, as shown in FIG. 21 and FIG. 22, the semiconductor chips 2H and 2L are mounted on the tabs 3H and 3L of the lead frame 30. FIG. 21 is an enlarged plan view showing a state in which semiconductor chips are respectively mounted on a plurality of chip-mounting parts shown in FIG. 19. FIG. 22 is an enlarged cross-sectional view taken along a line A-A of FIG. 21.

In the present process, the semiconductor chip 2H provided with the high-side MOSFET is mounted on the tab 3H, which also serves as the lead 4HD which is a high-side drain terminal. As shown in FIG. 22, the semiconductor chip 2H is bonded and fixed via the electrically-conductive adhesive material 6H so that the back surface 2Hb on which the drain electrode 2HDP is formed is opposed to the chip-mounting surface 3Ca of the tab 3H.

Moreover, in the present process, on the tab 3L, which also serves as the lead 4LD which is the high-side source terminal and the low-side drain terminal, the semiconductor chip 2L provided with the low-side MOSFET is mounted. As shown in FIG. 22, the semiconductor chip 2L is bonded and fixed via the electrically-conductive adhesive material 6L so that the back surface 2Lb on which the drain electrode 2LDP is formed is opposed to the chip-mounting surface 3Ca of the tab 3L.

The electrically-conductive adhesive materials 6H and 6L are the electrically-conductive members 6, in which a plurality of electrically-conductive particles (for example, silver particles) are mixed in a resin material containing a thermosetting resin such as an epoxy resin. The state of such an electrically-conductive adhesive material before hardening is in the form of paste. Therefore, after the electrically-conductive adhesive materials 6H and 6L in the form of paste are applied to the chip-mounting surfaces of the tabs 3H and 3L in advance, the semiconductor chips 2H and 2L are pressed against the chip-mounting surfaces. As a result, the electrically-conductive adhesive materials 6H and 6L can be spread between the semiconductor chips 2H and 2L and the chip-mounting surfaces 3Ca of the tabs 3H and 3L.

At this point, in the ribbon bonding process shown in FIG. 17, the ribbon-connecting surface 3Ba of the ribbon-connecting part 3B shown in FIG. 22, which is a region to be joined with a first end of the metal ribbon 7HSR (see FIG. 6), is disposed at a position higher than the chip-mounting surface 3Ca of the chip-connecting part 3C of the tab 3L. Therefore, for example, when the electrically-conductive adhesive material 6L is pressed and spread, reaching of the electrically-conductive adhesive material 6L to the ribbon-connecting surface 3Ba of the ribbon-connecting part 3B can be prevented or suppressed.

Therefore, even when the semiconductor chip 2L is mounted in the vicinity of the ribbon-connecting surface 3Ba of the ribbon-connecting part 3B, contamination of the ribbon-connecting surface 3Ba by the electrically-conductive adhesive material 6L can be suppressed. As a result, in the ribbon bonding process shown in FIG. 17, the first end of the metal ribbon 7HSR (see FIG. 6) can be stably joined. In other words, according to the present embodiment, since spreading of the electrically-conductive adhesive material 6L can be regulated by causing the height of the ribbon-connecting surface 3Ba to be higher than the chip-mounting surface 3Ca of the chip-connecting part 3C, the semiconductor chip 2L and the ribbon-connecting part 3B can be positioned to be closer to each other. As a result, the planar size of the entire tab 3L can be reduced; therefore, the semiconductor device 1 (see FIG. 5) can be downsized.

Then, in the present process, after the semiconductor chips 2H and 2L are mounted on the tabs 3H and 3L, respectively, the electrically-conductive adhesive materials 6H and 6L are hardened at a time (curing process). Since the electrically-conductive adhesive materials 6H and 6L contain the thermosetting resin as described above, the thermosetting resin components contained in the electrically-conductive adhesive materials 6H and 6L are hardened by carrying out heating treatment (baking treatment). An example of baking conditions is about 60 to 120 minutes in a temperature range of 180 to 250° C. In the present process, the drain electrode 2HDP of the semiconductor chip 2H is electrically connected to the tab 3H (the lead 4HD) via the electrically-conductive adhesive material 6H (specifically, the plurality of electrically-conductive particles in the electrically-conductive adhesive material 6H). Moreover, the drain electrode 2LDP of the semiconductor chip 2L is electrically connected to the tab 3L (the lead 4LD) via the electrically-conductive adhesive material 6L (specifically, the plurality of electrically-conductive particles in the electrically-conductive adhesive material 6L).

In this curing process, organic components such as a binder resin contained in the electrically-conductive adhesive materials 6H and 6L are easily generated as a gas (out-gas) or liquid (bleed) from the electrically-conductive adhesive materials 6H and 6L. When the organic components attach to the ribbon bonding surface 3Ba, they serve as an obstructive factor when the first end of the metal ribbon 7HSR (see FIG. 6) is joined in the ribbon bonding process shown in FIG. 17. However, according to the present embodiment, the height of the ribbon-connecting surface 3Ba is caused to be higher than the chip-mounting surface 3Ca (the ribbon-connecting surface 3Ba is disposed to be separated from the chip-mounting surface 3Ca); as a result, the out-gas and bleed do not easily attach to the ribbon-connecting surface 3Ba. As a result, in the ribbon bonding process shown in FIG. 17, the first end of the metal ribbon 7HSR (see FIG. 6) can be stably joined. In other words, according to the present embodiment, contamination of the ribbon-connecting surface 3Ba due to the out-gas and bleed can be suppressed by causing the height of the ribbon-connecting surface 3Ba to be higher than the chip-mounting surface 3Ca; therefore, the semiconductor chip 2L and the ribbon-connecting part 3B can be positioned to be closer to each other. As a result, the planar size of the entire tab 3L can be reduced. Therefore, the semiconductor device 1 (see FIG. 5) can be downsized.

Moreover, according to the present embodiment, the electrically-conductive adhesive materials 6H and 6L can be hardened at a time. In other words, a step of hardening the electrically-conductive adhesive material 6H and a step of hardening the electrically-conductive adhesive material 6L are not required to be separately provided. Therefore, as whole assembly processes of the package, the manufacturing processes can be simplified.

In order to harden the electrically-conductive adhesive materials 6H and 6L at a time in the present process, the curing process has to be carried out after the semiconductor chips 2H and 2L are mounted; however, the mounting order of the semiconductor chips 2H and 2L may be arbitrary. Thus, one of the semiconductor chips 2H and 2L can be mounted first, and the other can be mounted thereafter.

The structures of the semiconductor chips 2H and 2L have been already explained by using FIG. 1 and FIG. 2. Therefore, redundant explanations thereof are omitted.

<Ribbon Bonding Process>

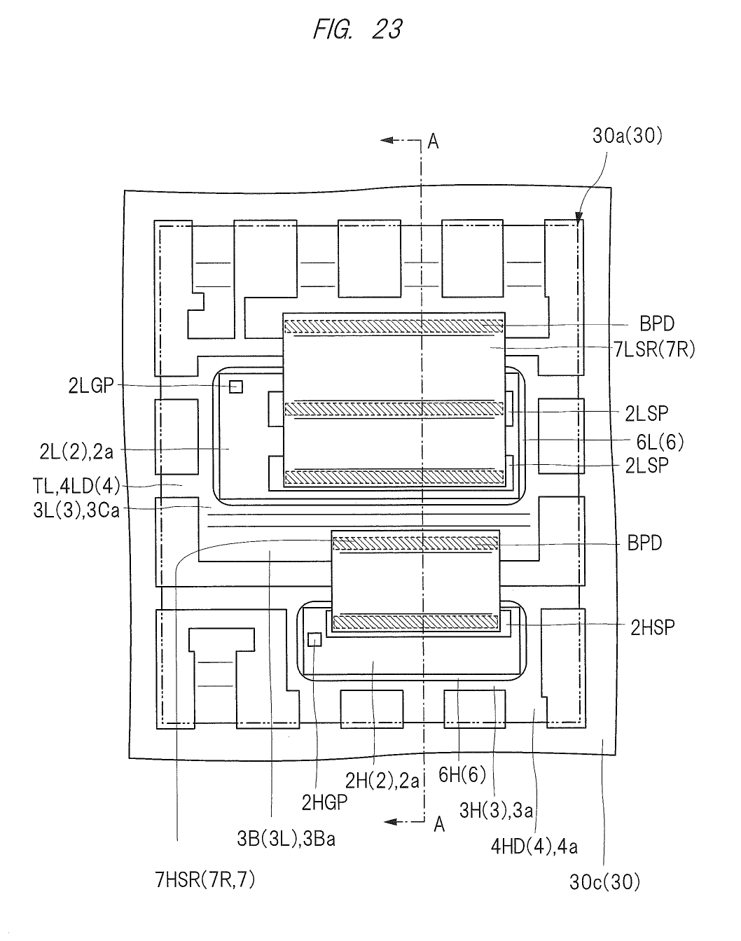

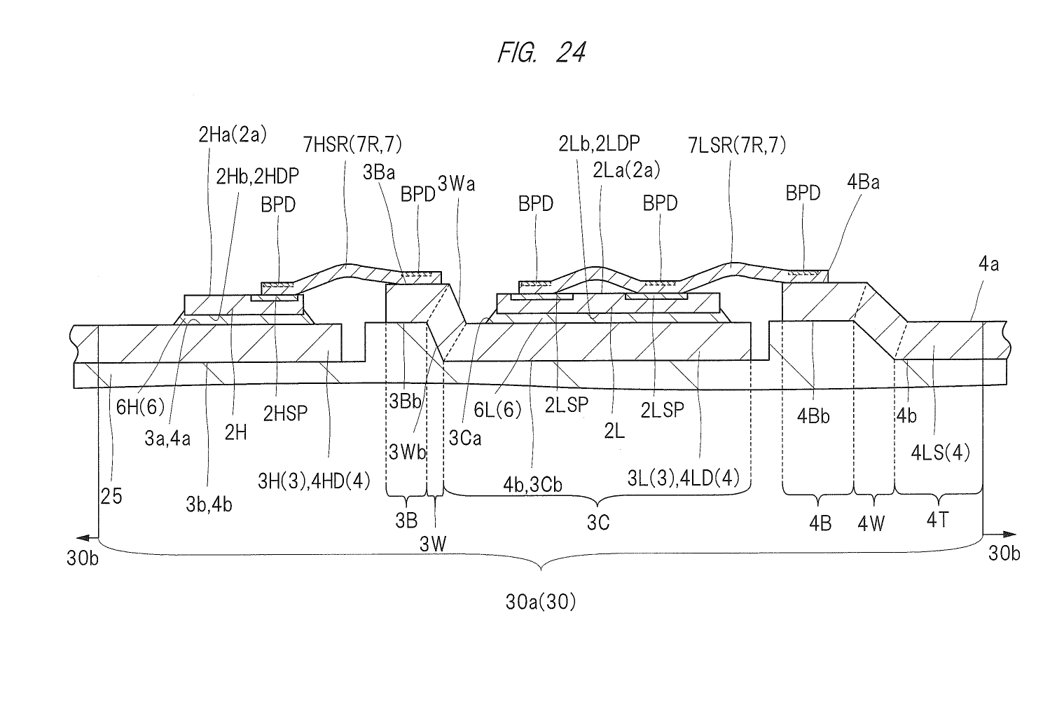

In the ribbon bonding process shown in FIG. 17, as shown in FIG. 23 and FIG. 24, the source electrode pad 2HSP of the semiconductor chip 2H and the ribbon-connecting surface 3Ba of the ribbon-connecting part 3B of the tab 3L are electrically connected via the metal ribbon 7HSR. Moreover, in the present process, the source electrode pad 2LSP of the semiconductor chip 2L and the ribbon-connecting surface 4Ba of the ribbon-connecting part 4B of the lead 4LS are electrically connected via the metal ribbon 7LSR.

FIG. 23 is an enlarged plan view showing a state in which the plurality of semiconductor chips and a plurality of leads shown in FIG. 21 are electrically connected via metal ribbons. In addition, FIG. 24 is an enlarged cross-sectional view taken along a line A-A of FIG. 23. FIGS. 25 to 29 are enlarged cross-sectional views each showing a state in which a high-side source electrode pad is joined with a metal ribbon shown in FIG. 24;

In the present process, the metal ribbons 7HSR and 7LSR are sequentially formed by the ribbon bonding method explained by using FIG. 13 and FIG. 14. Which one of the metal ribbons 7HSR and 7LSR is to be formed first can be determined by the layout of the ribbon-connecting part; however, in a case in which the ribbon-connecting part 3B of the tab 3L shown in FIG. 24 serves as the second bonding side of the metal ribbon 7HSR, it is preferred to form (bonding) the metal ribbon 7HSR first. In this case, the metal ribbon 7HSR is joined with the ribbon-connecting part 3B in the state in which the metal ribbon 7LSR is not formed on the top surface 2La of the semiconductor chip 2L; therefore, the bonding tool 23 can be easily moved.

In the present process, first, as shown in FIG. 25, a first end of the metal strip 20 (first end of the metal ribbon 7HSR shown in FIG. 24) is joined with the source electrode pad 2HSP of the high-side semiconductor chip 2H. In this process, when the metal strip 20 is pressed against the source electrode pad 2HSP, the shape of the metal strip 20 is deformed along the bonding tool 23. When ultrasonic waves are applied to the bonding tool 23, metal bonding is formed at the contact interface of the metal strip 20 and the source electrode pad 2HSP, and the metal strip 20 and the source electrode pad 2HSP can be electrically connected to each other.

The lower surface 3b positioned in the side of the tab 3H that is opposite to the chip-mounting surface adheres to a tab retaining surface 25a of a supporting base 25 and is retained by the supporting base 25. When bonding is carried out in the state in which the source electrode pad 2HSP, which is a part to be joined, is supported by the supporting base 25 in this manner, the ultrasonic waves applied to the bonding tool 23 is efficiently transmitted to the joining surface of the metal strip 20. As a result, the joining strength of the metal strip 20 and the source electrode pad 2HSP can be improved. It is preferred to use, for example, a table made of metal (metal table) as the supporting base 25 so that the ultrasonic waves applied to the bonding tool 23 are transmitted to the joining interface in a concentrated manner.

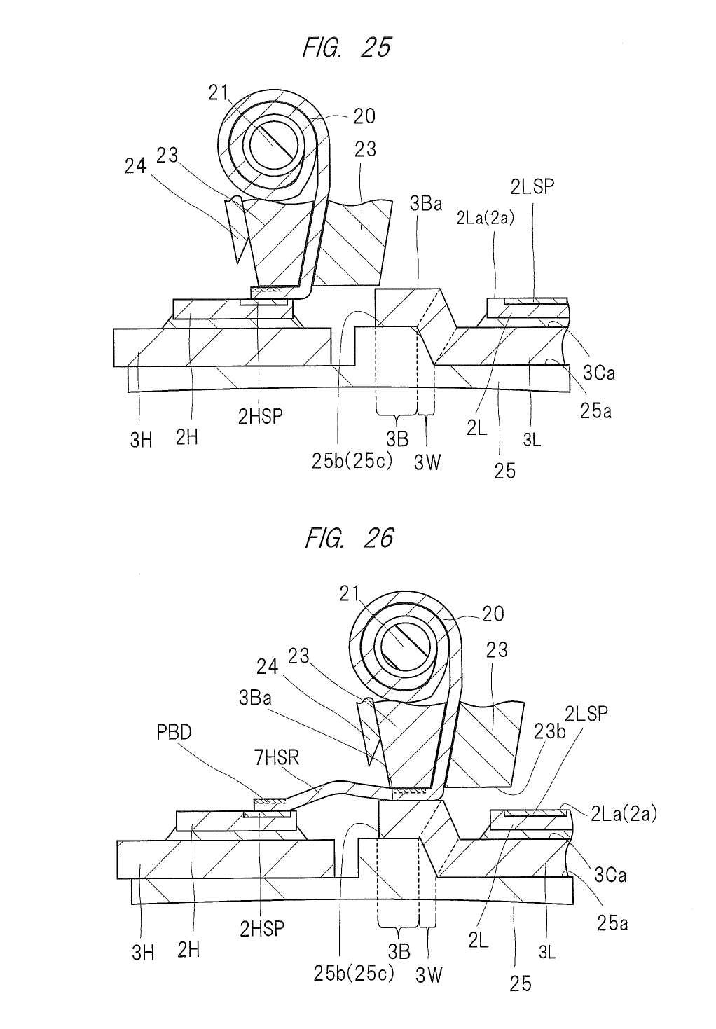

Then, while the metal strip 20 is sequentially fed from the reel 21 retaining the metal strip 20, the bonding tool 23 is moved to join the second end of the metal strip 20 with the chip-mounting surface 3Ca of the ribbon-connecting part 3B of the tab 3L as shown in FIG. 26. In this process, when the metal strip 20 is pressed against the ribbon-connecting surface 3Ba of the tab 3L, the metal strip 20 is deformed to adhere to the ribbon-connecting surface 3Ba of the tab 3L along the bonding tool 23. Moreover, when ultrasonic waves are applied to the bonding tool 23, metal bonding is formed at the joining interface of the metal strip 20 and the ribbon-connecting surface 3Ba of the ribbon-connecting part 3B, and the metal strip 20 and the ribbon-connecting surface 3Ba of the ribbon-connecting part 3B can be electrically connected.

Meanwhile, the lower surface positioned in the side of the ribbon-connecting part 3B that is opposite to (immediately below) the ribbon-connecting surface 3Ba adheres to a ribbon-connecting-part retaining surface 25b of the supporting base 25 and is retained by the supporting base 25. In the example shown in FIG. 26, since the tab 3L has undergone bending as described above, the ribbon-connecting-part retaining surface 25b is disposed at a position higher than the tab retaining surface 25a. When bonding is carried out in the state in which the ribbon-connecting surface 3Ba of the ribbon-connecting part 3B, which is a part to be joined, is supported by the ribbon-connecting-part retaining surface 25b of the supporting base 25 in this manner, the ultrasonic waves applied to the bonding tool 23 are efficiently transmitted to the joining surface of the metal strip 20. As a result, the joining strength of the metal strip 20 and the ribbon-connecting part 3B can be improved.

Moreover, in the example shown in FIG. 26, since the semiconductor chip 2L is disposed in the vicinity of the ribbon-connecting part 3B, part of the bonding tool 23 and the semiconductor chip 2L are overlapped in the thickness direction. In other words, part of the lower surface 23b of the bonding tool 23 and the top surface 2La of the semiconductor chip 2L are opposed to each other. However, according to the present embodiment, the position of the ribbon-connecting surface 3Ba of the ribbon-connecting part 3B is positioned to be higher than the chip-mounting surface 3Ca, which is the chip-mounting surface of the tab 3L, so that the lower surface 23b of the bonding tool 23 is positioned at the position higher than the top surface 2La of the semiconductor chip 2L upon ribbon bonding.

Therefore, as shown in FIG. 26, even in the case in which the semiconductor chip 2L is disposed to be close to the ribbon-connecting-part-3B side so that the part of the bonding tool 23 and the semiconductor chip 2L are overlapped with each other in the thickness direction when the metal strip 20 is joined with the ribbon-connecting part 3B, contact between the bonding tool 23 and the semiconductor chip 2L can be prevented or suppressed.

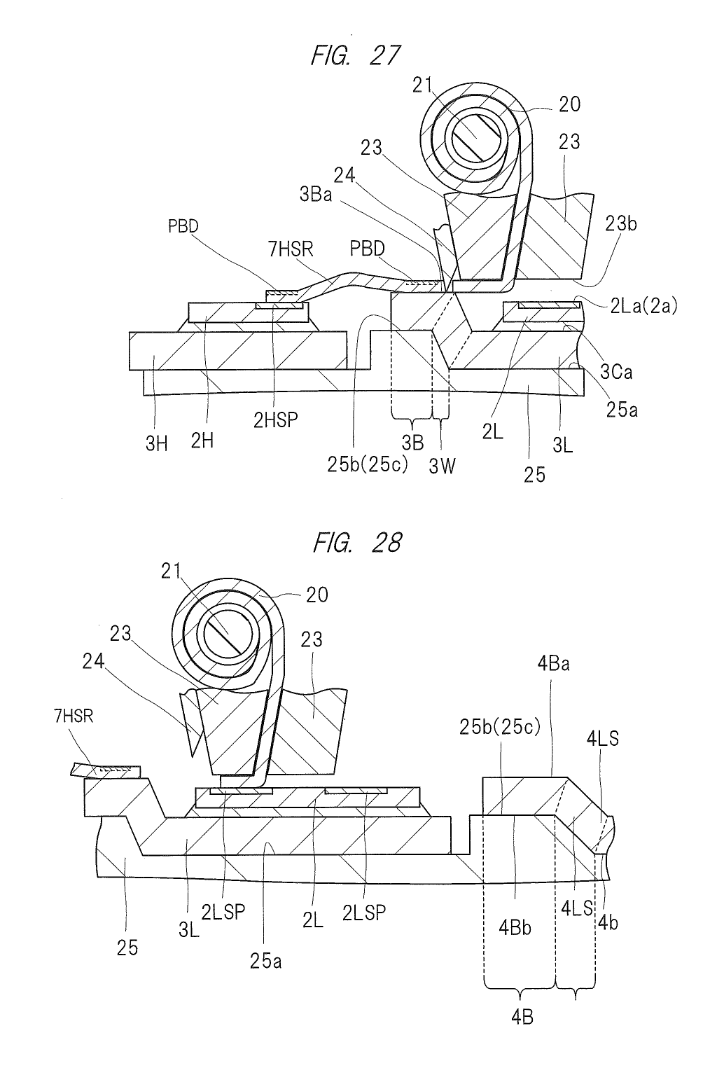

Then, as shown in FIG. 27, the bonding tool 23 is further moved to the semiconductor-chip-2L side along the ribbon-connecting surface 3Ba. Then, the metal strip 20 is cut by pressing the cutting blade 24 against the metal strip 20. As a result, the metal ribbon 7HSR, which electrically connects the source electrode pad 2HSP of the semiconductor chip 2H and the ribbon-connecting part 3B integrally formed with the tab 3L, is formed to be separated from the metal strip 20. In this process, the cutting position by the cutting blade 24 is preferred to be above the ribbon-connecting surface 3Ba of the ribbon-connecting part 3B. The metal strip 20 can be stably cut when the metal strip 20 is cut in a state that the metal strip is sandwiched between the cutting blade 24 and the ribbon-connecting surface 3Ba.

Moreover, according to the present embodiment, the position of the ribbon-connecting surface 3Ba of the ribbon-connecting part 3B is positioned to be higher than the chip-mounting surface 3Ca, which is the chip-mounting surface of the tab 3L, so that the lower surface 23b of the bonding tool 23 is disposed at a position higher than the top surface 2La of the semiconductor chip 2L upon ribbon bonding. Therefore, as shown in FIG. 27, even in the case in which the semiconductor chip 2L is disposed to be closer to the ribbon-connecting-part-3B side so that part of the bonding tool 23 and the semiconductor chip 2L are overlapped with each other in the thickness direction when the metal strip 20 is cut, contact of the bonding tool 23 and the semiconductor chip 2L can be prevented or suppressed.

Then, as shown in FIG. 28, a first end of the metal strip 20 (first end of the metal ribbon 7LSR shown in FIG. 24) is joined with the source electrode pad 2LSP of the low-side semiconductor chip 2L. The metal ribbon 7HSR and the metal ribbon 7LSR shown in FIG. 23 have mutually different widths. Therefore, the metal ribbon 7LSR (see FIG. 24) is joined by using the bonding tool 23 which supplies a metal strip 20 having a width different from that of the bonding tool 23 used when the metal ribbon 7HSR is joined. However, except for the point that the width of the supplied metal strip 20 is different, it has a structure similar to that of the bonding tool 23 shown in FIG. 25 to FIG. 27; therefore, it is shown as the bonding tool 23, and redundant explanations will be omitted.

In the present process, by applying the ultrasonic waves to the bonding tool 23, metal bonding is formed at the contact interface of the metal strip 20 and the source electrode pad 2LSP, the metal strip 20 and the source electrode pad 2HSP can be electrically connected. Meanwhile, the lower surface 3Cb positioned in the side of the tab 3L that is opposite to the chip-mounting surface 3Ca adheres to the tab retaining surface 25a of the supporting base 25 and is retained by the supporting base 25. Therefore, the ultrasonic waves applied to the bonding tool 23 are efficiently transmitted to the joining surface of the metal strip 20. As a result, the joining strength of the metal strip 20 and the source electrode pad 2LSP can be improved.

In the example shown in FIG. 24, the low-side source electrode pads 2LSP are formed to be separately at two locations. Therefore, in the present process, the bonding tool 23 is sequentially moved onto the source electrode pads 2LSP at the two locations, and the metal strip 20 is sequentially joined. Since the joining method is similar, illustration thereof is omitted.

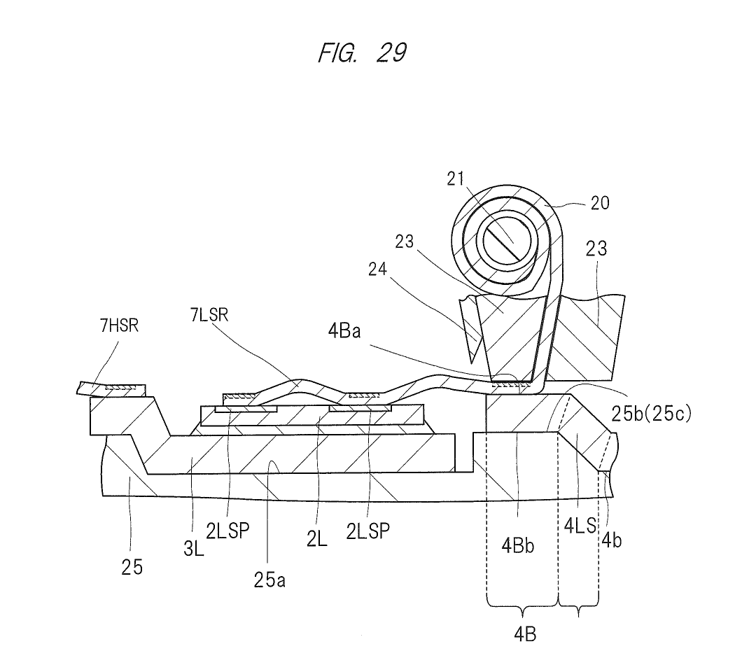

Then, the bonding tool 23 is moved while the metal strip 20 is sequentially fed from the reel 21 retaining the metal strip 20, and, as shown in FIG. 29, the second end of the metal strip 20 is joined with the upper surface 4a of the ribbon-connecting part 4B of the lead 4LS. In this process, when the metal strip 20 is pressed against the ribbon-connecting surface 4Ba of the lead 4LS, the metal strip 20 is deformed to adhere to the ribbon-connecting surface 4Ba along the bonding tool 23. Moreover, when ultrasonic waves are applied to the bonding tool 23, metal bonding is formed at the contact interface of the metal strip 20 and the ribbon-connecting surface 4Ba of the ribbon-connecting part 4B, and the metal strip 20 and the ribbon-connecting surface 4Ba of the ribbon-connecting part 4B can be electrically connected.

Since the semiconductor chip is not mounted on the lead 4LS, the problem of the contact between the bonding tool 23 and the semiconductor chip upon ribbon bonding does not occur. However, as explained by using FIG. 6, from the viewpoint of causing the lead 4LS not to easily fall from the seal 5, the ribbon-connecting surface 4Ba of the ribbon-connecting part 4B of the lead 4LS is preferred to be positioned at a position higher than the upper surface 4a of the terminal part 4T.

Therefore, in the present process, the lower surface positioned in the side of the ribbon-connecting part 4B that is opposite to (immediately below) the upper surface 4a adheres to the ribbon-connecting-part retaining surface 25b of the supporting base 25 and is retained by the supporting base 25. In the example shown in FIG. 29, a projecting part 25c is provided at part of the supporting base 25, and the upper surface of the projecting part serves as the ribbon-connecting-part retaining surface 25b. When bonding is carried out in the state in which the ribbon-connecting surface 4Ba of the ribbon-connecting part 4B, which is the part to be joined, is supported by the ribbon-connecting-part retaining surface 25b of the supporting base 25 in this manner, the ultrasonic waves applied to the bonding tool 23 are efficiently transmitted to the joining surface of the metal strip 20. As a result, the joining strength of the metal strip 20 and the ribbon-connecting part 4B can be improved.

Then, the bonding tool 23 is further moved to the semiconductor-chip-2L side along the ribbon-connecting surface 4Ba. Then, the metal strip 20 is cut by pressing the cutting blade 24 against the metal strip 20. Since the cutting method of the metal strip 20 is similar to the method explained by using FIG. 27, illustration and redundant explanations are omitted.

Through the above processes, as shown in FIG. 23 and FIG. 24, the source electrode pad 2HSP of the semiconductor chip 2H and the ribbon-connecting surface 3Ba of the ribbon-connecting part 3B of the tab 3L are electrically connected to each other via the metal ribbon 7HSR. Also, the source electrode pads 2LSP of the semiconductor chip 2L and the ribbon-connecting surface 4Ba of the ribbon-connecting part 4B of the lad 4LS are electrically connected to each other via the metal ribbon 7LSR.

<Wire Bonding Process>

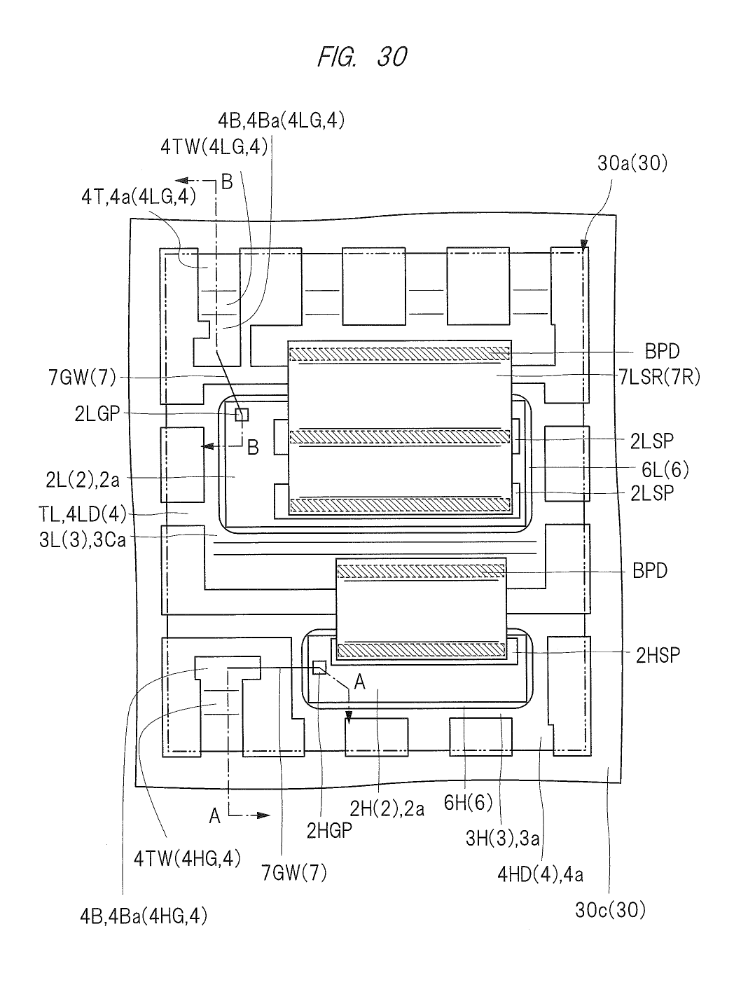

Moreover, in a wire bonding process shown in FIG. 17, as shown in FIG. 30 to FIG. 32, the gate electrode pad 2HGP of the semiconductor chip 2H and the ribbon-connecting surface 4Ba of the ribbon-connecting part 4B of the lead 4HG are electrically connected to each other via the wire (metal wire) 7GW. Moreover, in the present process, the gate electrode pad 2LGP of the semiconductor chip 2L and the ribbon-connecting surface 4Ba of the ribbon-connecting part 4B of the lead 4LG are electrically connected to each other via the wire (metal wire) 7GW.

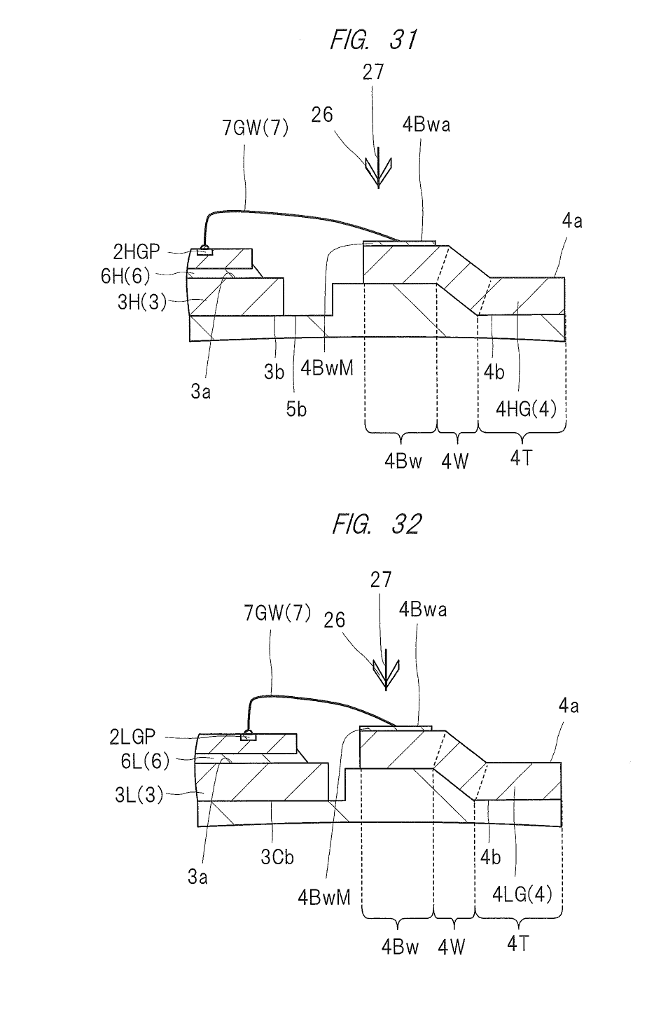

FIG. 30 is an enlarged plan view showing a state in which the plurality of semiconductor chips and the plurality of leads shown in FIG. 23 are electrically connected via wires. In addition, FIG. 31 is an enlarged cross-sectional view taken along a line A-A of FIG. 30. Further, FIG. 32 is an enlarged cross-sectional view taken along a line B-B of FIG. 30.

As shown in FIG. 31 or FIG. 32, in the present process, part of the wire 7GW is joined with the part to be joined by metal bonding by applying ultrasonic waves to a bonding tool 26. For example, in the example shown in FIG. 31 and FIG. 32, first, a first end of the wire 7GW consisting of, for example, gold (Au) is joined with the metal film (for example, an aluminum film or a gold film) formed on the uppermost surface of the gate electrode pad 2HGP or 2LGP. In this process, the metal bonding is formed at the joining interface by applying ultrasonic waves to the bonding tool 26.

Then, the bonding tool 26 is moved to above the ribbon-connecting part 4B while feeding a wire 27 from the bonding tool 26. The metal film 4BM, which can improve the connection strength between the wire 7GW and the base material (for example, copper) of the lead 4HG or 4LG, is formed on the ribbon-connecting surface 4Ba of the ribbon-connecting part 4B of the lead 4HG or 4LG. The base material of the leads 4HG and 4LG consists of, for example, copper (Cu), and the metal film 4B consists of, for example, silver (Ag). Then, by applying ultrasonic waves to the bonding tool 26, metal bonding is formed at the joining interface of part of the wire (second bonding part) and the metal film 4B, and they are electrically connected to each other. Then, when the wire 27 is cut, the wire 7GW shown in FIG. 31 and FIG. 32 is formed.

In the present process, from the viewpoint of efficiently transmitting ultrasonic waves to the part to be joined and improving joining strength, it is preferred to apply the ultrasonic waves to the bonding tool 26 in the state in which the part to be joined is supported by the supporting base 28.

FIG. 17 shows that the wire bonding process is carried out after the ribbon bonding process. However, as a modification example, the wire bonding process can be carried out after the ribbon bonding process is carried out. However, the bonding tool 23 (see FIG. 25 to FIG. 29) used in the ribbon bonding process is large compared with the bonding tool 26 (see FIG. 31 and FIG. 32) used in the wire bonding process. Therefore, from the viewpoint of preventing the bonding tool 23 from contacting the wire 7GW upon ribbon bonding, it is preferred to carry out the wire bonding process after the ribbon bonding process as shown in FIG. 17. Furthermore, the power (energy) of the ultrasonic waves applied in the ribbon bonding process is larger than the power (energy) of the ultrasonic waves applied in the wire bonding in many cases. This also relates to the difference of the sizes of the above-described bonding tools; however, this is for a reason that the area of applying the ultrasonic waves by the bonding tool 23 in the ribbon bonding process is larger than the area of applying the ultrasonic waves by the bonding tool 26 in the wire bonding process. Therefore, if ribbon bonding is carried out after the wire 7GW is formed first, the risk that the wire 7GW is peeled off from the electrode pad is increased due to the influence of the power of the ultrasonic waves. Also in order to avoid such a risk, it is preferred to carry out the wire bonding process after the ribbon bonding process.

<Sealing Process>

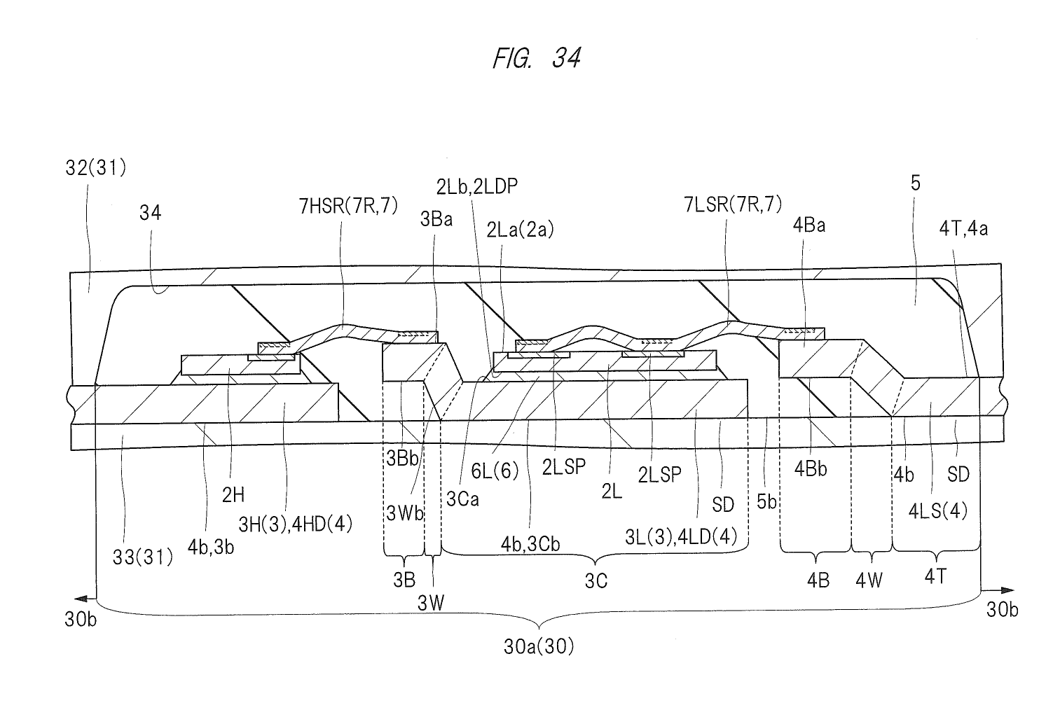

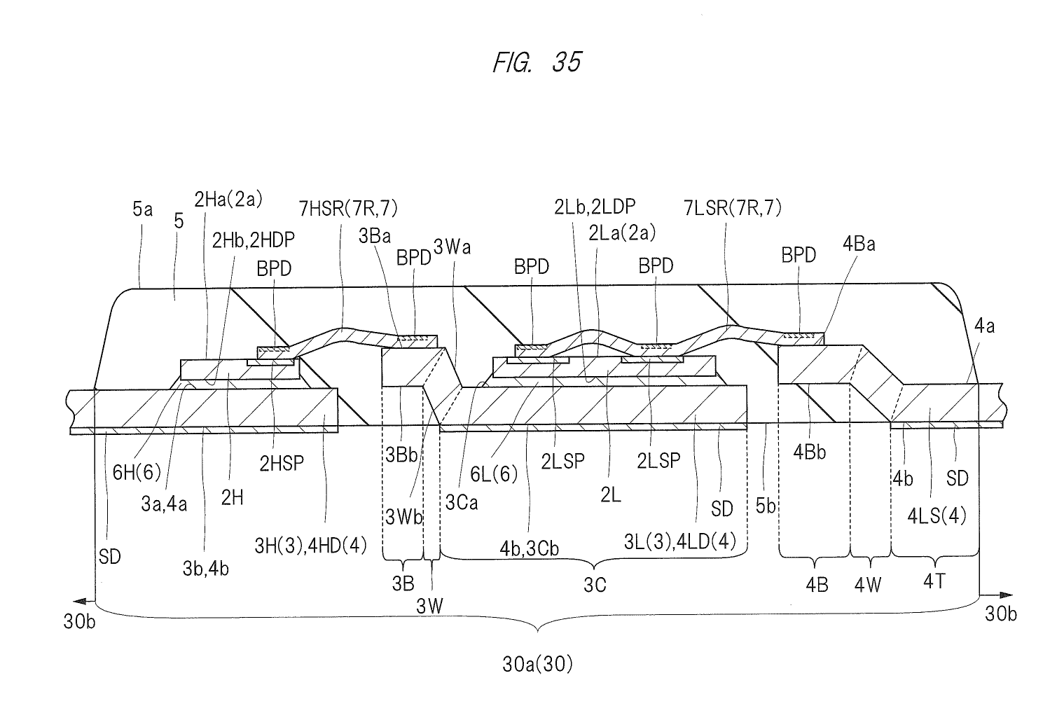

Then, in a sealing process shown in FIG. 17, as shown in FIG. 34, part of the semiconductor chips 2H and 2L and the tabs 3H and 3L; the ribbon-connecting part 4B of the lead LS4; and the metal ribbons 7HSR and 7LSR are sealed with an insulating resin to form the seal 5.

In the present process, for example, as shown in FIG. 34, the seal 5 is formed by a so-called transfer mold method by using a forming mold 31 provided with an upper mold (first mold) 32 and a lower mold (second mold) 33.

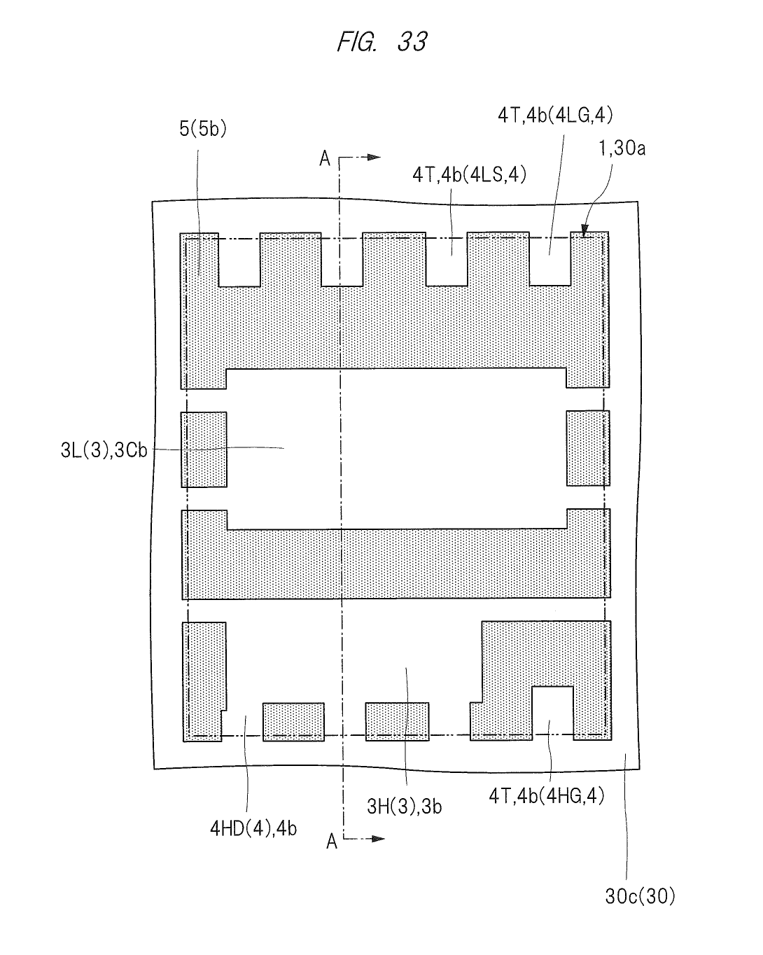

In the example shown in FIG. 33, the lead frame 30 is disposed so that the plurality of tabs 3 of the device regions 30a and the plurality of leads 4 disposed around the tabs 3 are positioned in a cavity 34 formed in the upper mold 32, and the lead frame 30 is clamped (sandwiched) by the upper mold 32 and the lower mold 33. When a softened (plasticized) thermosetting resin (insulating resin) is press-fitted in the cavity 34 of the forming mold 31 in this state, the insulating resin is supplied into the space formed by the cavity 34 and the lower mold 33 and is molded along the shape of the cavity 34.

When the lower surfaces 3b and 3Cb of the tabs 3H and 3L and the lower surface 4b of the terminal part 4T of the lead 4LS are caused to adhere to the lower mold 33 at this point, the lower surfaces 3b, 3Cb, and 4b are exposed from the seal 5 at the lower surface 5b of the seal 5. On the other hand, the lower surface of the ribbon-connecting part 3B of the tab 3L and the lower surface of the ribbon-connecting part 4B of the lead 4LS are not caused to adhere to the lower mold 33. Therefore, the ribbon-connecting parts 3B and 4B are covered with the insulating resin and sealed with the seal 5. Although illustration is omitted, also about the leads 4HG and 4LG explained by using FIG. 31 and FIG. 32, the lower surfaces 4b of the terminal parts 4T are exposed from the seal 5 shown in FIG. 33, and the ribbon-connecting parts 4B are sealed with the seal 5. Since part of the tabs 3 and the leads 4 is sealed with the seal 5 in this manner, they do not easily fall from the seal 5.

In FIG. 33, a mode of a so-called singulation mold method in which the single device region 30a is housed in the single cavity 34 is explained. However, as a modification example, for example, a method of sealing the plurality of device regions 30a at a time by using a forming mold having a cavity 34 which covers the plurality of device regions 30a shown in FIG. 18 at a time can be also applied. Such a sealing method is referred to as a one-time sealing (Block Molding) method or a MAP (Mold Array Process) method, and the effective area of the single lead frame 30 becomes large.

The seal 5 mainly consists of an insulating resin. However, for example, the function (for example, resistance against warping deformation) of the seal 5 can be improved by mixing filler particles such as silica (silicon dioxide; SiO₂) particles in the thermosetting resin.

<Plating Process>

Then, in a plating process shown in FIG. 17, as shown in FIG. 35, the lead frame 30 is immersed in an unshown plating solution to form the metal film SD on the surface of the metal parts exposed from the seal 5. FIG. 35 is an enlarged cross-sectional view showing a state in which the metal film is formed on the surfaces of the tabs and the leads shown in FIG. 34 exposed from the seal.

In the example shown in FIG. 35, for example, the lead frame 30 is immersed in a solder solution, the metal film SD, which is a solder film, is formed by an electrical plating method. The metal film SD has a function to improve the wettability of the joining material when the completed semiconductor device 1 (see FIG. 6) is packaged on an unshown packaging board. Examples of the type of the solder film include tin-lead plating, pure-tin plating which is Pb-free plating, and tin-bismuth plating.

A lead frame of preliminary plating in which a conductor film is formed on the lead frame in advance may be used. The conductor film of this case is often formed by, for example, a nickel film, a palladium film formed on the nickel film, and a gold film formed on the palladium film. If the lead frame of preliminary plating is used, the present plating process is omitted.

However, as described above, it is preferred that copper (Cu) which is the base material be exposed in the joining region of the metal ribbon 7R to improve the joining strength. If an electrically-conductive adhesive material is used as a die-bond material, it is preferred that copper (Cu) which is the base material be exposed in the chip mounting region to improve the joining strength. Therefore, even in the case in which the lead frame of preliminary plating is used, it is preferred that a conductor film be not formed in the joining region of the metal ribbon 7R and the chip mounting region.

<Singulation Process>

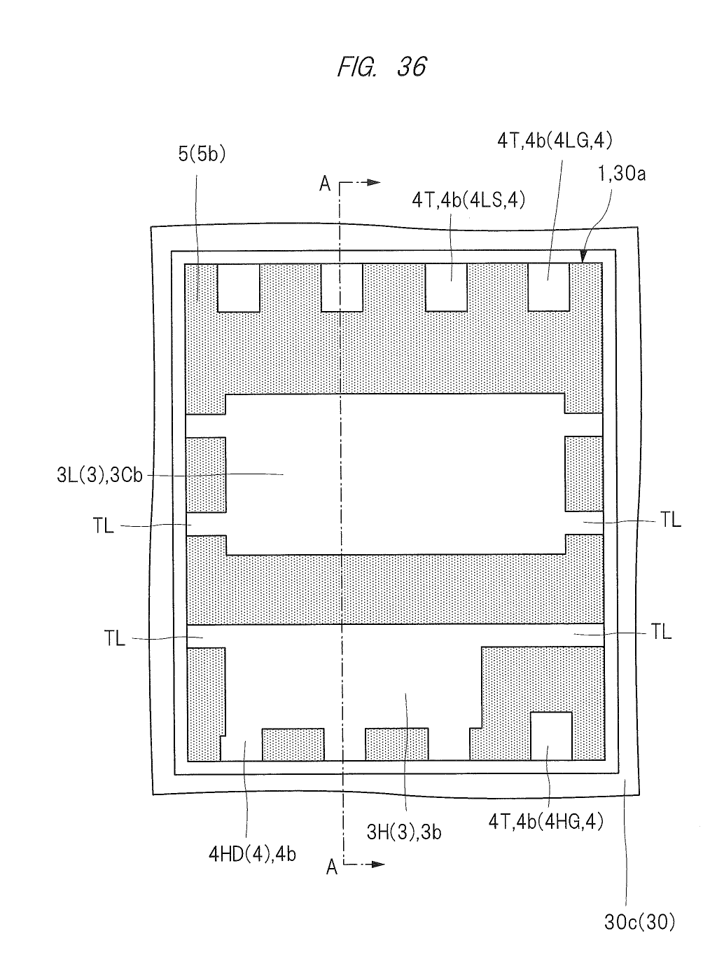

Then, in a singulation process shown in FIG. 17, as shown in FIG. 36, the lead frame 30 is divided by the device regions 30a, respectively. FIG. 36 is an enlarged plan view showing a state in which the lead frame shown in FIG. 33 has undergone singulation.

In the present process, as shown in FIG. 36, part of the lead 4LS is cut to separate the lead 4LS from the frame part 30c. Moreover, in the present process, part of the plurality of suspension leads TL supporting the tab 3L is cut to separate the tab 3L from the frame part 30c. Moreover, part of the plurality of suspension leads TL supporting the tab 3H and the lead 4HD is cut to separate the tab 3H from the frame part 30c. Moreover, part of the leads 4HG and 4LG is cut to separate the leads 4HG and 4LG from the frame part 30c. The cutting method is not particularly limited, and they can be cut by pressing or cutting using a rotating blade.

Through the above processes, the semiconductor device 1 explained by using FIG. 1 to FIG. 14 is obtained. Then, necessary checks and tests such as an appearance check and an electrical test are carried out, and the device is shipped or packaged on an unshown packaging board.

### Modification Examples

Next, various modification examples with respect to the mode explained in the above-described embodiment will be explained.

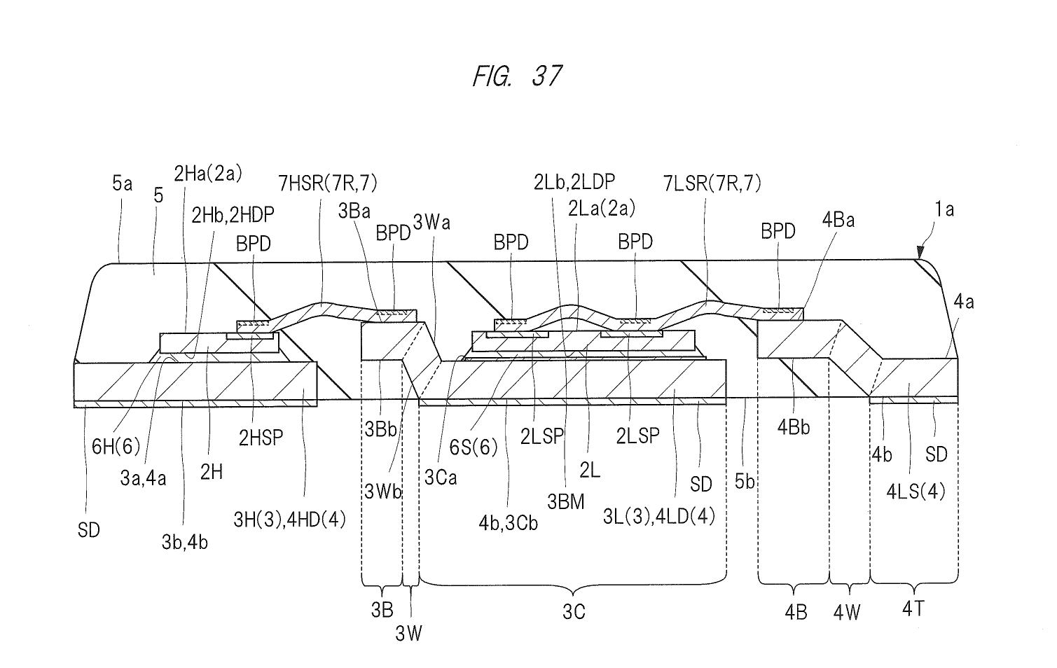

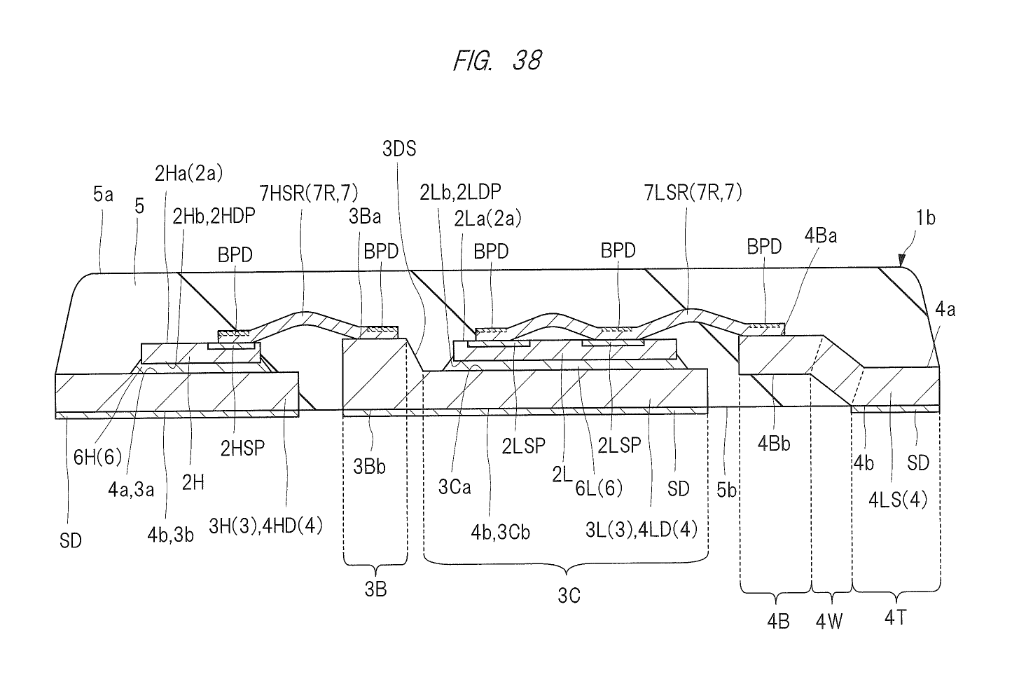

First, in the above-described embodiment, the mode in which the electrically-conductive adhesive materials 6H and 6L are used as the electrically-conductive members 6 for bonding and fixing the semiconductor chips 2H and 2L and electrically connecting the tabs 3H and 3L has been explained. However, like a semiconductor device 1a of a modification example shown in FIG. 37, a solder material 6S can be used as the electrically-conductive members 6. FIG. 37 is a cross-sectional view of the semiconductor device, which is a modification example with respect to FIG. 6.

The semiconductor device 1a shown in FIG. 37 is different from the semiconductor device 1 shown in FIG. 6 in the point that the solder material 6S is used as the electrically-conductive member 6 which bonds and fixes the semiconductor chips 2H and 2L to the tabs 3H and 3L and electrically connect them. In order to suppress remelting upon packaging of the semiconductor device 1, it is preferred that the solder material 6S be a material having a melting point higher than that of the metal film SD and the joining material, which is used upon packaging. The method of increasing the melting point thereof is not particularly limited; however, for example, the melting point can be increased by increasing the content rate of, for example, lead (Pb) mixed in tin (Sn). As an example, solder having a content rate of lead of 90 weight % or higher is used.

While the electrically-conductive adhesive materials 6H and 6L shown in FIG. 6 form conduction paths by contact of the electrically-conductive particles contained in the resin, the entire solder material 6S consists of a conductor. Therefore, the case in which the solder material 6S is used as the electrically-conductive members 6, it is preferred in the point that electrical connection reliability can be improved compared with the case in which the electrically-conductive adhesive material is used.

Moreover, in the case in which the solder material 6S is used, from the viewpoint of improving the connection strength with the chip-mounting surfaces of the tabs 3H and 3L, if the base material of the tabs 3H and 3L consists of, for example, copper (Cu), it is preferred that the chip-mounting surfaces 3a and 3Ca, which are chip-mounting surfaces, be covered with a metal film 3BM, which can improve the connection strength with the solder material 6S. The metal film 3BM is a plating conductor film having a function to improve the wettability of the solder material 6S with respect to the chip-mounting surfaces 3a and 3Ca, and examples thereof include a nickel (Ni) film or a silver (Ag) film.

As a further modification example with respect to FIG. 37, there is a method in which the metal film 3BM is formed on the entire exposed surfaces of the tabs 3 and the leads 4. However, as described above, the joining strength can be improved when copper (Cu), which is a base material, is exposed in the region of joining the metal ribbon 7R. Therefore, from the viewpoint of improving the connection strength of the metal ribbon 7R, as shown in FIG. 37, it is preferred that the metal film 3BM be partially formed in the chip mounting regions in which the semiconductor chips 2H and 2L are mounted.

Moreover, if the solder material 6A is used as a die-bond material, a heating treatment process (reflow process) for melting the solder material is required. In the reflow process, heating has to be carried out at a temperature higher than that in the above-described curing process; therefore, load is applied to the semiconductor chips 2H and 2L. Therefore, from the viewpoint of reducing the load applied to the semiconductor chips, it is preferred that the step of heating the solder material 6S be carried out once. Thus, it is preferred that the solder material 6S, which joins the semiconductor chip 2H, and the solder material 6S, which joins the semiconductor chip 2L, be melted and hardened at a time in one time of a reflow process.

Even in the case in which the solder material 6S is used, if the solder 6S leaks to the ribbon-connecting surface 3Ba of the ribbon-connecting part 3B, the ribbon-connecting surface is contaminated. Therefore, if the height of the ribbon-connecting surface 3Ba is positioned at the same height as that of the chip-mounting surface 3Ca, which is a chip-mounting surface, or at a height lower than that, the distance between the ribbon-connecting surface and the chip-mounting surface has to be increased as well as the above-described case in which the electrically-conductive adhesive materials 6H and 6L are used. As a result, even when the solder material 6S is used, there is a problem that downsizing is difficult. Therefore, some of the main characteristics explained above can solve this problem.

Since the semiconductor device 1a shown in FIG. 37 is similar to the semiconductor device 1, which has been explained in the above-described embodiment, except for the above-described different point, redundant explanations are omitted.

Next, in the above-described embodiment, the method of forming the bent part 3W by bending the tab 3L has been explained as a method of causing the height of the ribbon-connecting surface 3Ba of the ribbon-connecting part 3B of the tab 3L to be higher than the height of the chip-mounting surface 3Ca, which is a chip-mounting surface. However, like a semiconductor device 1b of a modification example shown in FIG. 38, the height of the ribbon-connecting surface 3Ba can be caused to be higher than the chip-mounting surface 3Ca by increasing the plate thickness of the ribbon-connecting part 3B to be thicker than the thickness of the chip mounting region. FIG. 38 is a cross-sectional view of the semiconductor device, which is another modification example with respect to FIG. 6.

The semiconductor device 1b shown in FIG. 38 is different from the semiconductor device 1 shown in FIG. 6 in the point that the thickness of the ribbon-connecting part 3B integrally formed with the tab 3L is thicker than the thickness of the mounting region of the semiconductor chip 2L. In other words, in the thickness direction of the tab 3L, the thickness (distance) from the ribbon-connecting surface 3Ba to the lower surface 3Bb immediately therebelow is thicker (larger) than the thickness (distance) from the chip-mounting surface 3Ca, which is a chip-mounting surface, to the lower surface 3Bb immediately therebelow.

Moreover, the semiconductor device 1b is different from the semiconductor device 1 shown in FIG. 6 in the point that the lower surface 3Bb of the ribbon-connecting part 3B of the tab 3L is continued to the lower surface 3Cb of the chip mounting region and is exposed from the seal 5.

As a result of that, the height of the ribbon-connecting surface 3Ba can be controlled by the thickness of the ribbon-connecting part 3B. Therefore, compared with the case in which, for example, the bent part 3W is formed by pressing like the semiconductor device 1, the height of the ribbon-connecting surface 3Ba can be controlled with high precision. The ribbon-connecting part 3B provided with a step part 3DS as shown in FIG. 38 can be formed by, for example, etching. Alternatively, it can be formed by subjecting the metal plate of the ribbon-connecting part 3B to bending and plastic deformation in the stage of forming the lead frame 30 (see FIG. 19). In any of the above-described cases, the position (height) of the ribbon-connecting surface 3Ba can be processed with high precision.

As described above, it is preferred that the height of the ribbon-connecting surface 3Ba be high by the degree that the contact between the bonding tool 23 and the semiconductor chip 2L in the ribbon bonding process can be avoided. On the other hand, if the height of the ribbon-connecting surface 3Ba is too high, the height of the metal ribbon 7HSR becomes high; therefore, the height of the package becomes high. Therefore, control of the height of the ribbon-connecting surface 3Ba by high precision is preferred in the point that increase of the height of the package can be suppressed.

Moreover, the semiconductor device 1b is different from the semiconductor device 1 shown in FIG. 6 in the points that the bent part 3W (see FIG. 6) is not formed between the ribbon-connecting surface 3Ba of the ribbon-connecting part 3B of the tab 3L and the chip-mounting surface 3Ca, which is a chip-mounting surface, and that the step part (tilted surface) 3DS is disposed between the ribbon-connecting surface 3Ba and the chip-mounting surface 3Ca, which is a chip-mounting surface.

In the above-described embodiment, it has been explained that progress of peel-off occurred at the blank region of the seal 5 and the ribbon-connecting part 3B can be suppressed by forming the bent part 3W. In the case in which the step part 3DS is provided between the ribbon-connecting surface 3Ba and the chip-mounting surface 3Ca like the semiconductor device 1b shown in FIG. 38, progress of the peel-off can be suppressed by the step part 3DS. Particularly, at the boundary between the ribbon-connecting surface 3Ba and the step part 3DS and at the boundary between the chip-mounting surface 3Ca and the step part 3DS, progress of peel-off can be easily prevented. Thus, according to the modification example shown in FIG. 38, since progress of peel-off can be suppressed by the step part 3DS, reduction of electrical characteristics caused by peel-off of the electrically-conductive adhesive material 6L can be suppressed. In other words, reliability of the semiconductor device 1 can be improved. Moreover, the modification example shown in FIG. 38 is excellent in below points in manufacturing processes. That is, since the semiconductor device 1b does not have a bent part in the tab 3, a flat supporting base (illustration omitted) on which the projecting part 25c is not provided can be used instead of the supporting base 25 shown in FIG. 25 in the above-described ribbon bonding process. By virtue of this, the structure of the supporting base used in the ribbon bonding process can be simplified. Moreover, ribbon bonding can be stably carried out since the lower surface 3Bb immediately below the ribbon-connecting surface 3Ba can be firmly retained by a flat retaining surface.

Since the semiconductor device 1b shown in FIG. 38 is similar to the semiconductor device 1, which has been explained in the above-described embodiment, except for the points of the above-described different points, redundant explanations thereof are omitted.

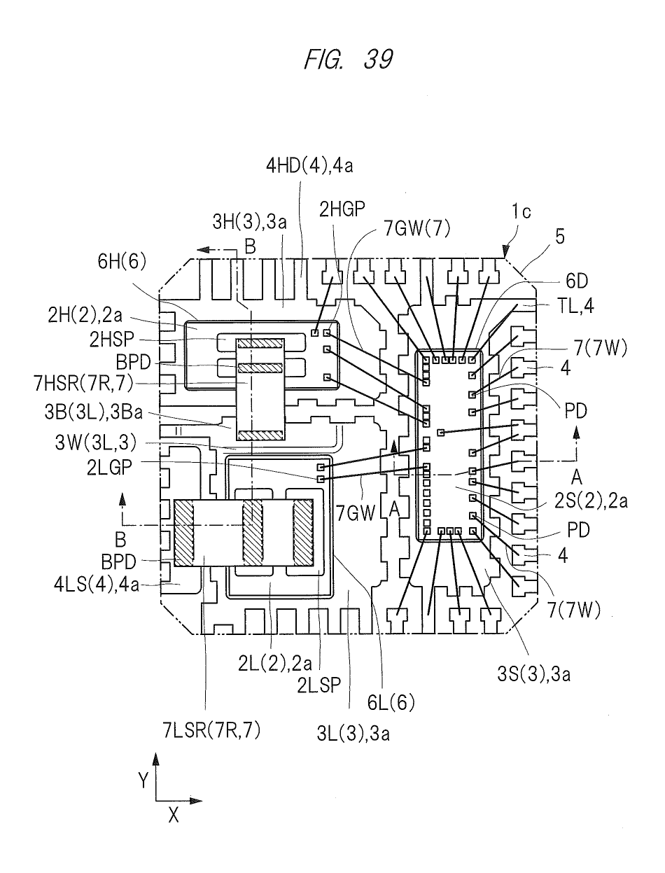

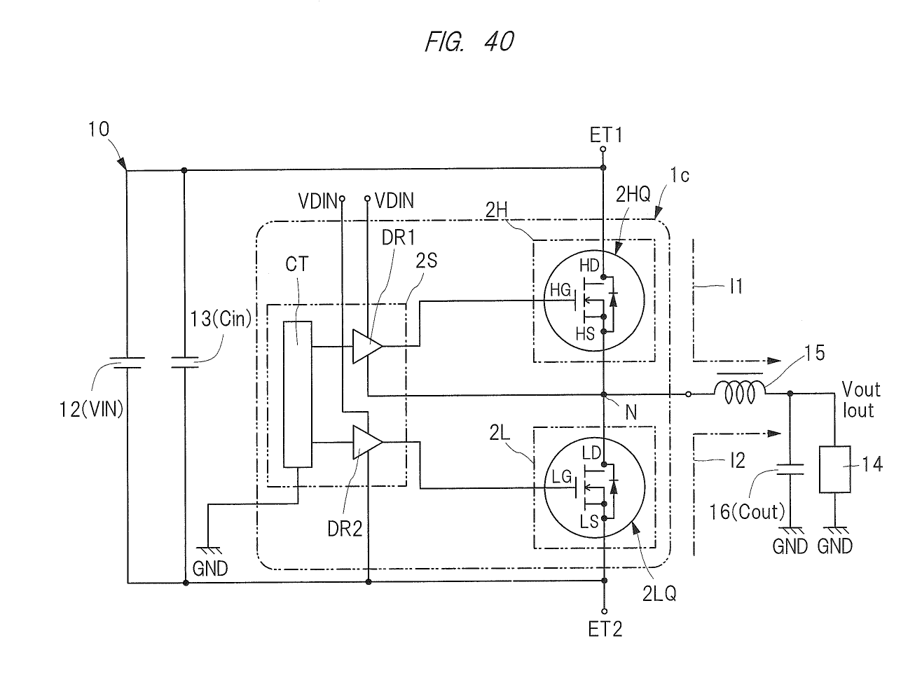

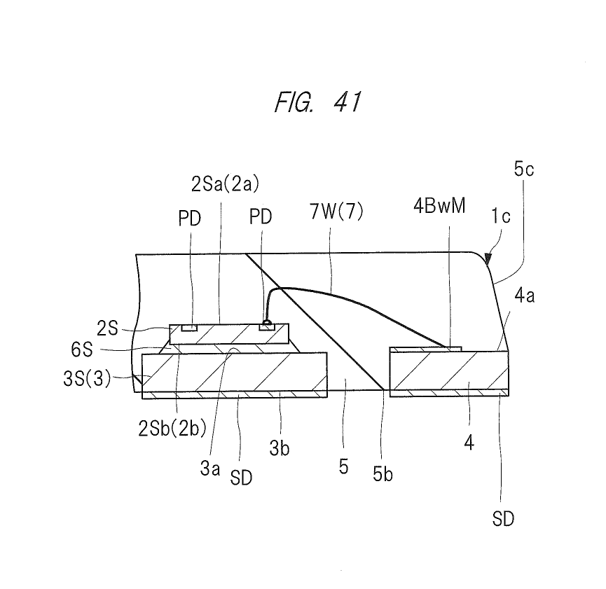

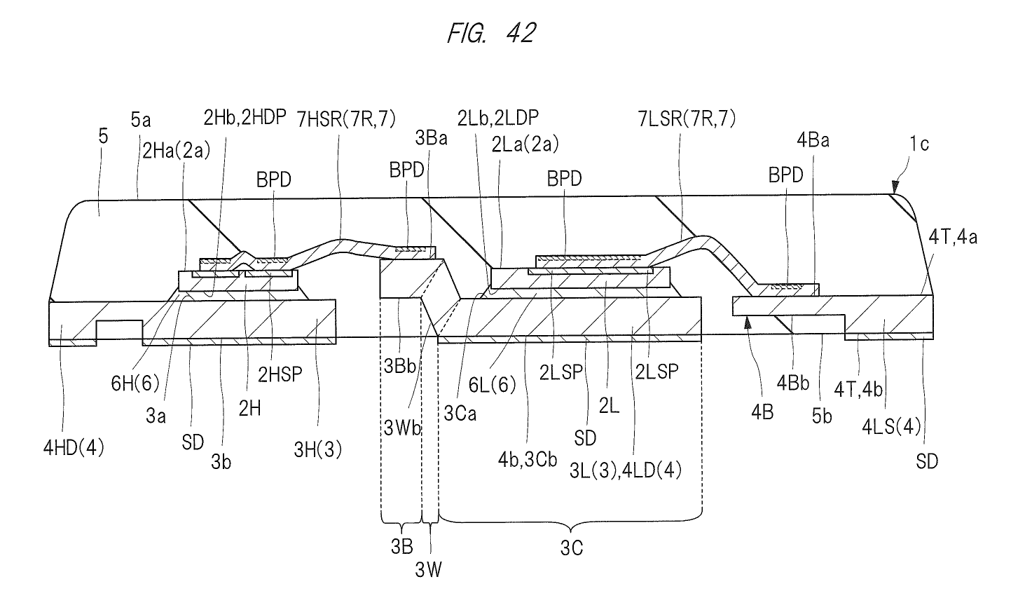

Next, in the above-described embodiment, the semiconductor device 1 in which the two semiconductor chips 2 are built has been explained for the sake of understandability. However, the number of the semiconductor chips 2 built in the single package is only required to be two or more. For example, this can be applied to a semiconductor device 1c in which three semiconductor chips 2 are built as shown in FIG. 39. FIG. 39 is a plan view showing an internal structure of a semiconductor device, which is a modification example with respect to FIG. 5. FIG. 40 is an explanatory diagram showing a modification example with respect to FIG. 1, which is a configuration example of a power source circuit in which the semiconductor device shown in FIG. 39 is incorporated. FIG. 41 is an enlarged cross-sectional view taken along a line A-A of FIG. 39. FIG. 42 is an enlarged cross-sectional view taken along a line B-B of FIG. 39.

The semiconductor device 1c shown in FIG. 39 is different from the semiconductor device 1 shown in FIG. 5 in the point that a semiconductor chip 2S, which is a third semiconductor chip, is provided in addition to the semiconductor chips 2H and 2L. As shown in FIG. 40, the semiconductor chip 2S has the driver circuits DR1 and DR2, which drive the high-side MOSFET 2HQ provided on the semiconductor chip 2H and the low-side MOSFET 2LQ provided on the semiconductor chip 2L. Moreover, the semiconductor chip 2S has the control circuit CT, which drives the MOSFETs 2HQ and 2LQ via the driver circuits DR1 and DR2. Thus, the semiconductor device 1c shown in FIG. 40 is a semiconductor package in which the semiconductor device 1 and the semiconductor device 11 shown in FIG. 1 are built in a single package. Since the semiconductor device 1c has the high-side MOSFET 2HQ, the low-side MOSFET 2LQ, the driver circuits DR1 and DR2, and the control circuit CT in the single package, the packaging area of the entire electric-power converting circuit can be reduced.

Moreover, as shown in FIG. 41, the semiconductor chip 2S has a top surface 2Sa and a back surface 2Sb positioned on the opposite side of the top surface 2Sa. Moreover, as shown in FIG. 39, a plurality of electrode pads (fifth electrode pads, sixth electrode pads) PD are formed on the top surface 2Sa of the semiconductor chip 2S. Some of the plurality of electrode pads PD are electrically connected to the gate electrode pads 2HGP, which are formed on the top surface 2Ha of the semiconductor chip 2H, via the wires 7GW. Also, some of the other plurality of electrode pads PD are electrically connected to the gate electrode pads 2LGP, which are formed on the top surface 2La of the semiconductor chip 2L, via the wires 7GW. In the periphery of the semiconductor chip 2S, the plurality of leads 4 are disposed, and some of the other plurality of electrode pads PD are electrically connected to the plurality of leads 4 via a plurality of wires 7W.

Moreover, as shown in FIG. 41, the semiconductor chip 2S is mounted on a tab 3S, which is formed in addition to (separately from) the tabs 3H and 3L. The tab 3S has a chip-mounting surface 3a, which is a chip-mounting surface, and a lower surface 3b positioned in the side opposite to the chip-mounting surface 3a, and the lower surface 3b is exposed from the seal 5. The semiconductor chip 2S is mounted on the tab 3S via a die-bond material 6D so that the back surface 2Sb is opposed to the chip-mounting surface 3a of the tab 3S.

No electrodes are formed on the back surface 2Sb of the semiconductor chip 2S. Therefore, the die-bond material 6D is not necessarily be an electrically-conductive member. However, use of an electrically-conductive adhesive material as well as the electrically-conductive adhesive materials 6H and 6L shown in 33 is preferred in the point that manufacturing processes become simple.

In the manufacturing processes of the semiconductor device 1c shown in FIG. 39 to FIG. 42, the timing of mounting the semiconductor chip 2S on the tab 3S is preferred to be carried out in the semiconductor-chip mounting process explained by using FIG. 17. Moreover, it is preferred that the die-bond material 6D be hardened at a time with the electrically-conductive adhesive materials 6H and 6L. Also, the step of joining the wires 7GW and 7W can be carried out in the wire-bonding process explained by using FIG. 17. Also, in the manufacturing process of the semiconductor device 1c, in the sealing process shown in FIG. 17, the semiconductor chip 2S is also sealed with an insulating resin.

Moreover, the semiconductor device 1c shown in FIG. 39 is different from the semiconductor device 1 shown in FIG. 5 in the point that the extending direction of the metal ribbon 7HSR and the extending direction of the metal ribbon 7LSR are different. In the example shown in FIG. 39, the metal ribbon 7HSR is extending along the Y-direction from the source electrode pad 2HSP of the semiconductor chip 2H toward the ribbon-connecting surface 3Ba of the ribbon-connecting part 3B of the tab 3L. On the other hand, the metal ribbon 7LSR is extending along the X-direction from the source electrode pad 2LSP of the semiconductor chip 2L toward the ribbon-connecting surface 4Ba of the ribbon-connecting part 4B of the lead 4LS. The Y-direction and the X-direction are orthogonal to each other.

In a plan view, the semiconductor device 1c forms a quadrangle, and the tab 3H and the lead 4LS are disposed at the same side (the side extending along the Y-direction). Therefore, as described above, this is a layout that the extending direction of the metal ribbon 7HSR and the extending direction of the metal ribbon 7LSR are practically orthogonal to each other.

If the input capacitor 13 is connected in the manner shown in FIG. 40, the loop distance of the circuit connected to the input capacitor 13 can be shortened by shortening the distance between the drain HD of the high-side MOSFET 2HQ and the source LS of the low-side MOSFET 2LQ. By virtue of this, occurrence of ringing, etc. becomes difficult. Moreover, in the example shown in FIG. 39, the planar size of the low-side semiconductor chip 2L can be increased by disposing the lead 4LS along the side extending in the Y-direction.

However, the optimum relation of the extending direction of the metal ribbon 7HSR and the extending direction of the metal ribbon 7LSR is different depending on the planar size and layout of the semiconductor chip 2S. For example, although illustration is omitted, as a further modification example with respect to FIG. 39, the metal ribbon 7HSR and the metal ribbon 7LSR can be disposed to be extended along the Y-direction while the planar sizes of the semiconductor chip 2S and the tab 3S are reduced.

Also, the semiconductor device 1c shown in FIG. 42 is different from the semiconductor device 1 shown in FIG. 6 in the points that the lead 4LS is not bent and that the ribbon-connecting surface 4Ba of the ribbon-connecting part 4B and the upper surface 4a of the terminal part 4T are at the same height. In the semiconductor device 1c, the lower surface immediately below the ribbon-connecting part 4B has undergone half etching, and, because of that, the ribbon-connecting part 4B is sealed in the seal 5. Since no semiconductor chip is mounted on the lead 4LS, the problem upon ribbon bonding does not occur even if the heights of the ribbon-connecting surface 4Ba of the ribbon-connecting part 4B and the upper surface 4a of the terminal part 4T are the same. Moreover, the case in which the ribbon-connecting part 4B is sealed by half etching is advantageous in terms of downsizing since the space for providing the bent part 4W shown in FIG. 6 is not required.

Since the semiconductor device 1c shown in FIG. 39 to FIG. 42 is similar to the semiconductor device 1 explained in the above-described embodiment except for the different points described above, redundant explanations are omitted.

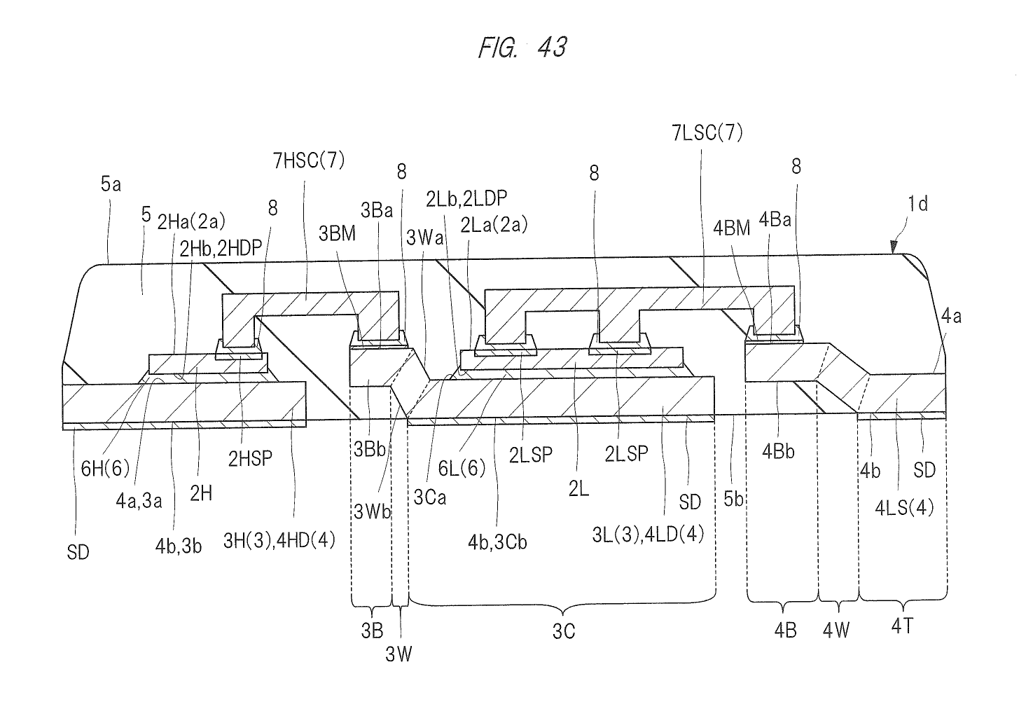

Then, in the above-described embodiment, the mode in which the source electrode pad 2HSP of the semiconductor chip 2H with the tab 3L and the source electrode pad 2LSP of the semiconductor chip 2L with the lead 4LS are electrically connected via the respective metal ribbons 7HSR and 7LSR has been explained. However, like a semiconductor device 1d of a modification example shown in FIG. 43, application to a mode in which electrical connection is established via metal clips HSC and 7LSC, which are metal plates molded in advance, can be made. FIG. 43 is a cross-sectional view of the semiconductor device which is another modification example with respect to FIG. 6.

The semiconductor device 1d shown in FIG. 43 is different from the semiconductor device 1 shown in FIG. 6 in the points that the source electrode pad 2HSP of the semiconductor chip 2H with the tab 3L and the source electrode pad 2LSP of the semiconductor chip 2L with the lead 4LS are electrically connected via the respective metal clips (metal plates) 7HSC and 7LSC.

One end of the metal clip 2HSC is electrically connected to the source electrode pad 2HSP of the semiconductor chip 2H via a solder material (electrically-conductive member) 8. Also, the second end positioned on the opposite side of the above-described first end of the metal clip 7HSC is electrically connected to the ribbon-connecting surface 3Ba of the ribbon-connecting part 3B, which is a clip connecting surface of the tab 3L, via the solder material 8. Moreover, the metal film 3BM is formed on the ribbon-connecting surface 3Ba in order to improve the wettability of the solder material 8.

Moreover, a first end of the metal clip 7LSC is electrically connected to the source electrode pad 2LSP of the semiconductor chip 2L via the solder material (electrically-conductive member) 8. Moreover, a second end of the metal clip 7LSC positioned on the opposite side of the above-described first end is electrically connected to the ribbon-connecting surface 4Ba of the ribbon-connecting part 4B, which is a clip connecting surface of the lead 4LS via the solder material 8. Moreover, the metal film 4BM is formed on the ribbon-connecting surface 4Ba in order to improve the wettability of the solder material 8.

In the case in which the metal clips 7HSC and 7LSC are used like the semiconductor device 1d instead of the metal ribbons HSR and 7HLR explained in the above-described embodiment, an electrically-conductive joining material such as the solder material 8 is provided at the joining part. Therefore, since joining can be carried out, for example, by carrying out reflow treatment upon bonding, the bonding tool 23, which is shown in FIG. 25 to FIG. 29 and applied with ultrasonic waves, is not used. Therefore, the problem of contact between the bonding tool 23 and the semiconductor chip 2L as explained in the above-described embodiment does not occur.

However, as shown in FIG. 43, in the manufacturing processes of the semiconductor device 1d, in a clip bonding process corresponding to the ribbon bonding process shown in FIG. 17, the metal film 3BM, which improves the wettability of the solder material 8, is formed. Then, if the exposed surface of the metal film 3BM is contaminated by the electrically-conductive adhesive material 6L in the semiconductor-chip mounting process shown in FIG. 17, the wettability of the solder material 8 is lowered. Thus, in the semiconductor-chip mounting process, a technique to protect the exposed surface of the metal film 3BM from contamination is required.

In the semiconductor-chip mounting process, the technique explained in the above-described embodiment can be applied and employed as the technique to protect the exposed surface of the metal film 3BM from contamination. More specifically, by causing the height of the ribbon-connecting surface 3Ba of the ribbon-connecting part 3B to be higher than the height of the chip-mounting surface 3Ca, which is the chip-mounting surface of the tab 3L, contamination of the metal film 3Bm in the chip mounting process can be prevented or suppressed. Moreover, as explained in the above-described embodiment, in the case of this countermeasure method, the distance between the semiconductor chip 2L and the ribbon-connecting part 3B can be shortened. Therefore, the planar size of the semiconductor device 1d can be downsized.

The semiconductor device 1d shown in FIG. 43 is similar to the semiconductor device 1 explained in the above-described embodiment except for the above-described different points. Therefore, redundant explanations are omitted. Extraction of the technical idea explained by using FIG. 43 can be expressed as described below.

[Note 1]

A method of manufacturing a semiconductor device including the steps of:

a) preparing a lead frame having a first chip-mounting part on which a first semiconductor chip is mounted and a second chip-mounting part on which a second semiconductor chip is mounted;

b) electrically connecting a first electrode pad formed on a top surface of the first semiconductor chip with a first end of a first metal ribbon via a first solder material; and

c) electrically connecting a ribbon-connecting surface of a ribbon-connecting part of the second chip-mounting part with a second end of the first metal ribbon on the opposite side of the first end via a second solder material; wherein

a first metal film covering a base material of the second chip-mounting part is formed on the ribbon-connecting surface;

in a plan view, the ribbon-connecting surface of the second chip-mounting part is positioned between the first semiconductor chip and the second semiconductor chip; and

the height of the ribbon-connecting surface is positioned at a position higher than the height of a mounting surface of the second semiconductor chip of the second chip-mounting part.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, the modification examples can be combined and applied within the range not departing from the gist of the technical ideas explained in the above-described embodiments.
1, 1a, 1b, 1c, 1d SEMICONDUCTOR DEVICE
2, 2H, 2L SEMICONDUCTOR CHIP
2a, 2Ha, 2La TOP SURFACE
2b, 2Hb, 2Lb BACK SURFACE
2HD, 2LD DRAIN
2HDP, 2LDP DRAIN ELECTRODE
2HG GATE ELECTRODE
2HGP, 2LGP GATE ELECTRODE PAD
2HQ, 2LQ, MOSFET (FIELD-EFFECT TRANSISTOR, POWER TRANSISTOR)
2HSP, 2LSP SOURCE ELECTRODE PAD
2S SEMICONDUCTOR CHIP
2Sa TOP SURFACE
2Sb BACK SURFACE
3, 3H, 3L TAB (CHIP-MOUNTING PART, DIE PAD)
3a, 3Ca CHIP-MOUNTING SURFACE (UPPER SURFACE)
3b LOWER SURFACE (MOUNTING SURFACE)
3B RIBBON-CONNECTING PART (CONNECTING PART)
3b, 3Cb LOWER SURFACE
3b, 3Cb, 4b LOWER SURFACE
3Ba RIBBON-CONNECTING SURFACE (CONNECTING SURFACE, UPPER SURFACE)
3Bb LOWER SURFACE (LOWER SURFACE IMMEDIATELY BELOW RIBBON-CONNECTING SURFACE 3Ba)
3BM METAL FILM
3C CHIP-CONNECTING PART
3Ca CHIP-MOUNTING SURFACE (UPPER SURFACE)
3Cb LOWER SURFACE (PACKAGING SURFACE)
3DS STEP PART (TILTED SURFACE)
3E EDGE PART
3S TAB
3W, 4W BENT PART (TILTED PART)
3Wa UPPER SURFACE
3Wb LOWER SURFACE
4, 4HD, 4HG, 4HS, 4LD, 4LG, 4LS LEAD
4a UPPER SURFACE
4b LOWER SURFACE
4B RIBBON-CONNECTING PART (CONNECTING PART)
4B METAL FILM
4Ba RIBBON-CONNECTING SURFACE (CONNECTING SURFACE, UPPER SURFACE)
4Bb LOWER SURFACE
4BM METAL FILM
4Bw WIRE CONNECTING PART
4Bwa WIRE CONNECTING SURFACE
4BwM METAL FILM
4HD LEAD
4HD, 4LD, 4LS LEAD
4HG LEAD
4HG, 4LG LEAD
4HG, 4LS, 4LG LEAD
4LD LEAD
4LG LEAD
4LS LEAD (PLATE-SHAPED LEAD MEMBER)
4LS LEAD
4LS, 4HG, 4LG LEAD
4T TERMINAL PART
4W PART (OR TILTED PART)
4W PART
5 SEAL (RESIN BODY)
5a UPPER SURFACE
5b LOWER SURFACE (PACKAGING SURFACE)
5c LATERAL SURFACE
6 ELECTRICALLY-CONDUCTIVE MEMBER (DIE-BOND MATERIAL)
6D DIE-BOND MATERIAL
6H, 6L ELECTRICALLY-CONDUCTIVE ADHESIVE MATERIAL (ELECTRICALLY-CONDUCTIVE MEMBER)
6S SOLDER MATERIAL
7GW, 7W WIRE (ELECTRICALLY-CONDUCTIVE MEMBER, MEAL WIRE)
7HSC, 7LSC METAL CLIP (METAL PLATE)
7HSR, 7LSR, 7R METAL RIBBON (ELECTRICALLY-CONDUCTIVE MEMBER, STRIP-SHAPED METAL MEMBER)
8 SOLDER MATERIAL (ELECTRICALLY-CONDUCTIVE MEMBER)
10 POWER SOURCE CIRCUIT
11 SEMICONDUCTOR DEVICE
12 INPUT POWER SOURCE
13 INPUT CAPACITOR
14 LOAD
15 COIL
16 OUTPUT CAPACITOR
20 METAL STRIP
21 REEL (RETAINING PART)
22 PART TO BE JOINED (ELECTRODE PAD PD OF SEMICONDUCTOR CHIP 2 OR CONNECTING SURFACE 3Ba OF RIBBON-CONNECTING PART 3B OF TAB 3)
22 PART TO BE JOINED
23 BONDING TOOL (JOINING JIG)
23b LOWER SURFACE
24 CUTTING BLADE
25 SUPPORTING BASE
25a TAB RETAINING SURFACE
25b RIBBON-CONNECTING-PART RETAINING SURFACE
25c PROJECTING PART
26 BONDING TOOL
27 WIRE
28 SUPPORTING BASE
30 LEAD FRAME
30a DEVICE REGION
30b OUTER FRAME
30c FRAME PART
31 FORMING MOLD
32 UPPER MOLD (FIRST MOLD)
32 UPPER MOLD
33 LOWER MOLD (SECOND MOLD)
33 LOWER MOLD
34 CAVITY
60, 61 SEMICONDUCTOR DEVICE

What is claimed is:

1. A method of manufacturing a semiconductor device comprising the steps of:
(a) preparing a lead frame having a first chip-mounting part on which a first semiconductor chip is mounted and a second chip-mounting part on which a second semiconductor chip is mounted;
(b) electrically connecting a first electrode pad formed on a top surface of the first semiconductor chip with a first end of a first metal ribbon by applying ultrasonic waves to a first bonding tool; and
(c) electrically connecting a ribbon-connecting surface of a ribbon-connecting part of the second chip-mounting part with a second end of the first metal ribbon on the opposite side of the first end by applying ultrasonic waves to the first bonding tool,
wherein, in a plan view, the ribbon-connecting surface of the second chip-mounting part is positioned between the first semiconductor chip and the second semiconductor chip; and
the height of the ribbon-connecting surface is positioned at a position higher than the height of a chip-connecting surface of a chip-connecting part of the second chip-mounting part on which the second semiconductor chip is mounted.

2. The method of manufacturing the semiconductor device according to claim 1,
wherein the height of the ribbon-connecting surface is higher than or equal to the height of a top surface of the second semiconductor chip.

3. The method of manufacturing the semiconductor device according to claim 1,
wherein the step (c) is carried out in a state that a lower surface on the opposite side of and immediately below the ribbon-connecting surface of the second chip-mounting part is supported by a supporting base.

4. The method of manufacturing the semiconductor device according to claim 3,
wherein the lead frame has a first lead having a ribbon-connecting part,
the method comprising the steps of:
(d) after the step (c), electrically connecting a second electrode pad formed on a top surface of the second semiconductor chip with a first end of a second metal ribbon by applying ultrasonic waves to a second bonding tool; and
(e) after the step (d), electrically connecting a ribbon-connecting surface of the ribbon-connecting part of the first lead with a second end of the second metal ribbon on the opposite side of the first end by applying ultrasonic waves to the second bonding tool.

5. The method of manufacturing the semiconductor device according to claim 4,
wherein the first semiconductor chip has a third electrode pad formed on the top surface thereof;
the second semiconductor chip has a fourth electrode pad formed on the top surface thereof,
the method comprising the step of,
(f) after the step (e), electrically connecting the third and fourth electrode pads with first ends of a first metal wire and a second metal wire, respectively, by applying ultrasonic waves to a third bonding tool.

6. The method of manufacturing the semiconductor device according to claim 5, the method comprising the step of,
(g) after the step (f), forming a seal by sealing the first and second semiconductor chips, part of the first and second chip-mounting parts, the first and second metal ribbons, the first and second metal wires, and the ribbon-connecting part of the first lead with an insulating resin.

7. The method of manufacturing the semiconductor device according to claim 6,
wherein the lead frame has a third chip-mounting part on which a third semiconductor chip is mounted;
a fifth electrode pad and a sixth electrode pad are formed on a top surface of the third semiconductor chip;
the step (f) includes a step of electrically connecting the fifth and sixth electrode pads with second ends of the first and second metal wires on the opposite side of the first ends, respectively, by applying ultrasonic waves to the third bonding tool; and
the step (g) includes forming the seal by also sealing the third semiconductor chip with the insulating resin.

8. The method of manufacturing the semiconductor device according to claim 6,
wherein the second chip-mounting part has an upper surface on which a chip-mounting surface and the ribbon-connecting surface are formed and has a lower surface on the opposite side of the upper surface;
the second semiconductor chip is mounted on the chip-mounting surface;
in a thickness direction of the second chip-mounting part, the thickness from the ribbon-connecting surface to the lower surface immediately below the ribbon-connecting surface is thicker than the thickness from the chip-mounting surface to the lower surface immediately below the chip-mounting surface; and,
in the step (g), the seal is formed so that the lower surface of the second chip-mounting part is exposed from the seal.

9. The method of manufacturing the semiconductor device according to claim 6,
wherein the second chip-mounting part has an upper surface on which the chip-mounting surface and the ribbon-connecting surface are formed and has a lower surface on the opposite side of the upper surface;
the second semiconductor chip is mounted on the chip-mounting surface;
in a thickness direction of the second chip-mounting part, the thickness from the ribbon-connecting surface to the lower surface immediately below the ribbon-connecting surface is equal to the thickness from the chip-mounting surface to the lower surface immediately below the chip-mounting surface; and,
in the step (g), the seal is formed so that part of the lower surface positioned immediately below the ribbon-connecting surface is covered with the seal and that part of the lower surface positioned immediately below the chip-mounting surface is exposed from the seal.

10. The method of manufacturing the semiconductor device according to claim 4,
wherein the width of the second metal ribbon in a direction orthogonal to the direction from the second electrode pad of the second semiconductor chip toward the ribbon-connecting part of the first lead is wider than the width of the first metal ribbon in the direction orthogonal to the direction from the first electrode pad of the first semiconductor chip toward the ribbon-connecting surface of the second chip-mounting part.

11. The method of manufacturing the semiconductor device according to claim 4,
wherein the first lead is disposed so that the second chip-mounting part is positioned between the first chip-mounting part and the first lead in a plan view.

12. The method of manufacturing the semiconductor device according to claim 4,
wherein the first metal ribbon is extending along a first direction from the first electrode pad of the first semiconductor chip toward the ribbon-connecting surface of the second chip-mounting part;
the second metal ribbon is extending along a second direction from the second electrode pad of the second semiconductor chip toward the ribbon-connecting part of the first lead; and
the first direction is orthogonal to the second direction.

13. The method of manufacturing the semiconductor device according to claim 4,
wherein the height of the ribbon-connecting surface of the first lead is higher than the height of the top surface of the second semiconductor chip.

14. A method of manufacturing a semiconductor device comprising the steps of:
(a) preparing a lead frame having a first chip-mounting part, a second chip-mounting part, and a first lead;
(b) mounting, on the first chip-mounting part, a first semiconductor chip having a first top surface on which a first electrode pad is formed and a first back surface on the opposite side of the first top surface via a first electrically-conductive adhesive material so that the first back surface and the first chip-mounting part are opposed to each other;
(c) mounting, on a chip-mounting surface of the second chip-mounting part, a second semiconductor chip having a second top surface on which a second electrode pad is formed and a second back surface on the opposite side of the second top surface via a second electrically-conductive adhesive material so that the second back surface and the second chip-mounting part are opposed to each other;
(d) hardening the first and second electrically-conductive adhesive materials after the steps (b) and (c);
(e) electrically connecting the first electrode pad of the first semiconductor chip with a first end of a first metal ribbon by applying ultrasonic waves to a first bonding tool;
(f) electrically connecting a ribbon-connecting surface of the second chip-mounting part with a second end of the first metal ribbon on the opposite side of the first end by applying ultrasonic waves to the first bonding tool;
(g) electrically connecting the second electrode pad of the second semiconductor chip with a first end of a second metal ribbon by applying ultrasonic waves to a second bonding tool;
(h) electrically connecting a ribbon-connecting part of the first lead with a second end of the second metal ribbon on the opposite side of the first end by applying ultrasonic waves to the second bonding tool;
(i) forming a seal by sealing the first and second semiconductor chips, part of the first and second chip-mounting parts, the ribbon-connecting part of the first lead, and the first and second metal ribbons with an insulating resin; and
(j) cutting part of the first lead and separating a remaining part of the first lead and the lead frame from each other,
wherein, in a plan view, the ribbon-connecting surface of the second chip-mounting part is positioned between the first semiconductor chip and the second semiconductor chip; and
the height of the ribbon-connecting surface is positioned at a position higher than the height of the mounting surface of the second semiconductor chip of the second chip-mounting part.

15. The method of manufacturing the semiconductor device according to claim 14,
wherein the height of the ribbon-connecting surface is higher than or equal to the height of the top surface of the second semiconductor chip.

16. A semiconductor device comprising:
a first semiconductor chip having a first top surface on which a first electrode pad is formed;
a second semiconductor chip having a second top surface;
a first chip-mounting part having an upper surface on which the first semiconductor chip is mounted via a first electrically-conductive adhesive material and has a lower surface on the opposite side of the upper surface;
a second chip-mounting part having a chip-connecting part on which the second semiconductor chip is mounted via a second electrically-conductive adhesive material, has a ribbon-connecting part, has an upper surface, and has a lower surface on the opposite side of the upper surface;
a first metal ribbon having a first end electrically connected to the first electrode pad of the first semiconductor chip and having a second end on the opposite side of the first end electrically connected to the ribbon-connecting part of the second chip-mounting part; and
a seal sealing the first and second semiconductor chips, part of the first and second chip-mounting parts, and the first metal ribbon,
wherein the second semiconductor chip is mounted on a chip-connecting surface of the chip-connecting part of the second chip-mounting part;
the second end of the first metal ribbon is electrically connected to a ribbon-connecting surface of the ribbon-connecting part of the second chip-mounting part;
in a plan view, the ribbon-connecting surface is positioned between the first semiconductor chip and the second semiconductor chip; and
the height of the ribbon-connecting surface is positioned at a position higher than the height of the chip-connecting surface.

17. The semiconductor device according to claim 16,
wherein the height of the ribbon-connecting surface is higher than or equal to the second top surface of the second semiconductor chip.

18. The semiconductor device according to claim 17,
wherein the second chip-mounting part is provided with a bent part between the ribbon-connecting part and the chip-connecting part so that the height of the ribbon-connecting surface is higher than the height of the chip-mounting surface.

19. The semiconductor device according to claim 18,
wherein the lower surface immediately below the ribbon-connecting surface of the second chip-mounting part is covered with the seal; and
the lower surface immediately below the chip-mounting surface of the second chip-mounting part is exposed from the seal.

20. The semiconductor device according to claim 19,
wherein, in a thickness direction of the second chip-mounting part, the thickness from the ribbon-connecting surface to the lower surface immediately below the ribbon-connecting surface is equal to the thickness from the chip-mounting surface to the lower surface immediately below the chip-mounting surface.
